(19) United States
(12) Patent Application Publication
(10) Pub. No.: US 2025/0055595 A1
(43) Pub. Date: Feb. 13, 2025

(54) METHODS AND APPARATUS FOR INFORMATION TRANSMISSION

(71) Applicant: ZTE Corporation, Shenzhen (CN)

(72) Inventors: Chulong LIANG, Shenzhen (CN); Jin XU, Shenzhen (CN); Wei ZHAO, Shenzhen (CN); Liguang LI, Shenzhen (CN); Guanghui YU, Shenzhen (CN); Jian KANG, Shenzhen (CN); Qiang FU, Shenzhen (CN)

(21) Appl. No.: 18/926,197

(22) Filed: Oct. 24, 2024

Related U.S. Application Data
(63) Continuation of application No. PCT/CN2022/121869, filed on Sep. 27, 2022.

(51) Int. Cl. H04L 1/00

(52) U.S. Cl. CPC H04L 1/0057; H04L 1/0067

(57) ABSTRACT

Methods, apparatus, and systems that relate to Polarization-Adjusted Convolutional (PAC) coding with variable lengths are disclosed. In one example aspect, a method for digital communication includes determining, by a first node, an output bit sequence having E bits based on an input bit sequence having K bits. The output bit sequence is determined based on a transform that is applied prior to applying a Polar transform having a size of N. The transform is based on at least one index set that is a subset of a set of bit indices. The set of bit indices comprises all non-negative integers that are less than N and wherein K<N and K<E. The method also includes transmitting, by the first node, a signal including the output bit sequence to a second node.

### CROSS-REFERENCE TO RELATED APPLICATIONS

This patent document is a continuation of and claims benefit of priority to International Patent Application No. PCT/CN2022/121869, filed on Sep. 27, 2022. The entire content of the before-mentioned patent application is incorporated by reference as part of the disclosure of this application.

### TECHNICAL FIELD

This patent document is directed to digital communications.

### BACKGROUND

Mobile communication technologies are moving the world toward an increasingly connected and networked society. The rapid growth of mobile communications and advances in technology have led to greater demand for capacity and connectivity. Other aspects, such as energy consumption, device cost, spectral efficiency, and latency are also important to meeting the needs of various communication scenarios. Various techniques, including new ways to provide higher quality of service, longer battery life, and improved performance are being discussed.

### SUMMARY

This patent document describes, among other things, techniques that related to Polarization-Adjusted Convolutional (PAC) coding with variable lengths are disclosed.

In one example aspect, a method for digital communication includes determining, by a first node, an output bit sequence having E bits based on an input bit sequence having K bits. The output bit sequence is determined based on a transform that is applied prior to applying a Polar transform having a size of N. The transform is based on at least one index set that is a subset of a set of bit indices. The set of bit indices comprises all non-negative integers that are less than N and wherein K<N and K<E. The method also includes transmitting, by the first node, a signal including the output bit sequence to a second node.

In another example aspect, a method for digital communication includes receiving, by a second node, a signal including an output bit sequence having E bits from a first node. The method also includes determining, by the second node, an input bit sequence having K bits by decoding the output bit sequence included in the signal. The input bit sequence is determined based on a transform that is applied after applying an inverse Polar transform having a size of N. The transform is based on at least one index set that is a subset of a set of bit indices. The set of bit indices comprises all non-negative integers that are less than N and wherein K<N and K<E.

In another example aspect, a communication apparatus is disclosed. The apparatus includes a processor that is configured to implement an above-described method.

In yet another example aspect, a computer-program storage medium is disclosed. The computer-program storage medium includes code stored thereon. The code, when executed by a processor, causes the processor to implement a described method.

These, and other, aspects are described in the present document.

### BRIEF DESCRIPTION OF THE DRAWINGS

FIG. 1 illustrates an example diagram of the Fifth Generation (5G) polar coding with rate matching.

FIG. 2 illustrates an example diagram of Polarization-adjusted convolutional (PAC) coding.

FIG. 3 illustrates an example of a convolution transform with a generator polynomial g(D).

FIG. 4A illustrates the factor graph of the Polar matrix G⁽³²⁾ of size N=32.

FIG. 4B illustrates the Polar matrix G⁽³²⁾.

FIG. 5A illustrates an example of polar coding in accordance with one or more embodiments of the present technology.

FIG. 5B illustrates another example of polar coding in accordance with one or more embodiments of the present technology.

FIG. 5C illustrates yet another example of polar coding in accordance with one or more embodiments of the present technology.

FIG. 6 illustrates an example diagram for a recursive convolution transform in accordance with one or more embodiments of the present technology.

FIG. 7 illustrates another example diagram for a recursive convolution transform in accordance with one or more embodiments of the present technology.

FIG. 8A illustrates an example of polar coding with pre-transform and rate matching in accordance with one or more embodiments of the present technology.

FIG. 8B illustrates another example of polar coding with pre-transform and rate matching in accordance with one or more embodiments of the present technology.

FIG. 8C illustrates yet another example of polar coding with pre-transform and rate matching in accordance with one or more embodiments of the present technology.

FIG. 9 illustrates a set of example block error rate (BLER) curves in accordance with one or more embodiments of the present technology.

FIG. 10 illustrates another set of example BLER curves in accordance with one or more embodiments of the present technology.

FIG. 11 illustrates another set of example BLER curves in accordance with one or more embodiments of the present technology.

FIG. 12 illustrates another set of example BLER curves in accordance with one or more embodiments of the present technology.

FIG. 13 illustrates another set of example BLER curves in accordance with one or more embodiments of the present technology.

FIG. 14 illustrates another set of example BLER curves in accordance with one or more embodiments of the present technology.

FIG. 15 illustrates another set of example BLER curves in accordance with one or more embodiments of the present technology.

FIG. 16 illustrates yet another set of example BLER curves in accordance with one or more embodiments of the present technology.

FIG. 17 is a flowchart representation of a method for wireless communication in accordance with one or more embodiments of the present technology.

FIG. 18 is a flowchart representation of another method for wireless communication in accordance with one or more embodiments of the present technology.

FIG. 19 shows an example of a wireless communication system where techniques in accordance with one or more embodiments of the present technology can be applied.

FIG. 20 is a block diagram representation of a portion of a radio station in accordance with one or more embodiments of the present technology can be applied.

### DETAILED DESCRIPTION

In the Fifth generation (5G) mobile communications standard of the Third Generation Partnership Project (3GPP), low-density parity-check (LDPC) codes are used for data transmission. However, LDPC codes does not perform as well as polar codes in short payload size (also referred to a transport block size, TBS). Also, LDPC codes have high error floors (e.g., at a block error rate, BLER, of 0.0001). To fulfill the future ultra-reliable low latency communication (URLLC), there is a need for more powerful channel coding.

Polarization-Adjusted Convolutional (PAC) codes can achieve finite-length bounds in moderate decoding complexity. As a result, PAC codes have code lengths of N as polar codes, where N=2ⁿ and n is a positive integer. However, the size of a payload, or a transport block (TB), in different wireless channel environments does not always have a code length of N=2ⁿ in time and frequency resources allocated by a base station (BS). Rate matching schemes are thus needed for applying PAC codes in wireless communications to efficiently transmit the payload. This patent document discloses techniques that can be implemented in various embodiments to enable variable lengths of PAC coding so as to adapt to the different payload sizes in wireless communications to improve efficiency.

Section headings below are used in the present document only to improve readability and do not limit scope of the disclosed embodiments and techniques in each section to only that section. Certain features are described using the example of 5G wireless protocol. However, applicability of the disclosed techniques is not limited to only 5G wireless systems.

### Notations

GF(2) denotes the Galois field of size 2 with two elements “0” and “1”.

br(i) denotes the bit-reversal function.

floor(x) denotes the largest integer not greater than x.

$$min ( x , y ) = \{ \begin{matrix}x , & x \leq y , \\ y , & y < x .\end{matrix}$$

min(x, y) denotes the minimum value between x and y,

mod(x, y) denotes the remainder of x divided by y. For example, mod(5, 3)=2 and mod(3, 5)=3.

X_{i,j} denotes the element in the i-th row and j-th column of a matrix X, where an boldface capital letter is used to represent a matrix.

[x₀, x₁, . . . , x_{Y-1}] denotes a sequence (or a vector) of length Y containing elements x₀, x₁, . . . , x_{Y-1}.

{x₀, x₁, . . . , x_{Y-1}} denotes a set with Y distinct elements x₀, x₁, . . . , x_{Y-1}, for any i≠j, xᵢ≠xⱼ.

<x₀, x₁, . . . , x_{Y-1}> denotes an ordered set with Y distinct elements x₀, x₁, . . . , x_{Y-1}, for any i≠j, xᵢ≠xⱼ. Let X=<x₀, x₁, . . . , x_{Y-1}>, X(i) denotes the i-th element xᵢ in the ordered set X.

For a set X, |X| denotes the set size (the number of elements in the set X).

Z_{N}={0, 1, . . . , N−2, N−1} denotes the integer set containing all non-negative integers smaller than N.

A matrix with Yr rows and Yc columns is called a Yr-by-Yc matrix.

An upper triangular matrix X with Yr rows and Yc is such that an element X_{i,j} in the i-th row and j-th column of the matrix X is 0 for any j<i with i being non-negative integers smaller than Yr and j being non-negative integers smaller than Yc, where Yr and Yc are positive integers.

Indices for sequences, vectors, or matrices are starting from zero.

Additional notations are listed in Table 1 below.

TABLE 1
Example Notations

| Notations | Meanings |
|---|---|
| [bₙ₋₁, bₙ₋₂, . . . , b₁, b₀] | n-bit binary expansion of an integer i |
| B^{(N)} | a bit-reversal permutation matrix with |
| | N rows and N columns |
| c = [c₀, c₁, . . . , c_{K-1}] | an input bit sequence; |
| | a precoding input bit sequence; |
| C | a convolution transform matrix of |
| | N rows and N columns |
| d = [d₀, d₁, . . . , d_{N-1}] | a polar transform output bit sequence; |
| | a rate matching input bit sequence; |
| | a bit selection input bit sequence; |
| | an interleaving input bit sequence; |
| d′ = [d′₀, d′₁, . . . , d′_{N-1}] | an interleaving output bit sequence; |
| | a bit selection input bit sequence; |
| D | a dummy variable representing delay |
| | in a digital circuit |
| e = [e₀, e₁, . . . , e_{E-1}] | an output bit sequence; |
| | a bit selection output bit sequence; |
| E | the length of an output bit sequence |
| f | a rate profiling frozen bit sequence |
| F | a rate profiling matrix with K rows |
| | and N columns |
| g(D) | a generator polynomial |
| | g(D) = g₀ + g₁ · D + . . . + gₘ · D^{m} over GF(2) |
| g = [g₀, g₁, . . . , gₘ] | a generator bit sequence defining a |
| | generator polynomial g(D) |
| G^{(N)} | a polar transform matrix with N rows |
| | and N columns |
| h | a precoding frozen bit sequence |
| i, j, k | index for an element in a sequence, |
| | a vector, a set or a matrix |
| J = [J₀, J₁, . . . , J_{N-1}] | an interleaver pattern |
| K | the length of an input bit sequence |
| L | L largest index in a set |
| m | the memory length of a convolution |
| | transform; |
| | the polynomial degree of a generator |
| | polynomial g(D); |
| | the polynomial degree of a recursive |
| | feedback polynomial q(D). |
| n | N = 2ⁿ, order of a polar matrix |
| N | the size of a polar matrix |
| Nᵣ | an ordered rate matching index |
| | set size |
| P_{I} | a precoding input index set |
| P_{O} | a precoding output index set |
| P^{(N)} | a core matrix of a polar matrix |
| π = [π₀, π₁, . . . , π₃₁] | a sub-block interleaver pattern |
| q = [q₀, q₁, . . . , qₘ] | a recursive feedback bit sequence |
| | over GF(2) |
| q(D) | a recursive feedback polynomial |
| | q(D) = q₀ + q₁ · D + . . . + qₘ · D^{m} over GF(2) |
| Q | a data bit index set, a subset of |
| | the set Z_{N} |
| Qₘₐₓ | an element that has a largest value in |
| | a data bit index set Q |
| R = <R(0), R(1), . . . , | an ordered rate matching index set |
| R(Nᵣ − 1)> | |
| Rₘₐₓ | an element that has a largest value in |
| | a ordered rate matching index set R |
| s | a summation bit |
| t = [t₀, t₁, . . . , tₘ₋₁, tₘ] | a state bit sequence |
| T | a pre-transform matrix with N rows |
| | and N columns |
| u = [u₀, u₁, . . . , u_{N-1}] | a polar transform input sequence; |
| | a convolution transform output |
| | bit sequence; |
| | a pre-transform output bit sequence; |
| | a precoding output bit sequence; |
| v = [v₀, v₁, . . . , v_{N-1}] | a rate-profiling output bit sequence; |
| | a convolution transform input bit |
| | sequence; |
| | a pre-transform input bit sequence; |
| W | a precoding matrix with K rows |
| | and N columns |
| x | any sequence or vector |
| X | any set |
| X | any matrix |
| y | any sequence or vector |
| Y | any sequence length or vector length |
| Z_{N} | a set containing non-negative integers |
| | smaller than N, {0, 1, . . . , N − 1} |

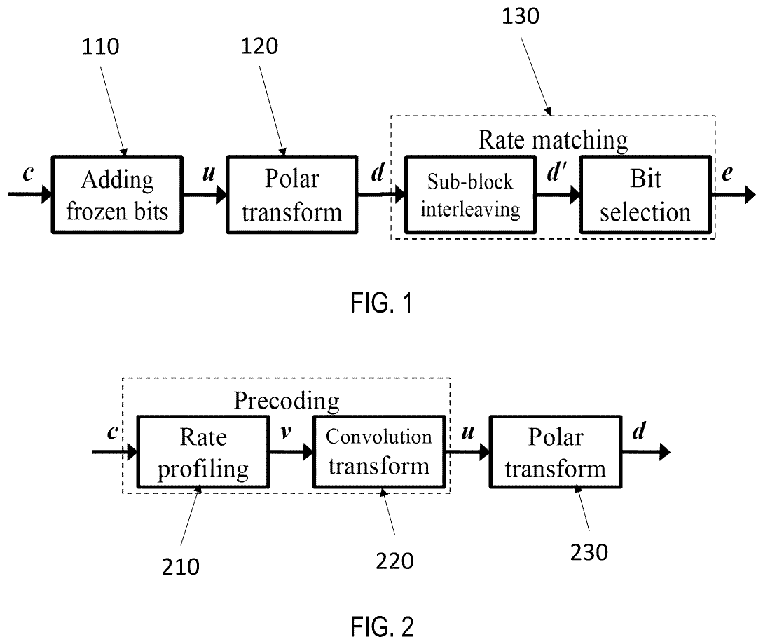

In the 3GPP 5G standard, polar codes are used in control channel transmissions. FIG. 1 illustrates an example diagram of 5G polar coding with rate matching. Denote Q as a data bit index set of size K, where |Q|=K, and where Q is a subset of an integer set Z_{N}={0, 1, . . . , N−2, N−1} containing all non-negative integers smaller than N. Then, the encoding of an input bit sequence c=[c₀, c₁, . . . , c_{K-2}, c_{K-1}] into an output bit sequence e=[e₀, e₁, . . . , e_{E-2}, e_{E-1}] for the 5G polar coding with a polar matrix G^{(N)} includes the following operations, where K is the length of the input bit sequence, E is the length of the output bit sequence, K and E are positive integers, K<N, and K<E.

Operation 110: Adding frozen bits. The adding-frozen-bits operation 110 combines N-K zero bits with the input bit sequence c to form a polar transform input sequence u=[u₀, u₁, . . . , u_{N-2}, u_{N-1}] of length N according to the data bit index set Q. The polar transform input sequence u is determined by the input bit sequence c, the data bit index set Q, and the polar matrix size N as follows.

```
k = 0;
For i = 0 to N−1
  If i ϵ Q
      uᵢ = cₖ,
      k = k + 1;
  Else
    uᵢ = 0;
  End if
End for
```

Operation 120: Polar transform. The polar transform operation 120 converts a first length-N bit sequence into a second length-N bit sequence by multiplying the first length-N bit sequence and the polar matrix G^{(N)} over GF(2). A polar transform output bit sequence d=[d₀, d₁, . . . , d_{N-2}, d_{N-1}] of length N is determined by the polar transform input sequence u and the polar matrix G^{(N)} as d=u·G^{(N)}, where the vector-matrix multiplication is over GF(2).

Operation 130: Rate matching. The rate matching operation of polar coding in 5G includes two operations: sub-block interleaving and bit selection.

(1) Sub-block interleaving: An interleaving output bit sequence d′=[d′₀, d′₁, . . . , d′_{N-2}, d′_{N-1}] of length N is determined by a sub-block interleaver pattern π of length 32, the polar transform output bit sequence d, and the polar matrix size N as follows.

```
For i = 0 to N−1
  j = floor(32i/N);
  Jᵢ = πⱼ×(N/32) + mod(i, N/32);
  d′ᵢ = d_{Ji};
End for
```

Here, π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31], and J=[J₀, J₁, . . . , J_{N-2}, J_{N-1}] is an interleaver pattern of length N determined by the sub-block interleaver pattern π and the polar matrix size N. The interleaver pattern J is a permutation of the integer sequence [0, 1, 2, . . . , N−2, N−1].

(2) Bit selection: There are three types of bit selection named as repetition, puncturing and shortening. With the interleaving output bit sequence d′, the length of the input bit sequence K, the length of the output bit sequence E, and the polar matrix size N, the output bit sequence e is determined as follows.

A. Repetition: For E≥N,

eₖ=d′_{mod(k,N)}, k=0, 1, 2, . . . , E−2, E−1.

B. Puncturing: For E<N and K|E≤ 7/16,

eₖ=d′_{N-E+k}, k=0, 1, 2, . . . , E−2, E−1.

C. Shortening: For E<N and K|E> 7/16,

eₖ=d′k, k=0, 1, 2, . . . , E−2, E−1.

Rate matching can also be alternatively described as follows. Denote R=<R(0), R(1), . . . , R(Nᵣ−2), R(Nᵣ−1)> as an ordered rate matching index set of size Nᵣ=min(E, N), where the ordered rate matching index set R is a subset of the integer set Z_{N}. Then, with the polar transform output bit sequence d, the ordered rate matching index set R, the length of the output bit sequence E, and the polar matrix size N, the output bit sequence e is determined as eₖ=d_{R(mod(k,N)}, k=0, 1, 2, . . . , E−2, E−1. Here, the ordered rate matching index set R=<J₀, J₁, . . . , J_{N-2}, J_{N-1}> for bit selection with repetition; the ordered rate matching index set R=<J_{N-E}, J_{N-E}+1, J_{N-E}+2, . . . , J_{N-2}, J_{N-1}> for bit selection with puncturing; and the ordered rate matching index set R=<J₀, J₁, . . . , J_{E-2}, J_{E-1}> for bit selection with shortening. J=[J₀, J₁, . . . , J_{N-2}, J_{N-1}] is the interleaver pattern of length N determined in the sub-block interleaving operation.

### PAC Coding

PAC codes is a class of pre-transformed polar codes. Specifically, PAC codes are polar codes using convolution transform. FIG. 2 illustrates an example diagram of PAC coding. Denote Q a data bit index set of size K, where |Q|=K, and where Q is a subset of an integer set Z_{N}={0, 1, . . . , N−2, N−1} containing all non-negative integers smaller than N. Then, the encoding of an input bit sequence c=[c₀, c₁, . . . , c_{K-2}, c_{K-1}] into an output bit sequence e=[e₀, e₁, . . . , e_{E-2}, e_{E-1}] by the polar matrix G^{(N)} includes the following operations, where K is the length of the input bit sequence, E is the length of the output bit sequence, K<N, K<E and K and E are positive integers.

Operation 210: Rate profiling. The rate profiling 210 shown in FIG. 2 is an operation same as the adding-frozen-bits operation in the 5G polar coding. The rate-profiling operation combines N-K zero bits with the input bit sequence c to form a rate-profiling output sequence v=[v₀, v₁, . . . , v_{N-2}, v_{N-1}] of length N according to the data bit index set Q. Specifically, the rate-profiling output bit sequence v is determined by the input bit sequence c, the data bit index set Q, and the polar matrix size N as follows.

```
k = 0;
For i = 0 to N−1
  If i ϵ Q
      vᵢ = cₖ,
      k = k + 1;
  Else
    vᵢ = 0;
  End if
End for
```

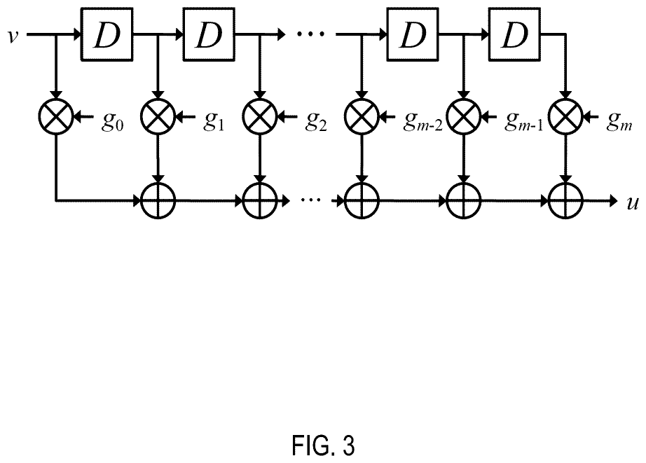

Operation 220: Convolution transform. The convolution transform 220 shown in FIG. 2 is an operation converting a convolution input bit sequence of length N into a convolution output bit sequence of length N by performing convolution on the convolution input bit sequence and a generator bit sequence g=[g₀, g₁, . . . , gₘ₋₁, gₘ] of length-(m+1) that defines a generator polynomial g(D)=g₀+g₁·D+ . . . +gₘ₋₁·Dₘ₋₁+gₘ·D^{m} over GF(2). Here, m is the memory length of the convolution transform or equivalently the generator polynomial degree of the generator polynomial g(D). D is a dummy variable representing delay in a digital circuit. FIG. 3 illustrates an example of a convolution transform with a generator polynomial g(D). Specifically, a convolution transform output bit sequence u=[u₀, u₁, . . . , u_{N-2}, u_{N-1}] of length N is determined by the rate-profiling output bit sequence v, the generator polynomial g(D) (or equivalently the generator bit sequence g) and the polar matrix size N as follows.

```
For i = 0 to N−1
  uᵢ = 0;
  For k = 0 to m
    uᵢ = mod(uᵢ + gₖ·vᵢ₋ₖ, 2);
  End for
End for
```

where vᵢ₋ₖ=0 if i<k.

Operation 230: Polar transform. The polar transform 230 as shown in FIG. 2 is the same as in the 5G polar coding. A polar transform output bit sequence d=[d₀, d₁, . . . , d_{N-2}, d_{N-1}] of length N is determined according to the convolution transform output bit sequence u and the polar matrix G^{(N)} as d=u·G^{(N)}, where the vector-matrix multiplication is over GF(2).

A Rate Profiling and a Convolution Transform Combines into a Precoding

The combination of a rate profiling and a convolution transform is a precoding for PAC codes, specifically a convolution precoding, where the precoding input bit sequence is the input bit sequence c=[c₀, c₁, . . . , c_{K-2}, c_{K-1}] of length K and the precoding output bit sequence is the convolution transform output bit sequence u=[u₀, u₁, . . . , u_{N-2}, u_{N-1}] of length N. Define a state bit sequence t=[t₀, t₁, t₂, . . . , tₘ₋₁, tₘ] of length m+1. The precoding output bit sequence u is determined by the precoding input sequence c, the data bit index set Q of size K, the generator bit sequence g=[g₀, g₁, . . . , gₘ₋₁, gₘ] of length-(m+1) corresponding to the generator polynomial g(D)=g₀+g₁·D+ . . . +gₘ₋₁·Dₘ₋₁+gₘ·D^{m} over GF(2), and the polar matrix size N is as follows.

```
For j = 0 to m
  tⱼ = 0;
End for
k = 0;
For i = 0 to N−1
    If i ϵ Q
        t₀ = cₖ,
        k = k + 1;
    Else
      t₀ = 0;
    End if
    uᵢ = g₀·t₀;
    For j = 1 to m
        uᵢ = mod(uᵢ + gⱼ·tⱼ, 2);
    End for
    For j = m to 1
        tⱼ = tⱼ₋₁;
    End for
End for
```

### Vector-Matrix Multiplication Description for Rate Profiling of PAC Coding

The rate profiling operation in PAC coding can be described as vector-matrix multiplication over GF(2). Specifically, the rate-profiling output bit sequence v is determined by the input bit sequence c as: v=c·F, where F is a rate profiling matrix with K rows and N columns defined by the data bit index set Q of size K with the following properties.
(1) The rate profiling matrix F contains all K rows in an N-by-N identity matrix with row indices belonging to the data bit index set Q;
(2) F_{i,j}=0 for any i and j with 0<j<i<N, where F_{i,j} is the element in the i-th row and j-th column of the rate profiling matrix F.

For example, for K=4, N=8 and Q={3, 5, 6, 7}, the rate profiling matrix F is a matrix with 4 rows and 8 columns as follow.

$$F = [ \begin{matrix}0 & 0 & 0 & 1 & 0 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1\end{matrix} ]$$

### Vector-Matrix Multiplication Description for the Convolution Transform of PAC Coding

Similar to rate profiling, the convolution transform in PAC coding can be described as vector-matrix multiplication over GF(2). Specifically, the convolution transform output bit sequence u of length N is determined by the convolution transform input bit sequence of length N (the rate profiling output bit sequence v of length N) as u=v·C, where C is a convolution transform matrix of N rows and N columns defined by the generator polynomial g(D)=g₀+g₁·D+ . . . +gₘ₋₁·Dₘ₋₁+gₘ·D^{m} (or equivalently the generator bit sequence g=[g₀, g₁, . . . , gₘ₋₁, gₘ] of length-(m+1)) and the polar matrix size N. The convolution transform matrix C is a Toeplitz matrix defined as

$${C}_{i , j} = \{ \begin{matrix}{g}_{j - i} , & 0 \leq j - i \leq m , \\ 0 , & otherwise ,\end{matrix}$$

for i=0, 1, 2, . . . , N−1 and j=0, 1, 2, . . . , N−1, where C_{i,j} is the element in the i-th row and j-th column of the convolution transform matrix C. Written in matrix form, the convolution transform matrix C is as follow.

$$C = [ \begin{matrix}{g}_{0} & {g}_{1} & … & {g}_{m} & 0 & 0 & … & 0 \\ 0 & {g}_{0} & {g}_{1} & … & {g}_{m} & 0 & … & 0 \\ ⋮ & ⋱ & ⋱ & ⋱ & ⋱ & ⋱ & ⋱ & ⋮ \\ 0 & … & 0 & {g}_{0} & {g}_{1} & … & {g}_{m} & 0 \\ 0 & 0 & … & 0 & {g}_{0} & {g}_{1} & … & {g}_{m} \\ ⋮ & ⋱ & ⋱ & ⋱ & ⋱ & ⋱ & ⋱ & ⋮ \\ 0 & … & … & … & … & 0 & {g}_{0} & {g}_{1} \\ 0 & 0 & … & … & … & … & 0 & {g}_{0}\end{matrix} ]$$

For example, for N=8 and a generator polynomial g(D)=g₀+g₁·D+g₂·D²+g₃·D³=1+D²+D³ with a generator bit sequence g=[g₀, g₁, g₂, g₃]=[1, 0, 1, 1] and a memory length m=3, the 8-by-8 convolution transform matrix C is as follows.

$$C = [ \begin{matrix}{g}_{0} & {g}_{1} & {g}_{2} & {g}_{3} & 0 & 0 & 0 & 0 \\ 0 & {g}_{0} & {g}_{1} & {g}_{2} & {g}_{3} & 0 & 0 & 0 \\ 0 & 0 & {g}_{0} & {g}_{1} & {g}_{2} & {g}_{3} & 0 & 0 \\ 0 & 0 & 0 & {g}_{0} & {g}_{1} & {g}_{2} & {g}_{3} & 0 \\ 0 & 0 & 0 & 0 & {g}_{0} & {g}_{1} & {g}_{2} & {g}_{3} \\ 0 & 0 & 0 & 0 & 0 & {g}_{0} & {g}_{1} & {g}_{2} \\ 0 & 0 & 0 & 0 & 0 & 0 & {g}_{0} & {g}_{1} \\ 0 & 0 & 0 & 0 & 0 & 0 & 0 & {g}_{0}\end{matrix} ] = [ \begin{matrix}1 & 0 & 1 & 1 & 0 & 0 & 0 & 0 \\ 0 & 1 & 0 & 1 & 1 & 0 & 0 & 0 \\ 0 & 0 & 1 & 0 & 1 & 1 & 0 & 0 \\ 0 & 0 & 0 & 1 & 0 & 1 & 1 & 0 \\ 0 & 0 & 0 & 0 & 1 & 0 & 1 & 1 \\ 0 & 0 & 0 & 0 & 0 & 1 & 0 & 1 \\ 0 & 0 & 0 & 0 & 0 & 0 & 1 & 0 \\ 0 & 0 & 0 & 0 & 0 & 0 & 0 & 1\end{matrix} ]$$

### Vector-Matrix Multiplication Description for the Precoding of PAC Coding

With the rate profiling matrix F and the convolution transform matrix C, the precoding of PAC coding is u=c·W=c·F·C, where u is a precoding output bit sequence of length N, the input bit sequence c is a precoding input bit sequence of length K, and the matrix multiplication and the vector-matrix multiplication is over GF(2). W=F·C is the precoding matrix of PAC coding. The precoding matrix W is an upper triangular matrix with K rows and N columns such that an element W_{i,j} in the i-th row and j-th column of the precoding matrix W is 0 for any j<i with i and j being non-negative integers smaller than N.

With the rate profiling matrix F and the convolution transform matrix C above, the precoding matrix W=F·C of PAC coding is as follows.

$$W = F \cdot C = [ \begin{matrix}0 & 0 & 0 & 1 & 0 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1\end{matrix} ] \cdot [ \begin{matrix}1 & 0 & 1 & 1 & 0 & 0 & 0 & 0 \\ 0 & 1 & 0 & 1 & 1 & 0 & 0 & 0 \\ 0 & 0 & 1 & 0 & 1 & 1 & 0 & 0 \\ 0 & 0 & 0 & 1 & 0 & 1 & 1 & 0 \\ 0 & 0 & 0 & 0 & 1 & 0 & 1 & 1 \\ 0 & 0 & 0 & 0 & 0 & 1 & 0 & 1 \\ 0 & 0 & 0 & 0 & 0 & 0 & 1 & 0 \\ 0 & 0 & 0 & 0 & 0 & 0 & 0 & 1\end{matrix} ] = [ \begin{matrix}0 & 0 & 0 & 1 & 0 & 1 & 1 & 0 \\ 0 & 0 & 0 & 0 & 0 & 1 & 0 & 1 \\ 0 & 0 & 0 & 0 & 0 & 0 & 1 & 0 \\ 0 & 0 & 0 & 0 & 0 & 0 & 0 & 1\end{matrix} ]$$

Referring back to FIG. 1, using the disclosed techniques, the output bit sequence e is determined by the first node by at least one of the following: a data index set Q, a rate profiling frozen bit sequence f, a rate profiling matrix F with K rows and N columns, a generator bit sequence g=[g₀, g₁, . . . , gₘ] over GF(2), a generator polynomial g(D)=g₀+g₁·D+ . . . +gₘ₋₁·Dₘ₋₁+gₘ·D^{m} over GF(2), a recursive feedback bit sequence q=[q₀, q₁, . . . , qₘ] over GF(2), a recursive feedback polynomial q(D)=q₀+q₁·D+ . . . +qₘ·D^{m} over GF(2), a state bit sequence t=[t₀, t₁, . . . , tₘ₋₁, tₘ] of length m+1, a pre-transform matrix T with N rows and N columns, a precoding matrix W with K rows and N columns, a precoding input index set P_{I}, a precoding output index set P_{O}, a precoding frozen bit sequence h, a polar matrix G^{(N)} with N rows and N columns, or an ordered rate matching index set R=<R(0), R(1), . . . , R(Nᵣ−2), R(Nᵣ−1)>. Here, m is the memory length for one of the following: the generator bit sequence g, the generator polynomial g(D), the recursive feedback bit sequence q, the recursive feedback polynomial q(D), the state bit sequence t; Nᵣ is the ordered rate matching index set size and Nᵣ is equal to the minimum value between N and E, Nᵣ=min(N, E); Q, P_{I}, P_{O}, and R are subsets of a first integer set Z_{N}={0, 1, 2, . . . , N−2, N−1}. The first integer set Z_{N}={0, 1, 2, . . . , N−2, N−1} contains all non-negative integers small than N.

Details about the above sets, sequences, matrices, and/or polynomials are further discussed below.

The data index set Q: The data index set Q is a subset of the first integer set Z_{N}, wherein the number of elements in the data index set Q is equal to the length of the input bit sequence K (the data index set Q has K elements, or say, the data index set size is K). Elements in the data index set Q are non-negative integers smaller than the polar matrix size N. In a first specific example with N=8 and K=4, a data index set is Q={3, 5, 6, 7}. In a second specific example with N=32 and K=25, a data index set is Q={5, 9, 6, 17, 10, 18, 12, 20, 24, 7, 11, 19, 13, 14, 21, 26, 25, 22, 28, 15, 23, 31, 27, 29, 30}.

The rate profiling frozen bit sequence f: In some embodiments, the rate profiling frozen bit sequence f can be any bit sequence of length N-K. In a specific example with N=8 and K=3, a rate profiling frozen bit sequence is f=[1, 1, 0, 0, 1]. In another specific example with N=8 and K=3, a rate profiling frozen bit sequence is f=[0, 0, 0, 0, 0]. In a third specific example with N=32 and K=25, a rate profiling frozen bit sequence f is an all-zero bit sequence of length N-K=32-25=7. In some embodiments, the rate profiling frozen bit sequence f can be any bit sequence of length N. In a specific example with N=8, a rate profiling frozen bit sequence is f=[0, 0, 0, 1, 1, 1, 0, 1]. In another specific example with N=8, a rate profiling frozen bit sequence is f=[0, 0, 0, 0, 0, 0, 0, 0]. In a third specific example with N=32, a rate profiling frozen bit sequence f is an all-zero bit sequence of length N=32.

The rate profiling matrix F: The rate profiling matrix F is an upper triangular matrix with K rows and N columns having the following properties.
(1) F_{i,j}=0 for any integers i and j with 0≤j<i<K, wherein F_{i,j} is the element in the i-th row and the j-th column of the rate profiling matrix F;
(2) The rate profiling matrix F contains N-K all-zero columns;
(3) The rate profiling matrix F contains K columns with only one non-zero element “1”, wherein the K columns with only one non-zero element “1” comprises an identity matrix with K rows and K columns.

In a specific example with K=4 rows and N=8 columns, a rate profiling matrix F is as follows.

$$F = [ \begin{matrix}0 & 0 & 0 & 1 & 0 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1\end{matrix} ] ,$$

The 0^{th}, 1^{st}, 2^{nd} and 4^{th} columns are all-zero columns, and the 3^{rd}, 5^{th}, 6^{th} and 7^{th} columns has only one non-zero element “1” and comprises an identity matrix with K=4 rows and K=4 columns as

$$[ \begin{matrix}1 & 0 & 0 & 0 \\ 0 & 1 & 0 & 0 \\ 0 & 0 & 1 & 0 \\ 0 & 0 & 0 & 1\end{matrix} ] .$$

The generator bit sequence g: The generator bit sequence g=[g₀, g₁, . . . , gₘ] can be any binary sequence of length m+1, wherein m is called the memory length. In a specific example with a memory length m=6, a generator bit sequence is g=[g₀, g₁, g₂, g₃, g₄, g₅, g₆]=[1, 0, 1, 1, 0, 1, 1]. In another specific example with a memory length m=3, a generator bit sequence is g=[g₀, g₁, g₂, g₃]=[1, 1, 0, 1].

The generator polynomial g(D): The generator polynomial g(D)=g₀+g₁·D+ . . . +gₘ₋₁·Dₘ₋₁+gₘ·D^{m} can be any binary polynomial over GF(2), wherein m is the generator polynomial degree. In a specific example with a memory length m=6, a generator polynomial is g(D)=g₀+g₁·D+g₂·D²+g₃·D³+g₄·D++g₅·D⁵+g₆·D⁶=1+0. D+1·D²⁺¹·D³⁺⁰·D⁴⁺¹·D⁵⁺¹·D⁶=1+D²+D³+D⁵+D⁶. In another specific example with a memory length m=3, a generator polynomial is g(D)=g₀+g₁·D+g₂·D²+g₃·D³=1+1·D+0·D²⁺¹·D³=1+D+D³.

The recursive feedback bit sequence q: The recursive feedback bit sequence q=[q₀, q₁, . . . , qₘ] is a binary sequence of length m+1 with [q₁, . . . , qₘ] being any binary sequence of length m and q₀=1, wherein m is the memory length. In a specific example with a memory length m=3, a recursive feedback bit sequence is q=[q₀, q₁, q₂, q₃, q₄, q₅, q₆]=[1, 0, 1, 0, 1, 1, 1]. In another specific example with a memory length m=3, a recursive feedback bit sequence is q=[q₀, q₁, q₂, q₃]=[1, 0, 1, 1].

The recursive feedback polynomial q(D): The recursive feedback polynomial q(D)=q₀, +q₁·D+ . . . +qₘ₋₁·Dₘ₋₁+qₘ·D^{m} is a binary polynomial with the zero-degree coefficient q₀ being 1 and other coefficients q₁, . . . , qₘ being any binary values over GF(2), wherein m is the memory length. In a specific example with a memory length m=6, a recursive feedback polynomial is q(D)=q₀+q₁·D+q₂·D²+q₃·D³+q₄·D⁴+q₅·D⁵+q₆·D⁶=1+0·D+1·D²⁺⁰·D³⁺¹·D⁴⁺¹·D⁵⁺¹·D⁶=1+D²+D⁴+D⁵+D⁶. In another specific example with a memory length m=3, a recursive feedback polynomial is q(D)=q₀+q₁·D+92·D²+q₃·D³=1+0·D+1·D²⁺¹·D³=1+D²+D³.

The state bit sequence t: The state bit sequence t is for storing the convolution state.

The pre-transform matrix T: The pre-transform matrix T is a binary upper triangular matrix with N rows and N columns satisfying the following: T_{i,j}=0 for any integers i and j with 0≤j<i<N, wherein T_{i,j} is the element in the i-th row and the j-th column of the pre-transform matrix T.

Row properties of the pre-transform matrix T: In some embodiments, the pre-transform matrix T has N−Nᵣ rows with all elements being zero, wherein Nᵣ is the size of the ordered rate matching index set. In some embodiments, for a row index i not belonging to the ordered rate matching index set R, all elements in the i-th row of the pre-transform matrix T are zero. In some embodiments, the pre-transform matrix T has N−1−Qₘₐₓ rows with all elements being zero, wherein Qₘₐₓ is an element that has a largest value in the data index set Q with

$${Q}_{max} = {max}_{k ∈ Q} k .$$

In some embodiments, the pre-transform matrix T has all elements in the last N−1−Qₘₐₓ rows being zero, wherein Qₘₐₓ is an element that has a largest value in the data index set Q with

$${Q}_{max} = {max}_{k ∈ Q} k .$$

In some embodiments, the pre-transform matrix T has all elements in the i-th rows being zero for i being larger than Qₘₐₓ, wherein Qₘₐₓ is an element that has a largest value in the data index set Q with

$${Q}_{max} = {max}_{k ∈ Q} k .$$

In some embodiments, the pre-transform matrix T has N−1−Rₘₐₓ rows with all elements being zero, wherein Rₘₐₓ is an element that has a largest value in the ordered rate matching index set R with

$${R}_{max} = {max}_{k ∈ R} k .$$

In some embodiments, the pre-transform matrix T has all elements in the last N−1−Rₘₐₓ rows being zero, wherein Rₘₐₓ is an element that has a largest value in the ordered rate matching index set R with

$${R}_{max} = {max}_{k ∈ R} k .$$

In some embodiments, the pre-transform matrix T has all elements in the i-th rows being zero for i being larger than Rₘₐₓ, wherein Rₘₐₓ is an element that has a largest value in the data index set R with

$${R}_{max} = {max}_{k ∈ R} k .$$

Column properties of the pre-transform matrix T: In some embodiments, the pre-transform matrix T has N−Nᵣ columns with all elements being zero, wherein Nᵣ is the ordered rate matching index set size. In some embodiments, for a column index j not belonging to the ordered rate matching index set R, all elements in the j-th column of the pre-transform matrix T are zero. In some embodiments, the pre-transform matrix T has N−1-Qₘₐₓ columns with all elements being zero, wherein Qₘₐₓ is an element that has a largest value in the data index set Q with

$${Q}_{max} = {max}_{k ∈ Q} k .$$

In some embodiments, the pre-transform matrix T has all elements in the last N−1-Qₘₐₓ columns being zero, wherein Qₘₐₓ is an element that has a largest value in the data index set y with

$${Q}_{max} = {max}_{k ∈ Q} k .$$

In some embodiments, the pre-transform matrix T has all elements in the j-th column being zero for j being larger than Qₘₐₓ, wherein Qₘₐₓ is an element that has a largest value in the data index set Q with

$${Q}_{max} = {max}_{k ∈ Q} k .$$

In some embodiments, the pre-transform matrix T has N−1−Rₘₐₓ columns with all elements being zero, wherein Rₘₐₓ is an element that has a largest value in the ordered rate matching index set R with

$${R}_{max} = {max}_{k ∈ R} k .$$

In some embodiments, the pre-transform matrix T has all elements in the last N−1−Rₘₐₓ columns being zero, wherein Rₘₐₓ is an element that has a largest value in the ordered rate matching index set R with

$${R}_{max} = {max}_{k ∈ R} k .$$

In some embodiments, the pre-transform matrix T has all elements in the j-th column being zero for j being larger than Rₘₐₓ, wherein Rₘₐₓ is an element that has a largest value in the data index set R with

$${R}_{max} = {max}_{k ∈ R} k .$$

The precoding matrix W: The precoding matrix W is a binary upper triangular matrix with K rows and N columns having the following properties: W_{i,j}=0 for any integers i and j with 0≤ j<i<K, where W_{i,j} is the element in the i-th row and j-th column of the precoding matrix W.

In some embodiments, the precoding matrix W has at least N−Nᵣ columns with all elements being zero, wherein Nᵣ is the set size of the ordered rate matching index set R. In some embodiments, for a column index j not belonging to the ordered rate matching index set R, all elements in the j-th column of the precoding matrix W are zero.

In some embodiments, the precoding matrix W has at least N−1−Rₘₐₓ columns with all elements being zero, wherein Rₘₐₓ is an element that has a largest value in the data index set R with

$${R}_{max} = {max}_{k ∈ R} k .$$

In some embodiments, for a column index j larger than Rₘₐₓ, all elements in the j-th column of the precoding matrix W are zero, wherein Rₘₐₓ is an element that has a largest in the data index set R with

$${R}_{max} = {max}_{k ∈ R} k .$$

The ordered rate matching index set R: The ordered rate matching index set R can be any subset of the first integer set Z_{N} having Nᵣ elements, wherein Nᵣ=min(N, E) and elements in the ordered rate matching index set R are non-negative integers smaller than the polar matrix size N. A first specific example of the ordered rate matching index set R is of size Nᵣ=N and R contains all elements in the first integer set Z_{N}, wherein R=<R(0), R(1), R(2), . . . , R(Nᵣ−2), R(Nᵣ−1)>=<0, 1, 2, . . . , N−2, N−1>. A second specific example of the ordered rate matching index set R is of size Nᵣ=E and R contains all non-negative integers smaller than E: R=<R(0), R(1), R(2), . . . , R(Nᵣ−2), R(Nᵣ−1)>=<0, 1, 2, . . . , E−2, E−1>. A third specific example of the ordered rate matching index set R is of size Nᵣ=E and R contains all integers smaller than N and larger than N−E−1: R=<R(0), R(1), R(2), . . . , R(Nᵣ−2), R(Nᵣ−1)>=<N−E, N−E+1, N−E+2, . . . , N−2, N−1>. Let J=[J₀, J₁, . . . , J_{N-2}, J_{N-1}] be an interleaver pattern of length N determined by the sub-block interleaver pattern π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] and the polar matrix size N as follows. Here, J=[J₀, J₁, . . . , J_{N-2}, J_{N-1}] is an interleaver pattern that is a permutation of the integer sequence [0, 1, 2, . . . , N−2, N−1], wherein a specific example of J is defined as follows.

```
For i = 0 to N−1
  j = floor(32i/N);
  Jᵢ = πⱼ×(N/32) + mod(i, N/32);
  d′ᵢ = d_{Ji};
End for
```

A fourth specific example of the ordered rate matching index set R is of size Nᵣ=N and R contains all elements in the first integer set Z_{N}. R=<R(0), R(1), R(2), . . . , R(Nᵣ−2), R(Nᵣ−1)>=<J₀, J₁, . . . , J_{N-2}, J_{N-1}>; wherein, Jᵢ is the i-th element in the interleaver pattern J=[J₀, J₁, . . . , J_{N-2}, J_{N-1}]. A fifth specific example of the ordered rate matching index set R is of size Nᵣ=E and R contains all elements in the interleaver pattern J with indices smaller than E. R=<R(0), R(1), R(2), . . . , R(Nᵣ−2), R(Nᵣ−1)>=<J₀, J₁, . . . , J_{E-2}, J_{E-1}>, wherein, J; is the i-th element in the interleaver pattern J=[J₀, J₁, . . . , J_{N-2}, J_{N-1}]. A sixth specific example of the ordered rate matching index set R is of size Nᵣ=E and R contains all elements in the interleaver pattern J with indices larger than N−E−1 and smaller than N. R=<R(0), R(1), R(2), . . . , R(Nᵣ−2), R(Nᵣ−1)>=<J_{N-E}, J_{N-E}+1, J_{N-E}+2, . . . , J_{N-2}, J_{N-1}>, wherein, Jᵢ is the i- th element in the interleaver pattern J=[J₀, J₁, . . . , J_{N-2}, J_{N-1}].

The precoding input set P_{I}: The precoding input index set P_{I} can be any subset of the first integer set Z_{N}. The precoding input set P_{I} can be used in a pre-transform operation of precoding to enable variable lengths so as to improve transmission efficiency of the payload.

A first specific example of the precoding input index set P_{I} is P_{I} equal to the first integer set Z_{N}. A second specific example of the precoding input index set P_{I} is that P_{I} consists of all non-negative integers not greater than Qₘₐₓ, P_{I}={0, 1, 2, . . . , Qₘₐₓ−1, Qₘₐₓ} with Qₘₐₓ+1 elements, wherein Qₘₐₓ is an element that has the largest value in the data index set Q with

$${Q}_{max} = {max}_{k ∈ Q} k .$$

A third specific example of the precoding input index set P_{I} is P_{I} equal to the ordered rate matching index set R. A fourth specific example of the precoding input index set P_{I} is that P_{I} consists of all non-negative integers not greater than Rₘₐₓ, P_{I}={0, 1, 2, . . . , Rₘₐₓ−1, Rₘₐₓ} with Rₘₐₓ+1 elements, wherein Rₘₐₓ is an element that has the largest value in the ordered rate matching index set R with

$${R}_{max} = {max}_{k ∈ R} k .$$

The precoding output set P_{O}: The precoding output index set P_{O} can be any subset of the first integer set Z_{N}. The precoding output index set P_{O} can be used in a pre-transform operation of precoding to enable variable lengths so as to improve transmission efficiency of the payload.

A first specific example of the precoding output index set P_{O} is P_{O} equal to the first integer set Z_{N}. A second specific example of the precoding output index set P_{O} is that P_{O} consists of all non-negative integers not greater than Qₘₐₓ, P_{O}={0, 1, 2, . . . , Qₘₐₓ−1, Qₘₐₓ} with Qₘₐₓ+1 elements, wherein Qₘₐₓ is the element with largest value in the data index set Q with

$${Q}_{max} = {max}_{k ∈ Q} k .$$

A third specific example of the precoding output index set P_{O} is P_{O} equal to the ordered rate matching index set R. A fourth specific example of the precoding output index set P_{O} is that P_{O} consists all non-negative integers not greater than Rₘₐₓ, P_{O}={0, 1, 2, . . . , Rₘₐₓ−1, Rₘₐₓ} with Rₘₐₓ+1 elements, wherein Rₘₐₓ is the element with largest value in the ordered rate matching index set R with

$${R}_{max} = {max}_{k ∈ R} k .$$

The precoding frozen bit sequence h: In some embodiments, the precoding frozen bit sequence h can be any bit sequence of length N−N_{PO}, wherein N_{PO} is the size of the precoding output index set P_{O} and N is the polar matrix size. A specific example with N=8 and N_{PO}=5, the precoding frozen bit sequence is h=[1, 0, 1] of length N−N_{PO}=8−5=3. Another specific example with N=32 and N_{PO}=5, the precoding frozen bit sequence h is an all-zero sequence of length N−N_{PO}=32-5=27.

In some embodiments, the precoding frozen bit sequence h can be any bit sequence of length N, wherein N is the polar matrix size. A specific example with N=8, the precoding frozen bit sequence is h=[0, 0, 0, 0, 0, 1, 0, 1] of length N=8. Another specific example with N=32, the precoding frozen bit sequence h is an all-zero sequence of length N=32.

The polar matrix G^{(N)}: The polar matrix G^{(N)} with N rows and N columns is one of the following: (1) G^{(N)}=(P⁽²⁾)^{⊗n}; (2) G^{(N)}=B^{(N)}·(P⁽²⁾)^{⊗n}; (3) G^{(N)}=P(N); or (4) G^{(N)}=B^{(N)}·P^{(N)}, where the matrix operation is over GF(2),

$${P}^{( N )} = [ \begin{matrix}{P}^{( N / 2 )} & 0 \\ {P}^{( N / 2 )} & {P}^{( N / 2 )}\end{matrix} ] , {P}^{( 2 )} = [ \begin{matrix}1 & 0 \\ 1 & 1\end{matrix} ] , {( {P}^{( 2 )} )}^{⊗ n}$$

is the n-th Kronecker power of the matrix P⁽²⁾, and B^{(N)} is a bit-reversal permutation matrix with N rows and N columns. 0 is an all-zero matrix with N/2 rows and N/2 columns. Let B_{i,j}^{(N)} be the element at the i-th row and j-th column of the bit-reversal permutation matrix B^{(N)}. Then, we have

$${B}_{i , j}^{( N )} = \{ \begin{matrix}1 , & j = br ( i ) , \\ 0 , & j \neq br ( i ) ,\end{matrix}$$

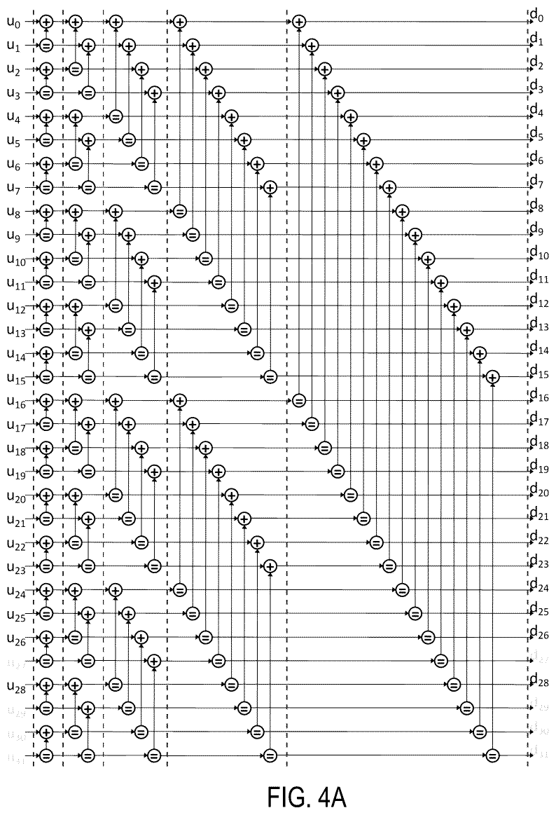

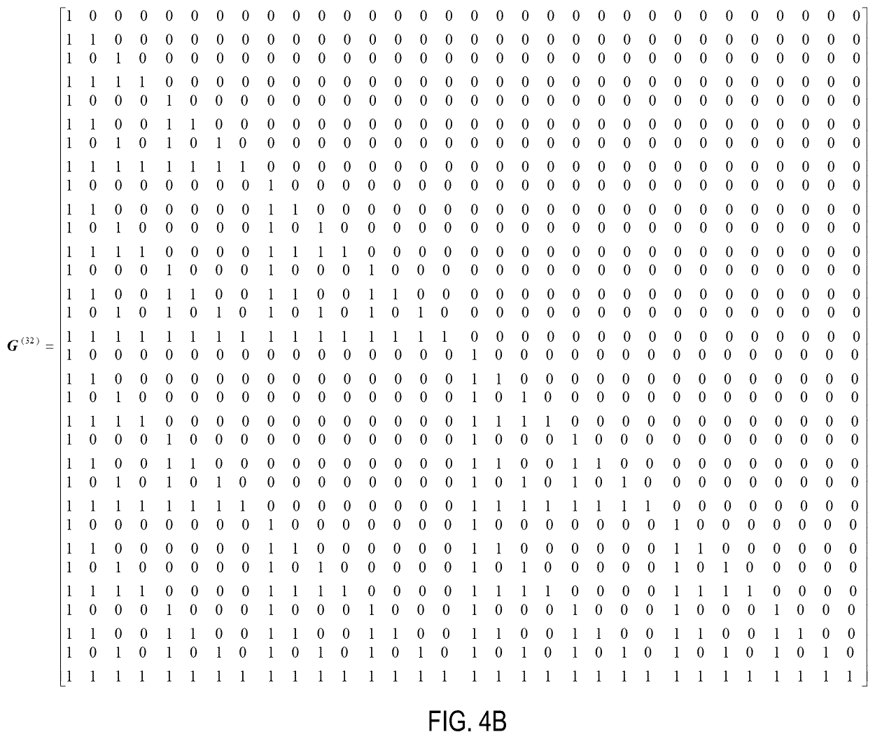

for 0<i<N and 0<j<N, where br(i) is the bit-reversal function defined as br(i)=Σₖ₌₀ⁿ⁻¹bₖ·2^{n-1-k} and [bₙ₋₁, bₙ₋₂, . . . , b₁, b₀] is the n-bit binary expansion of the integer i=Σₖ₌₀ⁿ⁻¹bₖ·2^{k}. A sequence (or a vector) x of length N over GF(2) multiplying the polar matrix G^{(N)} over GF(2) is called a polar transform on the sequence (vector) x. Denote y=x·G^{(N)}, where the vector-matrix multiplication is performed over GF(2). Then, y is the polar transform of x. FIG. 4A illustrates the factor graph of the polar matrix G⁽³²⁾ of size N=32, where the matrix G⁽³²⁾ is shown in FIG. 4B.

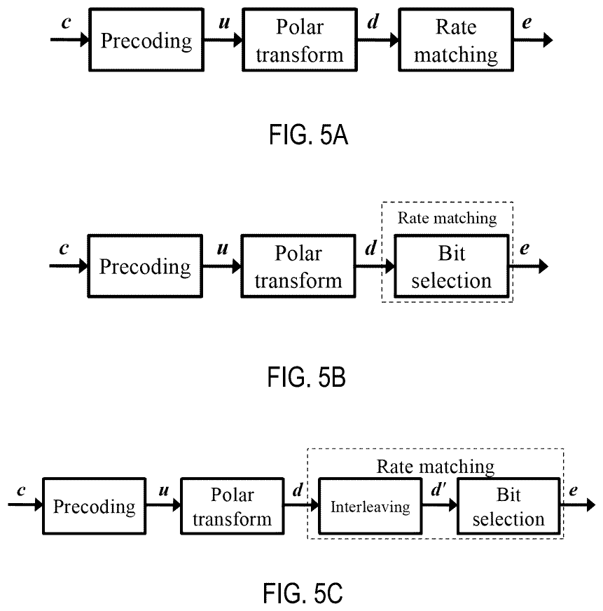

FIGS. 5A-5C illustrate examples of polar coding in accordance with one or more embodiments of the present technology. In some embodiments, the precoding comprises obtaining a precoding input bit sequence, and determining a precoding output bit sequence u=[u₀, u₁, . . . , u_{N-1}], wherein the precoding input bit sequence is the input bit sequence c of length K and the precoding output bit sequence u is of length equal to the polar matrix size N. In some embodiments, as shown in FIGS. 5A-5C, the output bit sequence e=[e₀, e₁, . . . , e_{E-1}] is determined by setting the input bit sequence c of length K as the precoding input bit sequence and determining a precoding output bit sequence u of length N using at least one of the following: the data index set Q, the rate profiling frozen bit sequence f, the rate profiling matrix F with K rows and N columns, the generator bit sequence g=[g₀, g₁, . . . , gₘ], the generator polynomial g(D)=g₀+g₁·D+ . . . +gₘ₋₁·Dₘ₋₁+gₘ·D^{m} over GF(2), the recursive feedback bit sequence q=[q₀, g₁, . . . , qₘ], the recursive feedback polynomial q(D)=q₀+q₁·D+ . . . +qₘ·D^{m} over GF(2), the pre-transform matrix T with N rows and N columns, the precoding matrix W with K rows and N columns, the precoding input index set P_{I}, the precoding output index set P_{O}, the precoding frozen bit sequence h.

### Properties of the Precoding Output Bit Sequence u

In some embodiments, the i-th bit uᵢ in the precoding output sequence u is determined by a subset of elements in the precoding input bit sequence c with indices in the integer set {0, 1, 2, . . . , i−1, i}, all non-negative integers not greater than i.

In some embodiments, the i-th bit uᵢ in the precoding output sequence u is a linear combination over GF(2) of elements c₀, c₁, c₂, . . . , cᵢ₋₁, cᵢ in the precoding input bit sequence c.

In some embodiments, the i-th output bit uᵢ in the precoding output sequence u of length N is determined by a sub-sequence of the precoding input sequence c with indices in the set {0, 1, 2, . . . , NE(i)−2, NE(i)−1} and the rate profile frozen bit sequence f=[f₀, f₁, . . . , f_{N-K-1}] of length N-K, wherein NE(i) is the size of the set {0, 1, 2, . . . , i}∩Q, wherein, the rate profile frozen bit sequence f can be any binary sequence of length N-K. In some embodiments, the rate profile frozen bit sequence f is the all-zero sequence of length N-K.

In some embodiments, for i not belonging to the precoding output index set P_{O}, the i-th output bit uᵢ in the precoding output sequence u of length N is set to a bit in a precoding frozen bit sequence h=[h₀, h₁, . . . , h_{N}_{_{PO}}₋₁] of length N−N_{PO}, wherein N_{PO} is the size of the precoding output index set P_{O}.

In some embodiments, for i not belonging to the precoding output index set P_{O}, the i-th output bit uᵢ in the precoding output sequence u of length N is set to bit 0.

In some embodiments, the i-th bit uᵢ in the precoding output sequence u is determined by both a subset of elements in the precoding input bit sequence c with indices in the integer set {0, 1, 2, . . . , i−1, i} and a subset of elements in the precoding output bit sequence u with indices in the integer set {0, 1, 2, . . . , i−2, i−1}.

In some embodiments, the i-th bit uᵢ in the precoding output sequence u is a linear combination over GF(2) of elements c₀, c₁, c₂, . . . , cᵢ₋₁, cᵢ in the precoding input bit sequence c and elements u₀, u₁, u₂, . . . , uᵢ₋₂, uᵢ₋₁ in the precoding output bit sequence u.

In some embodiments, a precoding output bit in the precoding output bit sequence u is determined by both (1) current precoding input bit and preceding precoding input bits in the precoding input bit sequence c; and (2) current precoding output bit and preceding precoding output bits in the precoding output bit sequence u.

### Precoding Using the Precoding Matrix W

In some embodiments, the precoding input sequence c has a length K. The precoding output bit sequence u has a length N. The precoding output bit sequence u is determined by performing vector-matrix multiplication on the precoding input bit sequence c and the precoding matrix W with K rows and N columns as u=c·W. The precoding input sequence c of length K is the input bit sequence of length K and the vector-matrix multiplication is performed over GF(2).

### Precoding Using the Precoding Matrix W and the Precoding Frozen Bit Sequence h

In some embodiments, the precoding output bit sequence u of length N is determined by performing vector-matrix multiplication on the precoding input bit sequence c and the precoding matrix W with K rows and N columns and adding the precoding frozen bit sequence h of length N as u=c·W+h. The precoding input sequence c of length K is the input bit sequence of length K. Both the vector-matrix multiplication and the vector-vector addition are performed over GF(2).

### Precoding Using the Rate Profiling Matrix F and the Pre-Transform Matrix T

In some embodiments, the precoding output sequence u of length N is determined using both the rate profiling matrix F with K rows and N columns and the pre-transform matrix T with N rows and N columns by multiplying the precoding input sequence c with the rate profiling matrix F and the pre-transform matrix T as u=c·F·T. The precoding input sequence c is the input bit sequence c of length K, N is the polar matrix size, and the matrix multiplication and the vector-matrix multiplication are performed over GF(2).

In some embodiments, the precoding output sequence u of length N is determined using the rate profiling matrix F with K rows and N columns, the rate profiling frozen bit sequence f of length N, and the pre-transform matrix T with N rows and N columns by multiplying the precoding input sequence c with the rate profiling matrix F over GF(2), adding the rate profiling frozen bit sequence f of length N over GF(2), and multiplying the pre-transform matrix T over GF(2) as u=(c·F+f)·T. The precoding input sequence e is the input bit sequence e of length K. N is the polar matrix size. The matrix multiplication, the vector-matrix multiplication and the vector-vector addition are performed over GF(2).

In some embodiments, the precoding output sequence u of length N is determined using the rate profiling matrix F with K rows and N columns, the pre-transform matrix T with N rows and N columns, and the precoding frozen bit sequence h of length N by multiplying the precoding input sequence c with the rate profiling matrix F over GF(2); multiplying the pre-transform matrix T over GF(2); and adding the precoding frozen bit sequence h of length N over GF(2) as u=c·F·T+h. The precoding input sequence c is the input bit sequence c of length K. N is the polar matrix size. The matrix multiplication, the vector-matrix multiplication and the vector-vector addition are performed over GF(2).

In some embodiments, the precoding output sequence u of length N is determined using both the rate profiling matrix F with K rows and N columns, the rate profiling frozen bit sequence f of length N, the pre-transform matrix T with N rows and N columns, and the precoding frozen bit sequence h of length N by multiplying the precoding input sequence c with the rate profiling matrix F over GF(2); adding the rate profiling frozen bit sequence f of length N over GF(2); multiplying the pre-transform matrix T over GF(2); and adding the precoding frozen bit sequence h of length N over GF(2) as u=(c·F+f)·T+h. The precoding input sequence c is the input bit sequence c of length K. N is the polar matrix size. The matrix multiplication, the vector-matrix multiplication and the vector-vector addition are performed over GF(2).

Precoding Determined by Q, f, g or (D), P_{I}, and P_{O}, h, t

In some embodiments, the precoding determines the precoding output bit sequence u of length N using at least one of the following: the data index set Q, the rate profiling frozen bit sequence f, the generator bit sequence g=[g₀, g₁, . . . , gₘ], the generator polynomial g(D)=g₀+g₁·D+ . . . +gₘ₋₁·Dₘ₋₁+gₘ·D^{m} over GF(2), the precoding input index set P_{I}, the precoding output index set P_{O}, the precoding frozen bit sequence h, or the state bit sequence t=[t₀, t₁, . . . , tₘ₋₁, tₘ]. The rate profiling frozen bit sequence f is of length N-K, the precoding frozen bit sequence h is of length N−N_{PO} and N_{PO} is the size of the precoding output index set P_{O}.

Table 2 shows example Algorithms 1A-1L, which are example implementations for the precoding. In the example Algorithms 1A-1L, the state bit sequence t=[t₀, t₁, . . . , tₘ₋₁, tₘ] is initialized to all zeros. If an index i belong to the data index set Q, the bit to in the state bit sequence t=[t₀, t₁, . . . , tₘ₋₁, tₘ] is set to a bit in the precoding input bit sequence c. If an index i belongs to the precoding output index set P_{O}, the i-th bit uᵢ of the precoding output bit sequence u is determined by the generator bit sequence g=[g₀, g₁, . . . , gₘ] and the state bit sequence t=[t₀, t₁, . . . , tₘ₋₁, tₘ], wherein, uᵢ=mod(Σⱼ₌₀^{m}gⱼ·tⱼ, 2). If an index i belongs to the precoding output index set P_{O}, the i-th bit uᵢ of the precoding output bit sequence u is determined by the generator polynomial g(D)=g₀+g₁·D+ . . . +gₘ₋₁·Dₘ₋₁+gₘ·D^{m} over GF(2) (e.g., as shown in FIG. 3) and the state bit sequence t=[t₀, t₁, . . . , tₘ₋₁, tₘ], wherein, uᵢ=mod(Σⱼ₌₀^{m}gⱼ·tⱼ, 2).

TABLE 2
Example Algorithms 1A-1L

| Algorithm 1A | Algorithm 1B | Algorithm 1C |
|---|---|---|
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = cₖ; | t₀ = cₖ; | t₀ = cₖ; |
| k = k + 1; | k = k + 1; | k = k + 1; |
| Else | Else | Else |
| t₀ = 0; | t₀ = 0; | t₀ = 0; |
| End if | End if | End if |
| If i ϵ P_{O} | If i ϵ P_{O} | If i ϵ P_{O} |
| uᵢ = 0; | uᵢ = 0; | uᵢ = 0; |
| For j = 0 to m | For j = 0 to m | For j = 0 to m |
| uᵢ = mod(uᵢ + | uᵢ = mod(uᵢ + | uᵢ = mod(uᵢ + |
| gⱼ·tⱼ, 2); | gⱼ·tⱼ, 2); | gⱼ·tⱼ, 2); |
| End for | End for | End for |
| Else | Else | Else |
| uᵢ = 0; | uᵢ = t₀; | uᵢ = h_{k′}; |
| End if | End if | k′ = k′ + 1; |
| | | End if |
| If i ϵ P_{I} | If i ϵ P_{I} | If i ϵ P_{I} |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End if | End if | End if |
| End for | End for | End for |
| Algorithm 1D | Algorithm 1E | Algorithm 1F |
| For j = 0 to m | For j = 0 to m | For j = 0 to m |
| tⱼ = 0; | tⱼ = 0; | tⱼ = 0; |
| End for | End for | End for |
| k = 0; | k = 0; | k = 0; |
| | | k′ = 0; |
| For i = 0 to N−1 | For i = 0 to N−1 | For i = 0 to N−1 |
| If i ϵ Q | If i ϵ Q | If i ϵ Q |
| t₀ = cₖ; | t₀ = cₖ; | t₀ = cₖ; |
| k = k + 1; | k = k + 1; | k = k + 1; |
| Else | Else | Else |
| t₀ = fᵢ₋ₖ; | t₀ = fᵢ₋ₖ; | t₀ = fᵢ₋ₖ; |
| End if | End if | End if |
| If i ∈ P_{O} | If i ∈ P_{O} | If i ∈ P_{O} |
| uᵢ = 0; | uᵢ = 0; | uᵢ = 0; |
| For j = 0 to m | For j = 0 to m | For j = 0 to m |
| uᵢ = mod(uᵢ + | uᵢ = mod(uᵢ + | uᵢ = mod(uᵢ + |
| gⱼ·tⱼ, 2); | gⱼ·tⱼ, 2); | gⱼ·tⱼ, 2); |
| End for | End for | End for |
| Else | Else | Else |
| uᵢ = 0; | uᵢ = 0; | uᵢ = h_{k′}; |
| End if | End if | k′ = k′ + 1; |
| | | End if |
| If i ϵ P_{I} | If i ϵ P_{I} | If i ϵ P_{I} |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End if | End if | End if |
| End for | End for | End for |
| Algorithm 1G | Algorithm 1H | Algorithm 1I |
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = cₖ, | t₀ = cₖ, | t₀ = cₖ, |
| k = k + 1; | k = k + 1; | k = k + 1; |
| Else | Else | Else |
| t₀ = 0; | t₀ = 0; | t₀ = 0; |
| End if | End if | End if |
| If i ϵ P_{O} | If i ϵ P_{O} | If i ϵ P_{O} |
| uᵢ = 0; | uᵢ = 0; | uᵢ = 0; |
| For j = 0 to m | For j = 0 to m | For j = 0 to m |
| uᵢ = mod(uᵢ + | uᵢ = mod(uᵢ + | uᵢ = mod(uᵢ + |
| gⱼ·tⱼ, 2); | gⱼ·tⱼ, 2); | gⱼ·tⱼ, 2); |
| End for | End for | End for |
| Else | Else | Else |
| uᵢ = 0; | uᵢ = t₀; | uᵢ = h_{k′}; |
| End if | End if | k′ = k′ + 1; |
| | | End if |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End for | End for | End for |
| Algorithm 1J | Algorithm 1K | Algorithm 1L |
| For j = 0 to m | For j = 0 to m | For j = 0 to m |
| tⱼ = 0; | tⱼ = 0; | tⱼ = 0; |
| End for | End for | End for |
| k = 0; | k = 0; | k = 0; |
| | | k′ = 0; |
| For i = 0 to N−1 | For i = 0 to N−1 | For i = 0 to N−1 |
| If i ϵ Q | If i ϵ Q | If i ϵ Q |
| t₀ = cₖ; | t₀ = cₖ; | t₀ = cₖ; |
| k = k + 1; | k = k + 1; | k = k + 1; |
| Else | Else | Else |
| t₀ = fᵢ₋ₖ; | t₀ = fᵢ₋ₖ; | t₀ = fᵢ₋ₖ; |
| End if | End if | End if |
| If i ϵ P_{O} | If i ϵ P_{O} | If i ϵ P_{O} |
| uᵢ = 0; | uᵢ = 0; | uᵢ = 0; |
| For j = 0 to m | For j = 0 to m | For j = 0 to m |
| uᵢ = mod(uᵢ + | uᵢ = mod(uᵢ + | uᵢ = mod(uᵢ + |
| gⱼ·tⱼ, 2); | gⱼ·tⱼ, 2); | gⱼ·tⱼ, 2); |
| End for | End for | End for |
| Else | Else | Else |
| uᵢ = 0; | uᵢ = t₀; | uᵢ = h_{k′}; |
| End if | End if | k′ = k′ + 1; |
| | | End if |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End for | End for | End for |

In some embodiments, if an index i does not belong to the data index set Q, the bit t₀ in the state bit sequence t=[t₀, t₁, . . . , tₘ₋₁, tₘ] is set to 0, e.g., as in Algorithms 1A, 1B, 1C, 1G, 1H, and 1I. In some examples, if an index i does not belong to the data index set Q, the bit to in the state bit sequence t=[t₀, t₁, . . . , tₘ₋₁, tₘ] is set to a bit in the rate profiling frozen bit sequence f, e.g., as shown in Algorithms 1D, 1E, 1F, 1J, 1K, and 1L.

In some embodiments, if an index i does not belong to the precoding output index set P_{O}, the i-th bit uᵢ of the precoding output bit sequence u is set to 0, e.g., as shown in Algorithms 1A, 1D, 1G, and 1J.

In some embodiments, if an index i does not belong to the precoding output index set P_{O}, the i-th bit uᵢ of the precoding output bit sequence u is set to t₀ in the state bit sequence t=[t₀, t₁, . . . , tₘ₋₁, tₘ], e.g., as shown in Algorithms 1B, 1E, 1H, and 1K.

In some examples, if an index i does not belong to the precoding output index set P_{O}, the i-th bit uᵢ of the precoding output bit sequence u is set to a bit in the precoding frozen bit sequence h, as shown in Algorithms 1C, 1F, 1I, and 1L. The precoding frozen bit sequence h is of length N−N_{PO} and N_{PO} is the size of the precoding output index set P_{O}.

In some examples, if an index i belongs to the precoding input index set P_{I}, a right shift is performed on the state bit sequence t=[t₀, t₁, . . . , tₘ₋₁, tₘ] as follows.

For j = m to 1
tⱼ = tⱼ₋₁;
End for

In some examples, for all indices i, a right shift is performed on the state bit sequence t=[t₀, t₁, . . . , tₘ₋₁, tₘ] as follows.

For j = m to 1
tⱼ = tⱼ₋₁;
End for

The state bit sequence t=[t₀, t₁, . . . , tₘ₋₁, tₘ] of length m+1 is for storing the convolution state. gⱼ can be either elements in the generator bit sequence g or coefficients in the generator polynomial g(D), e.g., as shown in FIG. 3.

Precoding Determined by Q, f, g or q(D), P_{I}, and P_{O}, h, t

In some embodiments, the precoding determines the precoding output bit sequence u of length N using at least one of the following: the data index set Q, the rate profiling frozen bit sequence f, the recursive feedback bit sequence q=[q₀, q₁, . . . , qₘ], the recursive feedback polynomial q(D)=q₀+q₁·D+ . . . +qₘ·D^{m} over GF(2), the precoding input index set P_{I}, the precoding output index set P_{O}, the precoding frozen bit sequence h, or the state bit sequence t=[t₀, t₁, . . . , tₘ₋₁, tₘ] of length m+1. The rate profiling frozen bit sequence f is of length N-K. The precoding frozen bit sequence h is of length N−N_{PO} and N_{PO} is the size of the precoding output index set P_{O}.

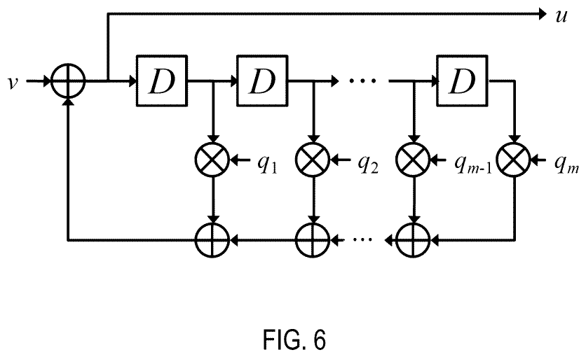

Table 3 shows example Algorithms 2A-2L, which are example implementations for the precoding. In the example Algorithms 2A-2L, the state bit sequence t=[t₀, t₁, . . . , tₘ₋₁, tₘ] is initialized to all zeros. If an index i belong to the data index set Q, the bit to in the state bit sequence t=[t₀, t₁, . . . , tₘ₋₁, tₘ] is set to a bit in the precoding input bit sequence c. If an index i belongs to the precoding output index set P_{O}, the i-th bit uᵢ of the precoding output bit sequence u is determined by the recursive feedback bit sequence q=[q₀, q₁, . . . , qₘ] and the state bit sequence t=[t₀, t₁, . . . , tₘ₋₁, tₘ], wherein, uᵢ=mod(Σⱼ₌₀^{m}gⱼ·tⱼ, 2). If an index i belongs to the precoding output index set P_{O}, the i-th bit uᵢ of the precoding output bit sequence u is determined by the recursive feedback polynomial q(D)=q₀+q₁·D+ . . . +qₘ₋₁·Dₘ₋₁+qₘ·D^{m} over GF(2) and the state bit sequence t=[t₀, t₁, . . . , tₘ₋₁, tₘ], wherein, uᵢ=mod(Σⱼ₌₀^{m}gⱼ·tⱼ, 2). FIG. 6 illustrates an example diagram for a recursive convolution transform in accordance with one or more embodiments of the present technology. The recursive convolution transform is defined by either the recursive feedback bit sequence q=[q₀, q₁, . . . , qₘ] or the recursive feedback polynomial q(D)=q₀+q₁·D+ . . . +qₘ₋₁·Dₘ₋₁+qₘ·D^{m} over GF(2) with q₀=1. If an index i belongs to the precoding output index set P_{O}, the bit to in the state bit sequence t=[t₀, t₁, . . . , tₘ₋₁, tₘ] is set to uᵢ, wherein, uᵢ=mod(Σⱼ₌₀^{m}gⱼ·tⱼ, 2).

TABLE 3
Example Algorithms 2A-2L

| Algorithm 2A | Algorithm 2B | Algorithm 2C |
|---|---|---|
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = ck; | t₀ = ck; | t₀ = ck; |
| k = k + 1; | k = k + 1; | k = k + 1; |
| Else | Else | Else |
| t₀ = 0; | t₀ = 0; | t₀ = 0; |
| End if | End if | End if |
| If i ϵ Po | If i ϵ Po | If i ϵ Po |
| uᵢ = 0; | uᵢ = 0; | uᵢ = 0; |
| For j = 0 to m | For j = 0 to m | For j = 0 to m |
| uᵢ = mod(uᵢ + qⱼ·tⱼ, | uᵢ = mod(uᵢ + qⱼ·tⱼ, | uᵢ = mod(uᵢ + qⱼ·tⱼ, |
| 2); | 2); | 2); |
| End for | End for | End for |
| t₀ = uᵢ; | t₀ = uᵢ; | t₀ = uᵢ; |
| Else | Else | Else |
| uᵢ = 0; | uᵢ = t₀; | uᵢ = h_{k′}; |
| End if | End if | k′ = k′ + 1; |
| | | End if |
| If i ϵ P_{I} | If i ϵ P_{I} | If i ϵ P_{I} |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End if | End if | End if |
| End for | End for | End for |
| Algorithm 2D | Algorithm 2E | Algorithm 2F |
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = cₖ; | t₀ = cₖ; | t₀ = cₖ; |
| k = k + 1; | k = k + 1; | k = k + 1; |
| Else | Else | Else |
| t₀ = f₁₋ₖ; | t₀ = f₁₋ₖ; | t₀ = f₁₋ₖ; |
| End if | End if | End if |
| If i ϵ Po | If i ϵ Po | If i ϵ Po |
| uᵢ = 0; | uᵢ = 0; | uᵢ = 0; |
| For j = 0 to m | For j = 0 to m | For j = 0 to m |
| uᵢ = mod(uᵢ + qⱼ·tⱼ, | uᵢ = mod(uᵢ + qⱼ·tⱼ, | uᵢ = mod(uᵢ + qⱼ·tⱼ, |
| 2); | 2); | 2); |
| End for | End for | End for |
| t₀ = uᵢ; | t₀ = uᵢ; | t₀ = uᵢ; |
| Else | Else | Else |
| uᵢ = 0; | uᵢ = t₀; | uᵢ = h_{k′}; |
| End if | End if | k′ = k′ + 1; |
| | | End if |
| If i ϵ P_{I} | If i ϵ P_{I} | If i ϵ P_{I} |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End if | End if | End if |
| End for | End for | End for |
| Algorithm 2G | Algorithm 2H | Algorithm 2I |
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = ck; | t₀ = ck; | t₀ = ck; |
| k = k + 1; | k = k + 1; | k = k + 1; |
| Else | Else | Else |
| t₀ = 0; | t₀ = 0; | t₀ = 0; |
| End if | End if | End if |
| If i ϵ Po | If i ϵ Po | If i ϵ Po |
| uᵢ = 0; | uᵢ = 0; | uᵢ = 0; |
| For j = 0 to m | For j = 0 to m | For j = 0 to m |
| uᵢ = mod(uᵢ + qⱼ·tⱼ, | uᵢ = mod(uᵢ + qⱼ·tⱼ, | uᵢ = mod(uᵢ + qⱼ·tⱼ, |
| 2); | 2); | 2); |
| End for | End for | End for |
| t₀ = uᵢ; | t₀ = uᵢ; | t₀ = uᵢ; |
| Else | Else | Else |
| uᵢ = 0; | uᵢ = t₀; | uᵢ = h_{k′}; |
| End if | End if | k′ = k′ + 1; |
| | | End if |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End for | End for | End for |
| Algorithm 2J | Algorithm 2K | Algorithm 2L |
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = ck; | t₀ = ck; | t₀ = ck; |
| k = k + 1; | k = k + 1; | k = k + 1; |
| Else | Else | Else |
| t₀ = f₁₋ₖ; | t₀ = f₁₋ₖ; | t₀ = f₁₋ₖ; |
| End if | End if | End if |
| If i ϵ Po | If i ϵ Po | If i ϵ Po |
| uᵢ = 0; | uᵢ = 0; | uᵢ = 0; |
| For j = 0 to m | For j = 0 to m | For j = 0 to m |
| uᵢ = mod(uᵢ + qⱼ·tⱼ, | uᵢ = mod(uᵢ + qⱼ·tⱼ, | uᵢ = mod(uᵢ + qⱼ·tⱼ, |
| 2); | 2); | 2); |
| End for | End for | End for |
| t₀ = uᵢ; | t₀ = uᵢ; | t₀ = uᵢ; |
| Else | Else | Else |
| uᵢ = 0; | uᵢ = t₀; | uᵢ = h_{k′}; |
| End if | End if | k′ = k′ + 1; |
| | | End if |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End for | End for | End for |

In some embodiments, if an index i does not belong to the data index set Q, the bit to in the state bit sequence t=[t₀, t₁, . . . , tₘ₋₁, tₘ] is set to 0. e.g., as in Algorithms 2A, 2B, 2C, 2G, 2H, and 2I.

In some embodiments, if an index i does not belong to the data index set Q, the bit to in the state bit sequence t=[t₀, t₁, . . . , tₘ₋₁, tₘ] is set to a bit in the rate profiling frozen bit sequence f, e.g., as in Algorithms 2D, 2E, 2F, 2J, 2K, and 2L.

In some embodiments, if an index i does not belong to the precoding output index set P_{O}, the i-th bit uᵢ of the precoding output bit sequence u is set to 0, e.g., as in Algorithms 2A, 2D, 2G, and 2J.

In some embodiments, if an index i does not belong to the precoding output index set P_{O}, the i-th bit uᵢ of the precoding output bit sequence u is set to t₀ in the state bit sequence t=[t₀, t₁, . . . , tₘ₋₁, tₘ], e.g., as in Algorithms 2B, 2E, 2H, and 2K.

In some embodiments, if an index i does not belong to the precoding output index set P_{O}, the i-th bit uᵢ of the precoding output bit sequence u is set to a bit in the precoding frozen bit sequence h, e.g., as in Algorithms 2C, 2F, 2I, and 2L. The precoding frozen bit sequence h is of length N−N_{PO} and N_{PO} is the size of the precoding output index set P_{O}.

In some examples, if an index i belongs to the precoding input index set P_{I}, a right shift is performed on the state bit sequence t=[t₀, t₁, . . . , tₘ₋₁, tₘ] as follows.

For j = m to 1
tⱼ = tⱼ₋₁;
End for

In some examples, for all indices i, a right shift is performed on the state bit sequence t=[t₀, t₁, . . . , tₘ₋₁, tₘ] as follows.

For j = m to 1
tⱼ = tⱼ₋₁;
End for

t=[t₀, t₁, . . . , tₘ₋₁, tₘ] is a state bit sequence of length m+1 for storing the convolution state. qⱼ can be either elements in the recursive feedback bit sequence q or coefficients in the recursive feedback polynomial q(D).

Precoding Determined by Q, f, g or g(D), q or q(D), P_{I}, and P_{O}, h, t

In some embodiments, the precoding determines the precoding output bit sequence u of length N using at least one of the following: the data index set Q, the rate profiling frozen bit sequence f, the generator bit sequence g=[g₀, g₁, . . . , gₘ], the generator polynomial g(D)=g₀+g₁·D+ . . . +gₘ·D^{m} over GF(2), the recursive feedback bit sequence q=[q₀, q₁, . . . , qₘ], the recursive feedback polynomial q(D)=q₀+q₁·D+ . . . +qₘ·D^{m} over GF(2), the precoding input index set P_{I}, the precoding output index set P_{O}, the precoding frozen bit sequence h, or the state bit sequence t=[t₀, t₁, . . . , tₘ₋₁, tₘ]. The rate profiling frozen bit sequence f is of length N-K. The precoding frozen bit sequence h is of length N−N_{PO} and N_{PO} is the size of the precoding output index set P_{O}.

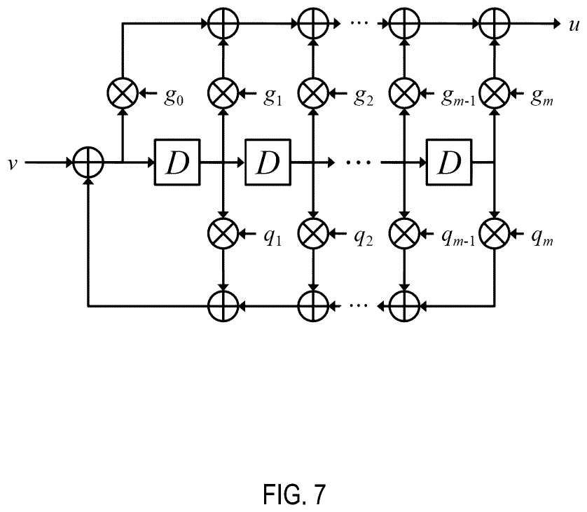

Table 4 shows example Algorithms 3A-3L, which are example implementations for the precoding. In the example Algorithm 3A-3L, the state bit sequence t=[t₀, t₁, . . . , tₘ₋₁, tₘ] is initialized to all zeros. If an index i belong to the data index set Q, the bit to in the state bit sequence t=[t₀, t₁, . . . , tₘ₋₁, tₘ] is set to a bit in the precoding input bit sequence c. If an index i belongs to the precoding output index set P_{O}, the i-th bit uᵢ of the precoding output bit sequence u is determined by the generator bit sequence g=[g₀, g₁, . . . , gₘ] (or the generator polynomial g(D)=g₀+g₁·D+ . . . +gₘ·D^{m} over GF(2)), the recursive feedback bit sequence q=[q₀, q₁, . . . , qₘ] (or the recursive feedback polynomial q(D)=q₀+q₁·D+ . . . +qₘ·D^{m} over GF(2)), and the state bit sequence t=[t₀, t₁, . . . , tₘ₋₁, tₘ]. FIG. 7 illustrates another example a recursive convolution transform in accordance with one or more embodiments of the present technology. The recursive convolution transform is defined by either the generator bit sequence g=[g₀, g₁, . . . , gₘ] and/or the recursive feedback bit sequence q=[q₀, q₁, . . . , qₘ], or the generator polynomial g(D)=g₀+g₁·D+ . . . +gₘ₋₁·Dₘ₋₁+gₘ·D^{m} and/or the recursive feedback polynomial q(D)=q₀+q₁·D+ . . . +qₘ·D^{m} over GF(2) with q₀=1. The determination can comprise: determining a summation bit s based on the recursive feedback bit sequence q=[q₀, q₁, . . . , qₘ] (or the recursive feedback polynomial q(D)=q₀+q₁·D+ . . . +qₘ·D^{m} over GF(2)) and the state bit sequence t=[t₀, t₁, . . . , tₘ₋₁, tₘ] as s=mod(Σⱼ₌₀^{m}gⱼ·tⱼ, 2), setting the bit to in the state bit sequence t=[t₀, t₁, . . . , tₘ₋₁, tₘ] to the summation bit s; and determining the i-th bit uᵢ of the precoding output bit sequence u by the generator bit sequence g=[g₀, g₁, . . . , gₘ] (or the generator polynomial g(D)=g₀+g₁·D+ . . . +gₘ·D^{m} over GF(2)) and the state bit sequence t=[t₀, t₁, . . . , tₘ₋₁, tₘ] as uᵢ=mod(Σⱼ₌₀^{m}gⱼ·tⱼ, 2).

TABLE 4
Example Algorithms 3A-3L

| Algorithm 3A | Algorithm 3B | Algorithm 3C |
|---|---|---|
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = ck; | t₀ = ck; | t₀ = ck; |
| k = k + 1; | k = k + 1; | k = k + 1; |
| Else | Else | Else |
| t₀ = 0; | t₀ = 0; | t₀ = 0; |
| End if | End if | End if |
| If i ϵ Po | If i ϵ Po | If i ϵ Po |
| s = 0; | s = 0; | s = 0; |
| For j = 0 to m | For j = 0 to m | For j = 0 to m |
| s = mod(s + qⱼ·tⱼ, | s = mod(s + qⱼ·tⱼ, | s = mod(s + qⱼ·tⱼ, |
| 2); | 2); | 2); |
| End for | End for | End for |
| t₀ = s; | t₀ = s; | t₀ = s; |
| uᵢ = 0; | uᵢ = 0; | uᵢ = 0; |
| For j = 0 to m | For j = 0 to m | For j = 0 to m |
| uᵢ = mod(uᵢ + qⱼ·tⱼ, | uᵢ = mod(uᵢ + qⱼ·tⱼ, | uᵢ = mod(uᵢ + qⱼ·tⱼ, |
| 2); | 2); | 2); |
| End for | End for | End for |
| Else | Else | Else |
| uᵢ = 0; | uᵢ = t₀; | uᵢ = h_{k′}; |
| End if | End if | k′ = k′ + 1; |
| | | End if |
| If i ϵ P_{I} | If i ϵ P_{I} | If i ϵ P_{I} |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End if | End if | End if |
| End for | End for | End for |
| Algorithm 3D | Algorithm 3E | Algorithm 3F |
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = ck; | t₀ = ck; | t₀ = ck; |
| k = k + 1; | k = k + 1; | k = k + 1; |
| Else | Else | Else |
| t₀ = f₁₋ₖ; | t₀ = f₁₋ₖ; | t₀ = f₁₋ₖ; |
| End if | End if | End if |
| If i ϵ Po | If i ϵ Po | If i ϵ Po |
| s = 0; | s = 0; | s = 0; |
| For j = 0 to m | For j = 0 to m | For j = 0 to m |
| s = mod(s + qⱼ·tⱼ, | s = mod(s + qⱼ·tⱼ, | s = mod(s + qⱼ·tⱼ, |
| 2); | 2); | 2); |
| End for | End for | End for |
| t₀ = s; | t₀ = s; | t₀ = s; |
| uᵢ = 0; | uᵢ = 0; | uᵢ = 0; |
| For j = 0 to m | For j = 0 to m | For j = 0 to m |
| uᵢ = mod(uᵢ + qⱼ·tⱼ, | uᵢ = mod(uᵢ + qⱼ·tⱼ, | uᵢ = mod(uᵢ + qⱼ·tⱼ, |
| 2); | 2); | 2); |
| End for | End for | End for |
| Else | Else | Else |
| uᵢ = 0; | uᵢ = t₀; | uᵢ = h_{k′}; |
| End if | End if | k′ = k′ + 1; |
| | | End if |
| If i ϵ P_{I} | If i ϵ P_{I} | If i ϵ P_{I} |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End if | End if | End if |
| End for | End for | End for |
| Algorithm 3G | Algorithm 3H | Algorithm 3I |
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = ck; | t₀ = ck; | t₀ = ck; |
| k = k + 1; | k = k + 1; | k = k + 1; |
| Else | Else | Else |
| t₀ = 0; | t₀ = 0; | t₀ = 0; |
| End if | End if | End if |
| If i ϵ Po | If i ϵ Po | If i ϵ Po |
| s = 0; | s = 0; | s = 0; |
| For j = 0 to m | For j = 0 to m | For j = 0 to m |
| s = mod(s + qⱼ·tⱼ, | s = mod(s + qⱼ·tⱼ, | s = mod(s + qⱼ·tⱼ, |
| 2); | 2); | 2); |
| End for | End for | End for |
| t₀ = s; | t₀ = s; | t₀ = s; |
| uᵢ = 0; | uᵢ = 0; | uᵢ = 0; |
| For j = 0 to m | For j = 0 to m | For j = 0 to m |
| uᵢ = mod(uᵢ + qⱼ·tⱼ, | uᵢ = mod(uᵢ + qⱼ·tⱼ, | uᵢ = mod(uᵢ + qⱼ·tⱼ, |
| 2); | 2); | 2); |
| End for | End for | End for |
| Else | Else | Else |
| uᵢ = 0; | uᵢ = t₀; | uᵢ = h_{k′}; |
| End if | End if | k′ = k′ + 1; |
| | | End if |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End for | End for | End for |
| Algorithm 3J | Algorithm 3K | Algorithm 3L |
| For j = 0 to m | For j = 0 tom | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Q | If i ϵ Q | If i ϵ Q |
| t₀ = ck; | t₀ = ck; | t₀ = ck; |
| k = k + 1; | k = k + 1; | k = k + 1; |
| Else | Else | Else |
| t₀ = f₁₋ₖ; | t₀ = f₁₋ₖ; | t₀ = f₁₋ₖ; |
| End if | End if | End if |
| If i ϵ Po | If i ϵ Po | If i ϵ Po |
| s = 0; | s = 0; | s = 0; |
| For j = 0 to m | For j = 0 to m | For j = 0 to m |
| s = mod(s + qⱼ·tⱼ, | s = mod(s + qⱼ·tⱼ, | s = mod(s + qⱼ·tⱼ, |
| 2); | 2); | 2); |
| End for | End for | End for |
| t₀ = s; | t₀ = s; | t₀ = s; |
| uᵢ = 0; | uᵢ = 0; | uᵢ = 0; |
| For j = 0 to m | For j = 0 to m | For j = 0 to m |
| uᵢ = mod(uᵢ + qⱼ·tⱼ, | uᵢ = mod(uᵢ + qⱼ·tⱼ, | uᵢ = mod(uᵢ + qⱼ·tⱼ, |
| 2); | 2); | 2); |
| End for | End for | End for |
| Else | Else | Else |
| uᵢ = 0; | uᵢ = t₀; | uᵢ = h_{k′}; |
| End if | End if | k′ = k′ + 1; |
| | | End if |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| End for | End for | End for |

In some embodiments, if an index i does not belong to the data index set Q, the bit to in the state bit sequence t=[t₀, t₁, . . . , tₘ₋₁, tₘ] is set to 0, e.g., as in Algorithm 3A, 3B, 3C, 3G, 3H, and 3I. In some embodiments, if an index i does not belong to the data index set Q, the bit to in the state bit sequence t=[t₀, t₁, . . . , tₘ₋₁, tₘ] is set to a bit in the rate profiling frozen bit sequence f, e.g., as in Algorithm 3D, 3E, 3F, 3J, 3K, and 3L. In some embodiments, if an index i does not belong to the precoding output index set P_{O}, the i-th bit uᵢ of the precoding output bit sequence u is set to 0, e.g., as in Algorithm 3A, 3D, 3G, and 3J. In some embodiments, if an index i does not belong to the precoding output index set P_{O}, the i-th bit uᵢ of the precoding output bit sequence u is set to t₀ in the state bit sequence t=[t₀, t₁, . . . , tₘ₋₁, tₘ], e.g., as in Algorithm 3B, 3E, 3H, and 3K.

In some embodiments, if an index i does not belong to the precoding output index set P_{O}, the i-th bit uᵢ of the precoding output bit sequence u is set to a bit in the precoding frozen bit sequence h, e.g., as in Algorithm 3C, 3F, 3I, and 3L. The precoding frozen bit sequence h is of length N−N_{PO} and N_{PO} is the size of the precoding output index set P_{O}. In some embodiments, if an index i belongs to the precoding input index set P_{I}, a right shift is performed on the state bit sequence t=[t₀, t₁, . . . , tₘ₋₁, tₘ] as follows, e.g., as in Algorithm 3A, 3B, 3C, 3D, 3E, and 3F.

For j = m to 1
tⱼ = tⱼ₋₁;
End for

In some examples, for all indices i, a right shift is performed on the state bit sequence t=[t₀, t₁, . . . , tₘ₋₁, tₘ] as follows, e.g., as in Algorithm 3G, 3H, 3I, 3J, 3K, and 3L.

For j = m to 1
tⱼ = tⱼ₋₁;
End for

t=[t₀, t₁, . . . , tₘ₋₁, tₘ] is a state bit sequence of length m+1 for storing the convolution state. gⱼ can be either elements in the generator bit sequence g or coefficients in the generator polynomial g(D). qⱼ can be either elements in the recursive feedback bit sequence q or coefficients in the recursive feedback polynomial q(D).

In some embodiments, the precoding comprises a rate profiling and a pre-transform. The rate profiling comprises obtaining, by the first node, a rate profiling input bit sequence, and determining, by the first node, a rate profiling output bit sequence v=[v₀, v₁, . . . , v_{N-1}]. The pre-transform comprises obtaining, by the first node, a pre-transform input bit sequence, and determining, by the first node, a pre-transform output bit sequence.

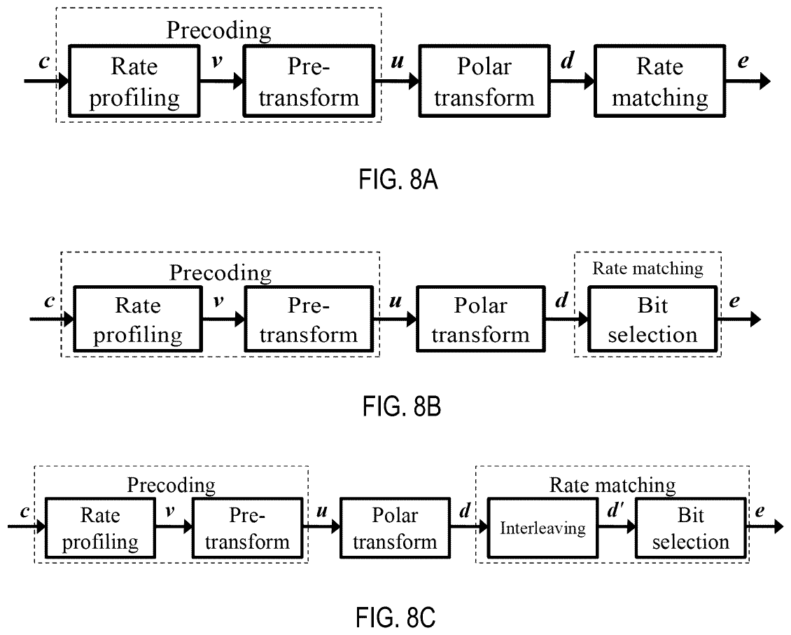

FIGS. 8A-8C illustrates examples of polar coding with pre-transform and rate matching in accordance with one or more embodiments of the present technology. The rate profiling input bit sequence is the input bit sequence c of length K. The rate profiling output bit sequence v has a length equal to the polar matrix size N. The pre-transform input bit sequence is the rate profiling output bit sequence v of length N. The pre-transform output bit sequence is the precoding output bit sequence u of length N.

The rate profiling: The rate profiling comprises obtaining, by the first node, a rate profiling input bit sequence, and determining, by the first node, a rate profiling output bit sequence v=[v₀, v₁, . . . , v_{N-1}]. As shown in FIGS. 8A-8C, the rate profiling input bit sequence is the input bit sequence c of length K. The rate profiling output bit sequence v is of length equal to the polar matrix size N.

The pre-transform: The pre-transform comprises obtaining, by the first node, a pre-transform input bit sequence, and determining, by the first node, a pre-transform output bit sequence u=[u₀, u₁, . . . , u_{N-1}]. As shown in FIGS. 8A-8C, the pre-transform input bit sequence is the rate profiling output bit sequence v of length N. The pre-transform output bit sequence u is of length equal to the polar matrix size N.

Parameters for the rate profiling: The rate profiling determines the rate profiling output bit sequence v corresponding to the rate profiling input bit sequence c by the first node using at least one of the following: the data index set Q), the rate profiling matrix F with K rows and N columns, or the rate profiling frozen bit sequence f.

In some embodiments, the rate profiling output bit sequence vis the multiplexing of the rate profiling input bit sequence c and the rate profiling frozen bit sequence f. The rate profiling frozen bit sequence f is of length N-K, and N is the polar matrix size and K is the rate profiling input bit sequence length. A first specific example with N=8 and K=3 is a rate profiling input bit sequence c=[c₀, c₁, c₂] and a rate profiling frozen bit sequence f=[f₀, f₁, f₂, f₃, f₄], then a rate profiling output bit sequence v=[v₀, v₁, v₂, v₃, v₄, v₅, v₆, v₇]=[f₀, f₁, f₂, f₃, f₄, c₀, c₁, c₂]. A second specific example with N=16 and K=4 is a rate profiling input bit sequence c=[c₀, c₁, c₂, c₃] and a rate profiling frozen bit sequence f=[f₀, f₁, f₂, f₃, f₄, f₅, f₆, f₇, f₈, f₀, f₁₀, f₁₁], then a rate profiling output bit sequence v=[v₀, v₁, v₂, v₃, v₄, v₅, v₆, v₇, v₈, v₉, v₁₀, v₁, v₁₂, v₁₃, v₁₄, v₁₅]=[f₀, f₁, f₂, f₃, f₄, f₅, f₆, f₇, f₈, f₉, f₁₀, c₀, f₁₁, c₁, c₂, c₃]. A third specific example is given in Algorithm 4A of Table 5.

In some embodiments, for an index i belonging to the data index set Q, the bit vᵢ in the rate profiling output bit sequence v is a bit in the rate profiling input bit sequence c. A first specific example with N=8, K=3 and a data index set Q={5, 6, 7}, a rate profiling input bit sequence c=[c₀, c₁, c₂], the bits v₅, v₆, v₇ with indices belonging to the data index set Q={5, 6, 7} in a rate profiling output bit sequence v=[v₀, v₁, v₂, v₃, v₄, v₅, v₆, v₇] is set as v₅=c₀, v₆=c₁, and v₇=c₂. A second specific example with N=16, K=4 and a data index set Q={11, 13, 14, 15}, a rate profiling input bit sequence c=[c₀, c₁, c₂, c₃], the bits v₁₁, v₁₃, v₁₄, v₁₅ with indices belonging to the data index set Q={11, 13, 14, 15} in a rate profiling output bit sequence v=[v₀, v₁, v₂, v₃, v₄, v₅, v₆, v₇, v₈, v₉, v₁₀, v₁₁, v₁₂, v₁₃, v₁₄, v₁₅] is set as v₁₁=c₀, v₁₃=c₁, v₁₄=c₂, and v₁₅=c₃. A third specific example is given in Algorithm 4A of Table 5. A fourth specific example is given in Algorithm 4B of Table 5.

In some embodiments, for a index i not belonging to the data index set Q, the bit vᵢ in the rate profiling output bit sequence v is a bit in the rate profiling frozen bit sequence f. A first specific example with N=8, K=3 and Q={5, 6, 7}, a rate profiling frozen bit sequence f=[f₀, f₁, f₂, f₃, f₄], the bits v₀, v₁, v₂, v₃, v₄ with indices not belonging to the data index set Q={5, 6, 7} in a rate profiling output bit sequence v=[v₀, v₁, v₂, v₃, v₄, v₅, v₆, v₇] is set as v₀=f₀, v₁=f₁, v₂=f₂, v₃=f₃, and v₄=f₄. A second specific example with N=16, K=4 and Q={11, 13, 14, 15}, a rate profiling frozen bit sequence f=[f₀, f₁, f₂, f₃, f₄, f₅, f₆, f₇, f₈, f₀, f₁₀, f₁₁], the bits v₀, v₁, v₂, v₃, v₄, v₅, v₆, v₇, v₈, v₉, v₁₀, v₁₂ with indices not belonging to the data index set Q={11, 13, 14, 15} in a rate profiling output bit sequence v=[v₀, v₁, v₂, v₃, v₄, v₅, v₆, v₇, v₈, v₉, v₁₀, v₁₁, v₁₂, v₁₃, v₁₄, v₁₅] is set as v₀=f₀, v₁=f₁, v₂=f₂, v₃=f₃, v₄=f₄, v₅=f₅, v₆=f₆, v₁=f₇, v₈=f₈, v₉=f₀, v₁₀=f₁₀, and v₁₂=f₁. A third specific example is given in Algorithm 4A of Table 5.

In some embodiments, the rate profiling output bit sequence vis the multiplexing of the rate profiling input bit sequence c and an all-zero sequence of length N-K, wherein N is the polar matrix size and K is the rate profiling input bit sequence length. A first specific example with N=8 and K=3 is a rate profiling input bit sequence c=[c₀, c₁, c₂] and an all-zero sequence of length N−K=8−3=5, then a rate profiling output bit sequence v=[v₀, v₁, v₂, v₃, v₄, v₅, v₆, v₇]=[0, 0, 0, 0, 0, c₀, c₁, c₂]. A second specific example with N=16 and K=4 is a rate profiling input bit sequence c=[c₀, c₁, c₂, c₃] and an all-zero sequence of length N-K=16−4=12, then a rate profiling output bit sequence v=[v₀, v₁, v₂, v₃, v₄, v₅, v₆, v₇, v₈, v₉, v₁₀, v₁₁, v₁₂, v₁₃, v₁₄, v₁₅]=[0, 0, 0, 0, 0, 0, 0, 0, 0, 0, c₀, 0, c₁, c₂, c₃]. A third specific example is given in Algorithm 4B of Table 5.

In some embodiments, for an index i not belonging to the data index set Q, the bit vᵢ in the rate profiling output bit sequence v is equal to 0. A first specific example with N=8, K=3 and Q={5, 6, 7}, the bits v₀, v₁, v₂, v₃, v₄ with indices not belonging to the data index set Q={5, 6, 7} in a rate profiling output bit sequence v=[v₀, v₁, v₂, v₃, v₄, v₅, v₆, v₇] is set as v₀=0, v₁=0, v₂=0, v₃=0, and v₄=0. A second specific example with N=16, K=4 and Q={11, 13, 14, 15}, the bits v₀, v₁, v₂, v₃, v₄, v₅, v₆, v₇, v₈, v₉, v₁₀, v₁₂ with indices not belonging to the data index set Q={11, 13, 14, 15} in a rate profiling output bit sequence v=[v₀, v₁, v₂, v₃, v₄, v₅, v₆, v₇, v₈, v₉, v₁₀, v₁₁, v₁₂, v₁₃, v₁₄, v₁₅] is set as v₀=0, v₁=0, v₂=0, v₃=0, v₄=0, v₅=0, v₆=0, v₇=0, v₈=0, v₉=0, v₁₀=0, and v₁₂=0. A third specific example is given in Algorithm 4B of Table 5.

TABLE 5
Example Algorithms 4A-4B

| Algorithm 4A | Algorithm 4B |
|---|---|
| k = 0; | k = 0; |
| For i = 0 to N−1 | For i = 0 to N−1 |
| If i ϵ Q | If i ϵ Q |
| vᵢ = cₖ; | vᵢ = cₖ; |
| k = k + 1; | k = k + 1; |
| Else | Else |
| vᵢ = f₁₋ₖ; | vᵢ = 0; |
| End if | End if |
| End for | End for |

In some embodiments, the rate profiling output sequence v of length N is the multiplication of the rate profiling input bit sequence c and the rate profiling matrix F with K rows and N columns as v=c·F. The rate profiling input bit sequence is the input sequence c of length K, the vector-matrix multiplication is over GF(2). In a specific example with K=4 rows and N=8 columns, a rate profiling matrix

$$F = [ \begin{matrix}0 & 0 & 0 & 1 & 0 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1\end{matrix} ] ,$$

a rate profiling input bit sequence c=[c₀, c₁, c₂, c₃], then a profiling output sequence v=c·F=[0, 0, 0, c₀, 0, c₁, c₂, c₃].

In some embodiments, the rate profiling output sequence v of length N is determined by adding the rate profiling frozen bit sequence f and the multiplication of the rate profiling input bit sequence c and the rate profiling matrix F with K rows and N columns as v=c·F+f. The rate profiling input bit sequence is the input sequence c of length K, the vector-matrix multiplication is over GF(2), the vector-vector addition is over GF(2), the rate profiling frozen bit sequence f is of length N. In a specific example with K=4 rows and N=8 columns, a rate profiling matrix

$$F = [ \begin{matrix}0 & 0 & 0 & 1 & 0 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1\end{matrix} ] ,$$

a rate profiling input bit sequence c=[c₀, c₁, c₂, c₃], a rate profiling frozen bit sequence f=[f₀, f₁, f₂, f₃, f₄, f₅, f₆, f₇], then a profiling output sequence v=c·F+f=[f₀, f₁, f₂, mod(c₀+f₃, 2), f₄, mod(c₁+f₅, 2), mod(c₂+f₆, 2), mod(c₃+f₇, 2)].

Parameters for determining the pre-transform: The pre-transform determines the pre-transform output bit sequence u corresponding to the pre-transform input bit sequence v by the first node using at least one of the following: the generator bit sequence g=[g₀, g₁, . . . , gₘ] over GF(2), the generator polynomial g(D)=g₀+g₁·D+ . . . +gₘ₋₁·Dₘ₋₁+gₘ·D^{m} over GF(2), the recursive feedback bit sequence q=[q₀, q₁, . . . , qₘ]over GF(2), the recursive feedback polynomial q(D)=q₀+q₁·D++qₘ·D^{m} over GF(2), the state bit sequence t=[t₀, t₁, . . . , tₘ₋₁, tₘ] of length m+1, the pre-transform matrix T with N rows and N columns, the precoding input index set P_{I}, the precoding output index set P_{O}, or the precoding frozen bit sequence h.

### A Pre-Transform Determined by the Pre-Transform Matrix T

In some embodiments, the pre-transform output sequence u of length N is the multiplication of the pre-transform input bit sequence and the pre-transform matrix T with N rows and N columns as u=v·T. The pre-transform input bit sequence is the rate profiling output sequence v of length N, the pre-transform output sequence u of length N is the precoding output bit sequence, the vector-matrix multiplication is over GF(2).

### A Pre-Transform Determined by the Pre-Transform Matrix T and the Precoding Frozen Bit Sequence h

In some embodiments, the pre-transform output sequence u of length N is determined by adding the precoding frozen bit sequence h and the multiplication of the pre-transform input bit sequence v and the pre-transform matrix T with N rows and N columns as u=v·T+h. The pre-transform input bit sequence is the rate profiling output bit sequence v of length N, the vector-matrix multiplication is over GF(2), the vector-vector addition is over GF(2), the length of precoding frozen bit sequence h is equal to the polar matrix size N.

A Pre-Transform Determined by g or g(D), t, P_{I}, P_{O}, h

In some embodiments, the pre-transform determines the pre-transform output bit sequence u of length N using at least one of the following: the generator bit sequence g=[g₀, g₁, . . . , gₘ], the generator polynomial g(D)=g₀+g₁·D+ . . . +gₘ₋₁·Dₘ₋₁+gₘ·D^{m} over GF(2), the precoding input index set P_{I}, the precoding output index set P_{O}, or the precoding frozen bit sequence h. The precoding frozen bit sequence h is of length N−N_{PO} and N_{PO} is the size of the precoding output index set P_{O}. Table 6 shows example Algorithms 5A-5G, which are example implementations for the pre-transform.

TABLE 6
Example Pre-Transform Implementations

| Algorithm 5A | Algorithm 5B | Algorithm 5C |
|---|---|---|
| | | k′= 0; |
| For i = 0 to N−1 | For i = 0 to N−1 | For i = 0 to N−1 |
| If i ϵ Po | If i ϵ Po | If i ϵ Po |
| k = 0; | k = 0; | k = 0; |
| j = 0; | j = 0; | j = 0; |
| uᵢ = 0; | uᵢ = 0; | uᵢ = 0; |
| While k ≤ m && j ≤ | While k ≤ m && j ≤ | While k ≤ m && j ≤ |
| i | i | i |
| If i − j ϵ P_{I} | If i − j ϵ P_{I} | If i − j ϵ P_{I} |
| uᵢ=mod(uᵢ+gₖ·vᵢ₋ⱼ, | uᵢ=mod(uᵢ+gₖ·vᵢ₋ⱼ, | uᵢ=mod(uᵢ+gₖ·vᵢ₋ⱼ, |
| 2); | 2); | 2); |
| k = k + 1; | k = k + 1; | k = k + 1; |
| End if | End if | End if |
| j = j + 1; | j = j + 1; | j = j + 1; |
| End while | End while | End while |
| Else | Else | Else |
| uᵢ = 0; | uᵢ = vᵢ, | uᵢ = h_{k′}; |
| End if | End if | k′= k′+ 1; |
| End for | End for | End if |
| | | End for |
| Algorithm 5D | Algorithm 5E | Algorithm 5F |
| | | k′= 0; |
| For i = 0 to N−1 | For i = 0 to N−1 | For i = 0 to N−1 |
| If i ϵ Po | If i ϵ Po | If i ϵ Po |
| k = 0; | k = 0; | k = 0; |
| uᵢ = 0; | uᵢ = 0; | uᵢ = 0; |
| While k ≤ m && k ≤ | While k ≤ m && k ≤ | While k ≤ m && k ≤ |
| i | i | i |
| uᵢ=mod(uᵢ+gₖ·vᵢ₋ⱼ, | uᵢ=mod(uᵢ+gₖ·vᵢ₋ⱼ, | uᵢ=mod(uᵢ+gₖ·vᵢ₋ⱼ, |
| 2); | 2); | 2); |
| k = k + 1; | k = k + 1; | k = k + 1; |
| End while | End while | End while |
| Else | Else | Else |
| uᵢ = 0; | uᵢ = vᵢ, | uᵢ = h_{k′}; |
| End if | End if | k′= k′ + 1; |
| End for | End for | End if |
| | | End for |
| Algorithm 5G | | |
| For i = 0 to N−1 | | |
| k = 0; | | |
| j = 0; | | |
| uᵢ = 0; | | |
| While k ≤ m && j ≤ i | | |
| If i − j ϵ P_{I} | | |
| uᵢ=mod(uᵢ+gₖ·vᵢ₋ⱼ, | | |
| 2); | | |
| k = k + 1; | | |
| End if | | |
| j = j + 1; | | |
| End while | | |
| End for | | |

In some embodiments, if an index i belongs to the precoding output index set P_{O}, the bit with the index i (uᵢ) of the pre-transform output bit sequence u is determined by at least one of the following: the generator bit sequence g=[g₀, g₁, . . . , gₘ], the generator polynomial g(D)=g₀+g₁·D+ . . . +μm′D™ over GF(2), and L bits in the pre-transform input bit sequence v=[v₀, v₁, . . . , v_{N-1}] with indices being the Z largest values in a first intersection set M₁. The first intersection set M₁ is the intersection set of a set with non-negative integers not greater than i ({0, 1, . . . , i−1, i}) and the precoding input index set P_{I}. L=min(|M₁|, min(i+1, m+1)) with |M₁| being the number of elements in the first intersection set M₁.

A first specific example with N=16, i=3, m=6, a generator polynomial g(D)=g₀+g₁·D+g₂·D²+g₃·D³+g₄·D⁴+g₅·D⁵+g₆·D⁶, a precoding output index set P_{O}={0, 1, 2, 3, 4, 5, 6, 7, 8, 9, 10}, and a precoding input index set P_{I}={0, 2, 3, 5, 7, 8, 10} is:
(1) a first intersection set M₁ is M₁={0, 1, 2, 3}∩P_{I}={0, 1, 2, 3}∩{0, 2, 3, 5, 7, 8, 10}={0, 2, 3};

$$L = min ( \vert {M}_{1} \vert , min ( i + 1 , m + 1 ) ) = min ( 3 , min ( 3 + 1 , 6 + 1 ) ) = 3 ; \qquad ( 2 )$$

(3) L=3 bits in the pre-transform input bit sequence v=[v₀, v₁, v₂, v₃, v₄, v₅, v₆, v₇, v₈, v₉, v₁₀, v₁₁, v₁₂, v₁₃, v₁₄, v₁₅] with indices being the L=3 largest values in the first intersection set M₁={0, 2, 3} are v₃, v₂ and v₀;
(4) Finally, the bit with index i=3 of the pre-transform output bit sequence u is uᵢ=mod(g₀·v₃+g₁·v₂+g₂·v₀, 2).

A second specific example with N=16, i=9, m=3, a generator sequence g=[g₀, g₁, g₂, g₃], a precoding output index set P_{O}={0, 1, 2, 3, 4, 5, 6, 7, 8, 9, 10}, and precoding input index set P_{I}={0, 2, 3, 5, 7, 8, 10} is:
(1) the first intersection set M₁ is M₁={0, 1, 2, 3, 4, 5, 6, 7, 8, 9}∩P_{I}={0, 1, 2, 3, 4, 5, 6, 7, 8, 9}∩{0, 2, 3, 5, 7, 8, 10}={0, 2, 3, 5, 7, 8};

$$L = min ( \vert {M}_{1} \vert , min ( i + 1 , m + 1 ) ) = min ( 6 , min ( 9 + 1 , 3 + 1 ) ) = 4 ; \qquad ( 2 )$$

(3) L=4 bits in the pre-transform input bit sequence v=[v₀, v₁, v₂, v₃, v₄, v₅, v₆, v₇, v₈, v₉, v₁₀, v₁₁, v₁₂, v₁₃, v₁₄, v₁₅] with indices being the L=4 largest values in the first intersection set M₁={0, 2, 3, 5, 7, 8} are v₈, v₇, v₅, v₃;
(4) Finally, the bit with index i=9 of the pre-transform output bit sequence u is u₉=mod(g₀·v₈+g₁·v₇+g₂·v₅+g₃·v₃, 2).

In some embodiments, if an index i belongs to the precoding output index set P_{O}, the bit with the index i (uᵢ) of the pre-transform output bit sequence u is determined by at least one of the following: the generator bit sequence g=[g₀, g₁, . . . , gₘ], the generator polynomial g(D)=g₀+g₁·D+ . . . +gₘ·D^{m} over GF(2), and/or L bits vᵢ, vᵢ₋₁, . . . , v_{i-L+1} in the pre-transform input bit sequence v=[v₀, v₁, . . . , v_{N-1}] with indices being the L largest values in a set with non-negative integers not greater than i ({0, 1, . . . , i−1, i}), where L=min(i+1, m+1).

A first specific example with i=3, m=6, a precoding output index set P_{O}={0, 1, 2, 3, 4, 5, 6, 7, 8, 9, 10}, and a generator polynomial g(D)=g₀+g₁·D+g₂·D²+g₃·D³+g₄·D⁴+g₅·D⁵+g₆·D⁶ is
(1) the set with non-negative integers not greater than i=3 is {0, 1, 2, 3};

$$L = min ( i + 1 , m + 1 ) = min ( 3 + 1 , 6 + 1 ) = 4 ; \qquad ( 2 )$$

(3) L=4 bits in the pre-transform input bit sequence v=[v₀, v₁, . . . , v_{N-1}] with indices being the L=4 largest values in the set {0, 1, 2, 3} are v₃, v₂, v₁, and v₀;
(4) Finally, the i-th bit uᵢ is uᵢ=mod(g₀·v₃+g₁·v₂+g₂·v₁+g₃·v₀, 2).

A second specific example with N=16, i=9, m=3, a precoding output index set P_{O}={0, 1, 2, 3, 4, 5, 6, 7, 8, 9, 10}, and a generator sequence g=[g₀, g₁, g₂, g₃] is
(1) the set with non-negative integers not greater than i=9 is {0, 1, 2, 3, 4, 5, 6, 7, 8, 9};

$$L = min ( i + 1 , m + 1 ) = min ( 9 + 1 , 3 + 1 ) = 4 ; \qquad ( 2 )$$

(3) L=4 bits in the pre-transform input bit sequence v=[v₀, v₁, v₂, v₃, v₄, v₅, v₆, v₇, v₈, v₉, v₁₀, v₁₁, v₁₂, v₁₃, v₁₄, v₁₅] with indices being the L=4 largest values in the set {0, 1, 2, 3, 4, 5, 6, 7, 8, 9} are v₉, v₈, v₇, v₆;
(4) Finally, the bit with index i=9 of the pre-transform output bit sequence u is 119=mod(g₀·v₉+g₁·v₈+g₂ v₇+g₃·v₆, 2).

In some embodiments, for any index i, the bit with the index i (uᵢ) of the pre-transform output bit sequence u is determined by at least one of the following: the generator bit sequence g=[g₀, g₁, . . . , gₘ], the generator polynomial g(D)=g₀+g₁·D+ . . . +gₘ·D^{m} over GF(2), and/or L bits in the pre-transform input bit sequence v=[v₀, v₁, . . . , v_{N-1}] with indices being the L largest values in a first intersection set M₁. The first intersection set M₁ is the intersection set of a set with non-negative integers not greater than i ({0, 1, . . . , i−1, i}) and the precoding input index set P_{I}, and L=min(|M₁|, min(i+1, m+1)) with |M₁| being the number of elements in the first intersection set M₁.

A first specific example with N=16, i=2, m=6, a generator polynomial g(D)=g₀+g₁·D+g₂·D²+g₃·D³+g₄·D⁴+g₅·D⁵+g₆·D⁶, and a precoding input index set P_{I}={0, 2, 3, 5, 7, 8, 10} is:
(1) a first intersection set M₁ is M₁={0, 1, 2}∩P_{I}={0, 1, 2}∩{0, 2, 3, 5, 7, 8, 10}={0, 2};

$$L = min ( \vert {M}_{1} \vert , min ( i + 1 , m + 1 ) ) = min ( 2 , min ( 3 + 1 , 6 + 1 ) ) = 2 ; \qquad ( 2 )$$

(3) L=2 bits in the pre-transform input bit sequence v=[v₀, v₁, v₂, v₃, v₄, v₅, v₆, v₇, v₈, v₉, v₁₀, v₁₁, v₁₂, v₁₃, v₁₄, v₁₅] with indices being the L=2 largest values in the first intersection set M₁={0, 2} are v₂, and v₀;
(4) Finally, the bit with index i=2 of the pre-transform output bit sequence u is 12=mod(g₀·v₂+g₁·v₀, 2).

A second specific example with N=16, i=9, m=3, a generator sequence g=[g₀, g₁, g₂, g₃], and a precoding input index set P_{I}={0, 2, 5, 7, 8, 10} is:
(1) the first intersection set M₁ is M₁={0, 1, 2, 3, 4, 5, 6, 7, 8, 9}∩P_{I}={0, 1, 2, 3, 4, 5, 6, 7, 8, 9}∩{0, 2, 5, 7, 8, 10}={0, 2, 5, 7, 8};

$$L = min ( \vert {M}_{1} \vert , min ( i + 1 , m + 1 ) ) = min ( 5 , min ( 9 + 1 , 3 + 1 ) ) = 4 ; \qquad ( 2 )$$

(3) L=4 bits in the pre-transform input bit sequence v=[v₀, v₁, v₂, v₃, v₄, v₅, v₆, v₇, v₈, v₉, v₁₀, v₁₁, v₁₂, v₁₃, v₁₄, v₁₅] with indices being the L=4 largest values in the first intersection set M₁ is v₈, v₇, v₅, v₂;
(4) Finally, the bit with index i=9 of the pre-transform output bit sequence u is 119=mod(g₀·v₈+g₁·v₇+g₂ v₅+g₃·v₂, 2),

In some examples, if an index i does not belong to the pre-transform output index set P_{O}, the bit with the index i (uᵢ) of the pre-transform output bit sequence u is set to 0, e.g., as in Algorithms 5A and 5D. In some examples, if an index i does not belong to the pre-transform output index set P_{O}, the bit with the index i (uᵢ) of the pre-transform output bit sequence u is set to the i-th bit vᵢ of the pre-transform input bit sequence v, e.g., as in Algorithms 5B and 5E. In some examples, if an index i does not belong to the pre-transform output index set P_{O}, the bit with the index i (u₁) of the pre-transform output bit sequence u is set to a bit in the precoding frozen bit sequence h as in Algorithm 5C, and 5F, wherein the precoding frozen bit sequence h is of length N−N_{PO} and N_{PO} is the size of the precoding output index set P_{O}.

In Algorithms 5A-5G, N is the polar matrix size, m is the memory length, vᵢ is the bit with index i in the pre-transform input bit sequence, uᵢ is the bit with index i in the pre-transform output bit sequence, gₖ is the bit with index k in the generator sequence g=[g₀, g₁, . . . , gₘ] or the coefficient of the term with degree K in the generator polynomial g(D)=g₀+g₁·D+ . . . +gₘ₋₁·Dₘ₋₁+gₘ·D^{m} over GF(2).

A pre-transform determined by q or q(D), t, P_{I}, P_{O}, h

In some embodiments, the pre-transform determines the pre-transform output bit sequence u of length N using at least one of the following: the recursive feedback bit sequence q=[q₀, q₁, . . . , qₘ], the recursive feedback polynomial q(D)=q₀+q₁·D+ . . . +qₘ₋₁·Dₘ₋₁+qₘ·D^{m} over GF(2), the precoding input index set P_{I}, the precoding output index set P_{O}, or the precoding frozen bit sequence h. The precoding frozen bit sequence h is of length N−N_{PO} and N_{PO} is the size of the precoding output index set P_{O}. Table 7 shows example algorithms 6A-6G, which are example implementations for the pre-transform.

TABLE 7
Example Pre-Transform Implementations

| Algorithm 6A | Algorithm 6B | Algorithm 6C |
|---|---|---|
| | | k′= 0; |
| For i = 0 to N−1 | For i = 0 to N−1 | For i = 0 to N−1 |
| If i ϵ Po | If i ϵ Po | If i ϵ Po |
| k = 1; | k = 1; | k = 1; |
| j = 1; | j = 1; | j = 1; |
| uᵢ = q₀·vᵢ, | uᵢ = q₀·vᵢ, | uᵢ = q₀·vᵢ, |
| While k ≤ m && j ≤ i | While k ≤ m && j ≤ i | While k ≤ m && j ≤ i |
| If i − j ϵ P_{I} | If i − j ϵ P_{I} | If i − j ϵ P_{I} |
| uᵢ=mod(uᵢ+gₖ·vᵢ₋ⱼ, | uᵢ=mod(uᵢ+gₖ·vᵢ₋ⱼ, | uᵢ=mod(uᵢ+gₖ·vᵢ₋ⱼ, |
| 2); | 2); | 2); |
| k = k + 1; | k = k + 1; | k = k + 1; |
| End if | End if | End if |
| j = j + 1; | j = j + 1; | j = j + 1; |
| End while | End while | End while |
| Else | Else | Else |
| uᵢ = 0; | uᵢ = vᵢ, | uᵢ = h_{k′}; |
| End if | End if | k′= k′+ 1; |
| End for | End for | End if |
| | | End for |
| Algorithm 6D | Algorithm 6E | Algorithm 6F |
| | | k′= 0; |
| For i = 0 to N−1 | For i = 0 to N−1 | For i = 0 to N−1 |
| If i ϵ Po | If i ϵ Po | If i ϵ Po |
| k = 1; | k = 1; | k = 1; |
| uᵢ = q₀·vᵢ, | uᵢ = q₀·vᵢ, | uᵢ = q₀·vᵢ, |
| While k ≤ m && k ≤ i | While k ≤ m && k ≤ i | While k ≤ m &&k ≤ i |
| uᵢ=mod(uᵢ + gₖ·vᵢ₋ⱼ, | uᵢ=mod(uᵢ + gₖ·vᵢ₋ⱼ, | uᵢ=mod(uᵢ + gₖ·vᵢ₋ⱼ, |
| 2); | 2); | 2); |
| k = k + 1; | k = k + 1; | k = k + 1; |
| End while | End while | End while |
| Else | Else | Else |
| uᵢ = 0; | uᵢ = vᵢ, | uᵢ = h_{k′}; |
| End if | End if | k′= k′+ 1; |
| End for | End for | End if |
| | | End for |
| Algorithm 6G | | |
| For i = 0 to N−1 | | |
| k = 1; | | |
| j = 1; | | |
| uᵢ = q₀·vᵢ, | | |
| While k ≤ m && j ≤ i | | |
| If i − j ϵ P_{I} | | |
| uᵢ = mod(uᵢ + gₖ·vᵢ₋ⱼ, | | |
| 2); | | |
| k = k + 1; | | |
| End if | | |
| j = j + 1; | | |
| End while | | |
| End for | | |

In some embodiments, if an index i belongs to the pre-transform output index set P_{O}, the bit with the index i (uᵢ) of the pre-transform output bit sequence u is determined by at least one of the following: the recursive feedback bit sequence q=[q₀, q₁, . . . , qₘ], the recursive feedback polynomial q(D)=q₀+q₁·D+ . . . +qₘ′D^{m} over GF(2), the i-th bit vᵢ in the pre-transform input bit sequence v=[v₀, v₁, . . . , v_{N-1}], and/or L bits in the pre-transform output bit sequence u=[u₀, u₁, . . . , u_{N-1}] with indices being the L largest values in a second intersection set M₂. The second intersection set M₂ is the intersection set of a set with non-negative integers smaller than i({0, 1, . . . , i−2, i−1}) and the pre-transform output index set P_{I}, and L=min(|M₂|, min(i, m)) with |M₂| being the number of elements in the second intersection set M₂ (e.g., as shown in Algorithm 6A, 6B, and 6C of Table 7). A first specific example with N=16, i=3, m=6, a recursive feedback polynomial q(D)=g₀+q₁·D+q₂·D²+q₃·D³+q₄·D⁴+q₅·D⁵+q₆·D⁶ with q₀=1, a precoding output index set P_{O}={0, 1, 2, 3, 4, 5, 6, 7, 8, 9, 10}, and a precoding input index set P_{I}={0, 2, 3, 5, 7, 8, 10} is:
(1) a second intersection set M₂ is M₂={0, 1, 2}∩P_{I}={0, 1, 2}∩{0, 2, 3, 5, 7, 8, 10}={0, 2};

$$L = min ( \vert {M}_{2} \vert , min ( i , m ) ) = min ( 2 , min ( 3 , 6 ) ) = 2 ; \qquad ( 2 )$$

(3) L=2 bits in the pre-transform input bit sequence v=[v₀, v₁, v₂, v₃, v₄, v₅, v₆, v₇, v₈, v₉, v₁₀, v₁₁, v₁₂, v₁₃, v₁₄, v₁₅] with indices being the L=2 largest values in the second intersection set M₂ are v₂ and v₀;
(4) Finally, the bit with index i=3 of the pre-transform output bit sequence u is u₃=mod(q₀·v₃+q₁·u₂+q₂·u₀, 2)=mod(v₃+q₁·u₂+q₂·u₀, 2) since q₀=1.

A second specific example with N=16, i=9, m=3, a recursive feedback sequence q=[q₀, q₁, q₂, q₃] with q₀=1, a precoding output index set P_{O}={0, 1, 2, 3, 4, 5, 6, 7, 8, 9, 10}, and a precoding input index set P_{I}={0, 2, 3, 5, 7, 8, 10} is:
(1) the second intersection set M₂ is M₂={0, 1, 2, 3, 4, 5, 6, 7, 8}∩P_{I}={0, 1, 2, 3, 4, 5, 6, 7, 8}∩{0, 2, 3, 5, 7, 8, 10}={0, 2, 3, 5, 7, 8};

$$L = min ( \vert {M}_{2} \vert , min ( i , m ) ) = min ( 6 , min ( 9 , 3 ) ) = 3 ; \qquad ( 2 )$$

(3) L=3 bits in the pre-transform input bit sequence v=[v₀, v₁, v₂, v₃, v₄, v₅, v₆, v₇, v₈, v₉, v₁₀, v₁₁, v₁₂, v₁₃, v₁₄, v₁₅] with indices being the L=3 largest values in the intersection set M₂={0, 2, 3, 5, 7, 8} are v₈, v₇, and v₅;
(4) Finally, the bit with index i=9 of the pre-transform output bit sequence u is 19=mod(q₀·v₉+q₁·u₈+q₂·u₇+g₃·u₅, 2)=mod(v₉+q₁·u₈+q₂·u₇+g₃·u₅, 2) since q₀=1.

In some embodiments, if an index i belongs to the precoding output index set P_{O}, the bit with index i (uᵢ) of the pre-transform output bit sequence u is determined by at least one of the following: the recursive feedback bit sequence q=[q₀, q₁, . . . , qₘ], the recursive feedback polynomial q(D)=q₀+q₁D+ . . . +qₘ′D™ over GF(2), the bit with index i (vᵢ) in the pre-transform input bit sequence v=[v₀, v₁, . . . , v_{N-1}], and/or L bits uᵢ₋₁, uᵢ₋₂, . . . , u_{i-L} in the pre-transform output bit sequence u=[u₀, u₁, . . . , u_{N-1}] with indices being the L largest values in a set with non-negative integers smaller than i {0, 1, . . . , i−2, i−1}. L=min(i, m) (e.g., as shown in Algorithm 6D, 6E, and 6F).

A first specific example with N=16, i=3, m=6, a precoding output index set P_{O}={0, 1, 2, 3, 4, 5, 6, 7, 8, 9, 10}, and a recursive feedback polynomial q(D)=90+q₁·D+q₂·D²+q₃·D³+q₄·D⁴+q₅·D⁵+q₆·D⁶ is:
(1) the set with non-negative integers smaller than i=3 is {0, 1, 2};
(2) L=min(i, m)=min(3, 6)=3;
(3) L=3 bits in the pre-transform output bit sequence u=[10, 11, . . . , u_{N-1}] with indices being the L=3 largest values in the set {0, 1, 2} is u₂, u₁, and u₀;
(4) Finally, the bit with index i=3 of the pre-transform output bit sequence u is uᵢ=mod(q₀·v₃+q₁·u₂+q₂·u₁+q₃·u₀, 2).

A second specific example with N=16, i=9, m=3, a recursive feedback q=[q₀, q₁, q₂, q₃] with q₀=1, and a precoding output index set P_{O}={0, 1, 2, 3, 4, 5, 6, 7, 8, 9, 10}, is:
(1) a set with non-negative integers smaller than i=9 is {0, 1, 2, 3, 4, 5, 6, 7, 8};
(2) L=min(i,m)=min(9,3)=3;
(3) L=3 bits in the pre-transform output bit sequence u=[u₀, u₁, u₂, u₃, u₄, u₅, u₆, u₇, u₈, u₉, u₁₀, u₁₁, u₁₂, u₁₃, u₁₄, u₁₅] with indices being the L=3 largest values in the set {0, 1, 2, 3, 4, 5, 6, 7, 8} is 118, 117, and 146;
(4) Finally, the bit with index i=9 of the pre-transform output bit sequence u is uᵢ=mod(q₀·v₉+q₁·u₈+q₂·u₇+q₃·u₆, 2)==mod(v₉+q₁·u₈+q₂·u₇+q₃·u₆, 2) since q₀=1.

In some embodiments, for any index i, the bit with the index i (uᵢ) of the pre-transform output bit sequence u is determined by at least one of the following: the recursive feedback bit sequence q=[q₀, q₁, . . . , qₘ], the recursive feedback polynomial q(D)=q₀+q₁·D+ . . . +qₘ·D^{m} over GF(2), the i-th bit vᵢ in the pre-transform input bit sequence v=[v₀, vᵢ, . . . , v_{N-1}], and/or L bits in the pre-transform output bit sequence u=[u₀, u₁, . . . , u_{N-1}] with indices being the L largest values in a second intersection set M₂. The second intersection set M₂ is the intersection set of a set with non-negative integers smaller than i ({0, 1, . . . , i−2, i−1}) and the precoding output index set P_{I}, and L=min(|M₂|, min(i, m)) with |M₂| being the number of elements in the second intersection set M₂ (e.g., as shown in Algorithm 6G).

A first specific example with N=16, i=3, m=6, a recursive feedback polynomial q(D)=q₀+q₁·D+q₂·D²+q₃·D³+q₄·D⁴+q₅·D⁵+q₆·D⁶ with q₀=1, and a precoding input index set P_{I}={0, 2, 3, 5, 7, 8, 10} is:
(1) a second intersection set M₂ is M₂={0, 1, 2}∩P_{I}={0, 1, 2}∩{0, 2, 3, 5, 7, 8, 10}={0, 2};

$$L = min ( \vert {M}_{2} \vert , min ( i , m ) ) = min ( 2 , min ( 3 , 6 ) ) = 2 ; \qquad ( 2 )$$

(3) L=2 bits in the pre-transform output bit sequence u=[u₀, u₁, u₂, u₃, u₄, u₅, u₆, u₇, u₈, u₉, u₁₀, u₁₁, u₁₂, u₁₃, u₁₄, u₁₅] with indices being the L=₂ largest values in the second intersection set M₂ are u₂ and u₀;
(4) Finally, the bit with index i=3 of the pre-transform output bit sequence u is ⅓=mod(q₀·v₃+q₁·u₂+q₂·u₀, 2)=mod(v₃+q₁·u₂+q₂·u₀, 2) since q₀=1.

A second specific example with N=16, i=9, m=3, a recursive feedback sequence q=[q₀, q₁, q₂, q₃] with q₀=1, and a precoding input index set P_{I}={0, 2, 3, 5, 7, 8, 10} is
(1) the second intersection set M₂ is M₂={0, 1, 2, 3, 4, 5, 6, 7, 8}∩P_{I}={0, 1, 2, 3, 4, 5, 6, 7, 8}∩{0, 2, 3, 5, 7, 8, 10}={0, 2, 3, 5, 7, 8};

$$L = min ( \vert {M}_{2} \vert , min ( i , m ) ) = min ( 6 , min ( 9 , 3 ) ) = 3 ; \qquad ( 2 )$$

(3) L=3 bits in the pre-transform output bit sequence u=[u₀, u₁, u₂, u₃, u₄, u₅, u₆, u₇, u₈, u₉, u₁₀, u₁₁, u₁₂, u₁₃, u₁₄, u₁₅] with indices being the L=3 largest values in the intersection set M₂={0, 2, 3, 5, 7, 8} are u₈, u₇, and u₅;
(4) Finally, the bit with index i=9 of the pre-transform output bit sequence u is u₉=mod(q₀·v₉+q₁·u₈+q₂·u₇+q₃·u₅, 2)=mod(v₉+q₁·u₈+q₂·u₇+q₃·u₅, 2) since q₀=1.

In some embodiments, if an index i does not belong to the precoding output index set P_{O}, the bit with the index i (uᵢ) of the pre-transform output bit sequence u is set to 0 (e.g., as in Algorithms 6A and 6D). In some embodiments, if an index i does not belong to the pre-transform output index set P_{O}, the bit with the index i (uᵢ) of the pre-transform output bit sequence u is set to the i-th bit vᵢ of the pre-transform input bit sequence v (e.g., as in Algorithms 6B and 6E). In some embodiments, if an index i does not belong to the pre-transform output index set P_{O}, the bit with the index i (uᵢ) of the pre-transform output bit sequence u is set to a bit in the precoding frozen bit sequence h (e.g., as in Algorithms 6C and 6F). The precoding frozen bit sequence h is of length N−N_{PO} and N_{PO} is the size of the precoding output index set P_{O}.

In example Algorithms 6A-6G, Nis the polar matrix size, m is the memory length, vᵢ is the bit with index i in the pre-transform input bit sequence, uᵢ is the bit with index i in the pre-transform output bit sequence, q is the bit with index k in the recursive feedback sequence q=[q₀, q₁, . . . , qₘ] or the coefficient of the term with degree K in the recursive feedback polynomial q(D)=q₀+q₁·D+ . . . +qₘ₋₁. Dₘ₋₁+qₘ·D^{m} over GF(2).

A Pre-Transform Determined by g or g(D), q or q(D), t, P_{I}, P_{O}, h

In some embodiments, the pre-transform determines the precoding output bit sequence u of length N using at least one of the following: the generator bit sequence g=[g₀, g₁, . . . , gₘ], the generator polynomial g(D)=g₀+g₁·D+ . . . +gₘ₋₁·Dₘ₋₁+gₘ·D^{m} over GF(2), the recursive feedback bit sequence q=[q₀, q₁, . . . , qₘ], the recursive feedback polynomial q(D)=q₀+q₁·D+ . . . +qₘ₋₁·Dₘ₋₁+qₘ·D^{m} over GF(2), the precoding input index set P_{I}, the precoding output index set P_{O}, the precoding frozen bit sequence h, or the state bit sequence t=[t₀, t₁, . . . , tₘ₋₁, tₘ] of length m+1. The precoding frozen bit sequence h is of length N−N_{PO} and N_{PO} is the size of the precoding output index set P_{O}. Examples of implementation for the pre-transform can be found in Algorithms 7A-7G of Table 8.

In some embodiments, if an index i belongs to the precoding output index set P_{O}, the bit with the index i (uᵢ) of the pre-transform output bit sequence u is determined based on at least one of: the bit with index i (vᵢ) of the pre-transform input bit sequence v, the generator bit sequence g=[g₀, g₁, . . . , gₘ], the generator polynomial g(D)=g₀+g₁·D+ . . . +gₘ·D^{m} over GF(2), the recursive feedback bit sequence q=[q₀, q₁, . . . , qₘ], the recursive feedback polynomial q(D)=90+q₁·D+ . . . +qₘ·D^{m} over GF(2), and/or the state bit sequence t=[t₀, t₁, . . . , tₘ₋₁, tₘ]. The pre-transform can be implemented using example implementations given in Algorithms 7A-7G of Table 8. The pre-transform can comprise setting, by the first node, the bit with index 0 in the state bit sequence t to be the bit with index i (vᵢ) of the precoding input bit sequence v, t₀=vᵢ, determining, by the first node, a summation bit s by the recursive feedback bit sequence q=[q₀, q₁, . . . , qₘ] (or the recursive feedback polynomial q(D)=q₀+q₁D+ . . . +qₘ·D^{m} over GF(2)) and the updated state bit sequence t=[t₀, t₁, . . . , tₘ₋₁, tₘ] as s=mod(Σⱼ₌₀^{m} qⱼ·tⱼ, 2), setting, by the first node, the bit with index 0 in the state bit sequence t to the summation bit s, t₀=s, and determining, by the first node, the bit with index i (uᵢ) of the precoding output bit sequence u by the generator bit sequence g=[g₀, g₁, . . . , gₘ] (or the generator polynomial g(D)=g₀+g₁·D+ . . . +gₘ·D^{m} over GF(2)) and the updated state bit sequence t=[10, 11, . . . , tₘ₋₁, tₘ] as uᵢ=mod(Σⱼ₌₀^{m} qⱼ·tⱼ, 2).

Table 8 shows example Algorithms 7A-7G, which are example implementations for the pre-transform.

TABLE 8
Another Example Pre-Transform Implementations

| Algorithm 7A | Algorithm 7B | Algorithm 7C |
|---|---|---|
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Po | If i ϵ Po | If i ϵ Po |
| s = 0; | s = 0; | s = 0; |
| t₀ = vᵢ, | t₀ = vᵢ, | t₀ = vᵢ, |
| For j = 0 to m | For j = 0 to m | For j = 0 to m |
| s = mod(s + qⱼ·tⱼ, | s = mod(s + qⱼ·tⱼ, | s = mod(s + qⱼ·tⱼ, |
| 2); | 2); | 2); |
| End for | End for | End for |
| t₀ = s; | t₀ = s; | t₀ = s; |
| uᵢ = 0; | uᵢ = 0; | uᵢ = 0; |
| For j = 0 to m | For j = 0 to m | For j = 0 to m |
| uᵢ = mod(uᵢ + gⱼ·tⱼ, | uᵢ = mod(uᵢ + gⱼ·tⱼ, | uᵢ = mod(uᵢ + gⱼ·tⱼ, |
| 2); | 2); | 2); |
| End for | End for | End for |
| Else | Else | Else |
| uᵢ = 0; | uᵢ = vᵢ, | uᵢ = h_{k′}; |
| End if | End if | k′ = k′ + 1; |
| | | End if |
| If i ϵ P_{I} | If i ϵ P_{I} | If i ϵ P_{I} |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| t₀ = 0; | t₀ = 0; | t₀ = 0; |
| End if | End if | End if |
| End for | End for | End for |
| Algorithm 7D | Algorithm 7E | Algorithm 7F |
| For j = 0 to m | For j = 0 to m | For j = 0 to m |
| tⱼ = 0; | tⱼ = 0; | tⱼ = 0; |
| End for | End for | End for |
| | | k = 0; |
| k = 0; | k = 0; | k′ = 0; |
| For i = 0 to N−1 | For i = 0 to N−1 | For i = 0 to N−1 |
| If i ϵ Po | If i ϵ Po | If i ϵ Po |
| s = 0; | s = 0; | s = 0; |
| t₀ = vᵢ, | t₀ = vᵢ, | t₀ = vᵢ, |
| For j = 0 to m | For j = 0 to m | For j = 0 to m |
| s = mod(s + qⱼ·tⱼ, | s = mod(s + qⱼ·tⱼ, | s = mod(s + qⱼ·tⱼ, |
| 2); | 2); | 2); |
| End for | End for | End for |
| t₀ = s; | t₀ = s; | t₀ = s; |
| uᵢ = 0; | uᵢ = 0; | uᵢ = 0; |
| For j = 0 to m | For j = 0 to m | For j = 0 to m |
| uᵢ = mod(uᵢ + gⱼ·tⱼ, | uᵢ = mod(uᵢ + gⱼ·tⱼ, | uᵢ = mod(uᵢ + gⱼ·tⱼ, |
| 2); | 2); | 2); |
| End for | End for | End for |
| Else | Else | Else |
| uᵢ = 0; | uᵢ = vᵢ, | uᵢ = h_{k′}; |
| End if | End if | k′ = k′ + 1; |
| | | End if |
| For j = m to 1 | For j = m to 1 | For j = m to 1 |
| tⱼ = tⱼ₋₁; | tⱼ = tⱼ₋₁; | tⱼ = tⱼ₋₁; |
| End for | End for | End for |
| t₀ = 0; | t₀ = 0; | t₀ = 0; |
| End for | End for | End for |
| Algorithm 7G | | |
| For j = 0 to m | | |
| tⱼ = 0; | | |
| End for | | |
| k = 0; | | |
| For i = 0 to N−1 | | |
| s = 0; | | |
| t₀ = vᵢ, | | |
| For j = 1 to m | | |
| s = mod(s + qⱼ·tⱼ, 2); | | |
| End for | | |
| t₀ = s; | | |
| uᵢ = 0; | | |
| For j = 0 to m | | |
| uᵢ = mod(uᵢ + gⱼ·tⱼ, | | |
| 2); | | |
| End for | | |
| If i ϵ P_{I} | | |
| For j = m to 1 | | |
| tⱼ = tⱼ₋₁; | | |
| End for | | |
| t₀ = 0; | | |
| End if | | |
| End for | | |

In some embodiments, if an index i does not belong to the precoding output index set P_{O}, the bit with the index i (uᵢ) of the pre-transform output bit sequence u is set to 0, e.g., as in Algorithms 7A and 7D. In some embodiments, if an index i does not belong to the precoding output index set P_{O}, the bit with the index i (uᵢ) of the pre-transform output bit sequence u is set to the bit with index i (vᵢ) of the pre-transform input bit sequence v, e.g., as in Algorithms 7B and 7E. In some embodiments, if an index i does not belong to the precoding output index set P_{O}, the bit with the index i (uᵢ) of the pre-transform output bit sequence u is set to a bit in the precoding frozen bit sequence h, e.g., as in Algorithms 7C and 7F, wherein the precoding frozen bit sequence h is of length N−N_{PO} and N_{PO} is the size of the precoding output index set P_{O}. In some embodiments, if an index i belongs to the precoding input index set P_{I}, a right shift is performed on the state bit sequence t=[t₀, t₁, . . . , tₘ₋₁, tₘ] and the bit with index 0 (t₀) in the state bit sequence tis set to 0 as follows, e.g., as in Algorithms 7A, 7B, 7C, and 7G.

For j = m to 1
tⱼ = tⱼ₋₁;
End for
t₀ = 0;

In some embodiments, for any index i, a right shift is performed on the state bit sequence t=[t₀, t₁, . . . , tₘ₋₁, tₘ] and the bit with index 0 (t₀) in the state bit sequence t is set to 0 as follows, e.g., as in Algorithms 7D, 7E, and 7F.

For j = m to 1
tⱼ = tⱼ₋₁;
End for
t₀ = 0;

In Algorithms 7A-7G, N is the polar matrix size, m is the memory length, vᵢ is the bit with index i in the pre-transform input bit sequence, uᵢ is the bit with index i in the pre-transform output bit sequence, qₖ is the bit with index k in the recursive feedback sequence q=[q₀, q₁, . . . , qₘ] or the coefficient of the term with degree K in the recursive feedback polynomial q(D)=90+q₁·D+ . . . +qₘ₋₁·D™-1+qₘ·D^{m} over GF(2), gₖ is the bit with index k in the generator sequence g=[g₀, g₁, . . . , gₘ] or the coefficient of the term with degree K in the generator polynomial g(D)=g₀+g₁·D+ . . . +gₘ₋₁·Dₘ₋₁+gₘ·D^{m} over GF(2).

Polar Transform: A polar transform comprises obtaining, by the first node, a polar transform input bit sequence; and determining, by the first node, a polar transform output bit sequence d=[d₀, d₁, . . . , d_{N-1}]. Both the polar transform input bit sequence and the polar transform output bit sequence d are of length equal to the polar matrix size N. The polar transform output bit sequence d is determined by the first node by multiplying the polar transform input bit sequence u and the polar matrix G^{(N)} of N rows and N columns, d=u·G^{(N)}, wherein the vector-matrix multiplication is performed over GF(2). In some embodiments, the polar transform input bit sequence is the precoding output bit sequence u=[u₀, u₁, . . . , u_{N-1}] of length N as shown in FIGS. 5A-5C. In some embodiments, the polar transform input bit sequence is the pre-transform output bit sequence u=[u₀, u₁, . . . , u_{N-1}] of length N, as shown in FIGS. 8A-8C.

Rate Matching: A rate matching comprises obtaining, by the first node, a rate matching input bit sequence; and determining, by the first node, a rate matching output bit sequence. The rate matching input bit sequence is the polar transform output bit sequence d=[d₀, d₁, . . . , d_{N-1}] of length N. The rate matching output bit sequence is the output bit sequence e=[e₀, e₁, . . . , e_{E-1}] of length E. N is the polar matrix size. Specific examples of rating matching are shown in FIG. 5A and FIG. 8A.

In some embodiments, the rate matching determines the rate matching output bit sequence d corresponding to the rate matching input bit sequence e by the first node using the ordered rate matching index set R=<R(0), R(1), . . . , R(Nᵣ−2), R(Nᵣ−1)>, wherein Nᵣ is the ordered rate matching index set size and Nᵣ is equal to the minimum value between N and E, Nᵣ=min(N, E); wherein N is N is the polar matrix size. E is the length of the rate matching output bit sequence or the length of the output bit sequence e. A first specific example is eₖ=d_{R(mod(k,N)}, k=0, 1, 2, . . . , E−2, E−1. A second specific example is eₖ=d_{R(k)}, k=0, 1, 2, . . . , E−2, E−1.

A third specific example is:

For k = 0 to E−1
eₖ = d_{R(k)};
End for

A fourth specific example is:

For k = 0 to E−1
eₖ = d_{R(mod(k,N))};
End for

### Interleaving

In some embodiments, the rate matching comprises an interleaving. The interleaving comprises obtaining, by the first node, an interleaving input bit sequence; and determining, by the first node, an interleaving output bit sequence d′=[d′₀, d′₁, . . . , d′_{N-1}]. Nis the polar matrix size. The interleaving input bit sequence is the polar transform output bit sequence d=[d₀, d₁, . . . , d_{N-1}] of length N. The interleaving output bit sequence d′=[d′₀, d′₁, . . . , d′_{N-1}] is of length N.

In some embodiments, the interleaving determines the interleaving output bit sequence d′=[d′₀, d′₁, . . . , d′_{N-1}] corresponding to the interleaving input bit sequence by an interleaver pattern J=[J₀, J₁, . . . , J_{N-2}, J_{N-1}] of length N as d′i=d_{J}_{ᵢ}, i=0, 1, 2, . . . , N−2, N−1, the i-th bits of the interleaving output bit sequence d′ is equal to the Jᵢ-th bit of the interleaving input bit sequence d=[d₀, d₁, . . . , d_{N-1}]. The interleaver pattern J can be any permutation of the integer sequence [0, 1, 2, . . . , N−2, N−1].

A first specific example of the interleaver pattern J=[J₀, J₁, . . . , J_{N-2}, J_{N-1}] is determined as:

```
For i = 0 to N−1
  j = floor(32i/N);
  Jᵢ = πⱼ×(N/32) + mod(i, N/32);
End for
```

π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] is a sub-block interleaver pattern and N is the polar matrix size.

A second specific example of the interleaver pattern J=[J₀, J₁, . . . , J_{N-2}, J_{N-1}] is that the relationship between the index i and the i-th element Jᵢ in the interleaver pattern J satisfies the following quadratic form: Jᵢ=mod(f₁·i+f₂·i², N). Some examples of parameters f₁ and f₂ depending on the polar matrix size N are summarized in Table 9.

TABLE 9
Example Interleaver Parameters

| N | f₁ | f₂ |
|---|---|---|
| 64 | 7 | 16 |
| 128 | 15 | 32 |
| 256 | 15 | 32 |
| 512 | 31 | 64 |
| 1024 | 31 | 64 |
| 2048 | 31 | 64 |
| 4096 | 31 | 64 |

### Bit Selection

In some embodiments, the rate matching comprises an bit selection. The bit selection comprises obtaining, by the first node, a bit selection input bit sequence, and determining, by the first node, a bit selection output bit sequence. The bit selection output bit sequence is the output bit sequence e=[e₀, e₁, . . . , e_{E-1}] of length E. In some embodiments, the bit selection input bit sequence is the polar transform output bit sequence d of length N, wherein N is the polar matrix size. Specific examples are shown in FIG. 5B and FIG. 8B.

A first specific example is that the bit selection determines the bit selection output bit sequence e=[e₀, e₁, . . . , e_{E-1}] to be the first E bits in the bit selection input bit sequence d=[d₀, d₁, . . . , dv] as eₖ=dₖ, k=0, 1, 2, . . . , E−2, E−1. E is not greater than N.

A second specific example is that the bit selection determines the bit selection output bit sequence e=[e₀, e₁, . . . , e_{E-1}] to be the last E bits in the bit selection input bit sequence d=[d₀, d₁, . . . , d_{N}] as eₖ=d_{N-E+k}, k=0, 1, 2, . . . , E−2, E−1. E is not greater than N.

A third specific example is that the bit selection determines the bit selection output bit sequence e=[e₀, e₁, . . . , e_{E-1}] to be the repetition of bits in the bit selection input bit sequence d=[d₀, d₁, . . . , d_{N}] as eₖ=d_{mod(k,N)}, k=0, 1, 2, . . . , E−2, E−1. E is not less than N.

In some embodiments, the bit selection input bit sequence is the interleaving output bit sequence d′ of length N, wherein N is the polar matrix size. Examples are shown in FIG. 5C and FIG. 8C.

A first specific example is that the bit selection determines the bit selection output bit sequence e=[e₀, e₁, . . . , e_{E-1}] to be the first E bits in the interleaving output bit sequence d′=[d′₀, d′₁, . . . , d′_{N-1}] as eₖ=d′, k=0, 1, 2, . . . , E−2, E−1. E is not greater than N.

A second specific example is that the bit selection determines the bit selection output bit sequence e=[e₀, e₁, . . . , e_{E-1}] to be the last E bits in the interleaving output bit sequence d′=[d′₀, d′₁, . . . , d′_{N-1}] as eₖ=d′N−E+k, k=0, 1, 2, . . . , E−2, E−1. E is not greater than N.

A third specific example is that the bit selection determines the bit selection output bit sequence e=[e₀, e₁, . . . , e_{E-1}] to be the repetition of bits in the interleaving output bit sequence d′=[d′₀, d′1, . . . , d′_{N-1}] as eₖ=d′_{mod(k,N)}, k=0, 1, 2, . . . , E−2, E−1. E is not less than N.

Second Interleaving after Rate Matching

In some embodiments, the output sequence e=[e₀, e₁, . . . , e_{E-1}] is further interleaved into a second output bit sequence f=[f₀, f₁, . . . , f_{E-1}], wherein E is the length of the output sequence e.

Modulation after Rate Matching or Second Interleaving

In some embodiments, the output sequence e=[e₀, e₁, . . . , e_{E-1}] is further modulated into a first output symbol sequence x=[x₀, x₁, . . . , X_{E/Qm-1}] using one of the following modulation schemes: π/2 binary phase shift keying (π/2-BPSK), binary phase shift keying (BPSK), quadrature phase shift keying (QPSK), quadrature amplitude modulation (QAM), phase shift keying (PSK), amplitude shift keying (ASK), or amplitude phase shift keying (APSK). Qₘ is the modulation order.

In some embodiments, the second output bit sequence f=[f₀, f₁, . . . , f_{E-1}] is further modulated into a first output symbol sequence x=[x₀, x₁, . . . , X_{E/Qm-1}] using one of the following modulation schemes: π/2 binary phase shift keying (π/2-BPSK), binary phase shift keying (BPSK), quadrature phase shift keying (QPSK), quadrature amplitude modulation (QAM), phase shift keying (PSK), amplitude shift keying (ASK), or amplitude phase shift keying (APSK). Qₘ is the modulation order.

### Input Bit Sequence c Comprising CRC Bits

In some embodiments, the input bit sequence c comprises Lcrc cyclic redundancy check (CRC) bits determined by a cyclic generator polynomial g′ (D)=g′_{Lcrc}·D^{Lcrc}+g′_{Lcrc-1}·D^{Lcrc-1}+ . . . +g′₂·D²+g′₁·D+g′₀ with coefficients over GF(2) and K-Lcrc payload bits.

In some embodiments, the input bit sequence c is determined by the first node by attaching Lcrc cyclic redundancy check (CRC) bit to a payload sequence of length K-Lcrc, wherein, the Lcrc CRC bits are determined by a cyclic generator polynomial g′(D)=g′_{Lcrc}·D^{Lcrc}+g′_{Lcrc-1}·D^{Lcrc-1}+ . . . +g′₂·D²+g′₁·D+g′₀ with coefficients over GF(2).

Some additional examples of the disclosed coding scheme are described below.

### Example 1

In Example 1, a first node obtains an input bit sequence c=[c₀, c₁, c₂, c₃, c₄, c₅, c₆, c₇, c₈, c₉, c₁₀, c₁₁, c₁₂, c₁₃, c₁₄, c₁₅, c₁₆, c₁₇, c₁₈, c₁₉, c₂₀, c₂₁, c₂₂, c₂₃] of length K=24. As shown in FIG. 5A, the first node performs the following to determine an output bit sequence e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28:
(1) Perform a precoding with the input bit sequence c of length K=24 as a precoding input bit sequence to obtain a precoding output bit sequence u=[u₀, u₁, u₂, u₃, u₄, u₅, u₆, u₇, u₈, u₉, u₁₀, u₁₁, u₁₂, u₁₃, u₁₄, u₁₅, u₁₆, u₁₇, u₁₈, u₁₉, u₂₀, u₂₁, u₂₂, u₂₃, u₂₄, u₂₅, u₂₆, u₂₇, u₂₈, u₂₉, u₃₀, u₃₁] of length N=32 by performing vector-matrix multiplication on the input bit sequence c and a precoding matrix W with K=24 rows and N=32 columns and then vector addition on a precoding frozen bit sequence h of length N=32 as u=c·W+h. The precoding matrix W is

$$W = [ \begin{matrix}0 , 0 , 0 , 0 , 0 , 0 , 1 , 0 , 0 , 0 , 0 , 0 , 0 , 0 , 1 , 0 , 0 , 0 , 0 , 0 , 0 , 0 , 0 , 0 , 0 , 1 , 0 , 0 , 0 , 0 , 0 , 0 \\ 0 , 0 , 0 , 0 , 0 , 0 , 0 , 1 , 0 , 1 , 0 , 0 , 0 , 0 , 0 , 1 , 0 , 0 , 0 , 0 , 0 , 0 , 0 , 0 , 0 , 0 , 1 , 0 , 0 , 0 , 0 , 0 \\ 0 , 0 , 0 , 0 , 0 , 0 , 0 , 0 , 0 , 1 , 1 , 0 , 1 , 0 , 0 , 0 , 0 , 0 , 0 , 0 , 0 , 0 , 0 , 0 , 0 , 0 , 0 , 1 , 0 , 0 , 0 , 0 \\ 0 , 0 , 0 , 0 , 0 , 0 , 0 , 0 , 0 , 0 , 1 , 1 , 0 , 1 , 0 , 0 , 0 , 0 , 0 , 0 , 0 , 0 , 0 , 0 , 1 , 0 , 0 , 0 , 0 , 0 , 0 , 0 \\ 0 , 0 , 0 , 0 , 0 , 0 , 0 , 0 , 0 , 0 , 0 , 1 , 0 , 0 , 1 , 0 , 0 , 1 , 0 , 0 , 0 , 1 , 0 , 0 , 0 , 0 , 1 , 0 , 1 , 0 , 0 , 0 \\ 0 , 0 , 0 , 0 , 0 , 0 , 0 , 0 , 0 , 0 , 0 , 0 , 1 , 0 , 0 , 1 , 0 , 0 , 1 , 0 , 0 , 0 , 1 , 0 , 0 , 0 , 0 , 1 , 0 , 1 , 0 , 0 \\ 0 , 0 , 0 , 0 , 0 , 0 , 0 , 0 , 0 , 0 , 0 , 0 , 0 , 1 , 0 , 0 , 0 , 0 , 0 , 1 , 0 , 0 , 0 , 1 , 1 , 0 , 0 , 0 , 0 , 0 , 1 , 0 \\ 0 , 0 , 0 , 0 , 0 , 0 , 0 , 0 , 0 , 0 , 0 , 0 , 0 , 0 , 1 , 0 , 0 , 0 , 0 , 0 , 1 , 0 , 0 , 0 , 0 , 1 , 0 , 0 , 0 , 0 , 0 , 1 \\ 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 1 , 0 , 0 , 0 , 0 , 1 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 1 , 0 , 0 , 0 , 0 , 1 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 1 , 1 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 1 , 0 , 0 , 0 , 0 , 1 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 1 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1\end{matrix} ]$$

and the precoding frozen bit sequence h is an all-zero vector.
(2) Perform a polar transform with the precoding output bit sequence u as a polar transform input bit sequence using a polar matrix G⁽³²⁾=B⁽³²⁾·P⁽³²⁾ of size N=32 to obtain a polar transform output bit sequence d=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 as d=u·G⁽³²⁾, wherein, the matrix operation is over GF(2),

$${P}^{( N )} = [ \begin{matrix}{P}^{( N / 2 )} & 0 \\ {P}^{( N / 2 )} & {P}^{( N / 2 )}\end{matrix} ] , and {P}^{( 2 )} = [ \begin{matrix}1 & 0 \\ 1 & 1\end{matrix} ] .$$

(3) Perform a rate matching with the polar transform output bit sequence d=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 as a rate matching input bit sequence to obtain a rate matching output bit sequence (also an output bit sequence) e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28 as eᵢ=d_{J}_{ᵢ} for i=0, 1, 2, . . . , 26, 27. J=[J₀, J₁, J₂, J₃, J₄, J₅, J₆, J₇, J₈, J₉, J₁₀, J₁₁, J₁₂, J₁₃, J₁₄, J₁₅, J₁₆, J₁₇, J₁₈, J₁₉, J₂₀, J₂₁, J₂₂, J₂₃, J₂₄, J₂₅, J₂₆, J₂₇, J₂₈, J₂₉, J₃₀, J₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] is an interleaver pattern of length N=32.

After the rate matching, the first node transmits a signal including the output bit sequence e to a second node.

### Example 2

In Example 2, a second node receives a signal including an output bit sequence e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28 sent by a first node. The second node determines an estimated bit sequence of an input bit sequence c=[c₀, c₁, c₂, c₃, c₄, c₅, c₆, c₇, c₈, c₉, c₁₀, c₁₁, c₁₂, c₁₃, c₁₄, c₁₅, c₁₆, c₁₇, c₁₈, c₁₉, c₂₀, c₂₁, c₂₂, c₂₃] of length K=24. As shown in FIG. 5B, the output bit sequence e is determined by the first node as follows:
(1) Perform a precoding with the input bit sequence c of length K=24 as a precoding input bit sequence to obtain a precoding output bit sequence u=[10, 11, 12, 13, 14, 15, 16, 147, 118, 119, u₁₀, u₁₁, u₁₂, u₁₃, u₁₄, u₁₅, u₁₆, u₁₇, u₁₈, u₁₉, u₂₀, u₂₁, u₂₂, u₂₃, u₂₄, u₂₅, u₂₆, u₂₇, u₂₈, u₂₉, u₃₀, u₃₁] of length N=32 using the following:
a data bit index set Q={9, 6, 17, 10, 18, 12, 20, 24, 7, 11, 19, 13, 14, 21, 26, 25, 22, 28, 15, 23, 31, 27, 29, 30},
a generator polynomial g(D)=g₀+g₁·D+ . . . +gₘ·D^{m}=1+D+D³ over GF(2) or equivalently a generator bit sequence g=[g₀, g₁, g₂, g₃]=[1, 1, 0, 1] with a memory length m=3,
a precoding input index set P_{I}={0, 1, 2, . . . , Qₘₐₓ−1, Qₘₐₓ}={0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31} with Qₘₐₓ=31 being the element with the largest value in the data bit index set Q, and
a precoding output index set P_{O}={0, 1, 2, 3, 4, 5, 6, 7, 8, 9, 10, 11, 12, 13, 14, 15, 16, 17, 18, 19, 20, 21, 22, 23, 24, 25, 26, 27} with all elements from an ordered rate matching index set R=<R(0), R(1), R(2), R(3), R(4), R(5), R(6), R(7), R(8), R(9), R(10), R(11), R(12), R(13), R(14), R(15), R(16), R(17), R(18), R(19), R(20), R(21), R(22), R(23), R(24), R(25), R(26), R(27)>=<0, 1, 2, 3, 4, 5, 6, 7, 8, 9, 10, 11, 12, 13, 14, 15, 16, 17, 18, 19, 20, 21, 22, 23, 24, 25, 26, 27>. The precoding is as follows (e.g., see also Algorithm 1A of Table 2).

```
For j = 0 to m
  tⱼ = 0;
End for
k = 0;
For i = 0 to N-1
    If i ∈ Q
        t₀ = cₖ;
        k = k + 1;
    Else
      t₀ = 0;
    End if
    If i ∈ Pₒ
        uᵢ = 0;
        For j = 0 to m
            uᵢ = mod(uᵢ + gⱼ·tⱼ, 2);
        End for
    Else
      uᵢ = 0;
    End if
    If i ∈ P_{I}
        For j = m to 1
          tⱼ = tⱼ₋₁;
        End for
    End if
End for
```

(2) Perform a polar transform with the precoding output bit sequence u as a polar transform input bit sequence using a polar matrix G⁽³²⁾=P⁽³²⁾ of size N=32 to obtain a polar transform output bit sequence d=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 as d=u·G⁽³²⁾, wherein, the matrix operation is over GF(2),

$${P}^{( N )} = [ \begin{matrix}{P}^{( N / 2 )} & 0 \\ {P}^{( N / 2 )} & {P}^{( N / 2 )}\end{matrix} ] , and {P}^{( 2 )} = [ \begin{matrix}1 & 0 \\ 1 & 1\end{matrix} ] .$$

(3) Perform a bit selection with the polar transform output bit sequence u=[u₀, u₁, u₂, u₃, u₄, u₅, u₆, u₇, u₈, u₉, u₁₀, u₁₁, u₁₂, u₁₃, u₁₄, u₁₅, u₁₆, u₁₇, u₁₈, u₁₉, u₂₀, u₂₁, u₂₂, u₂₃, u₂₄, u₂₅, u₂₆, u₂₇, u₂₈, u₂₉, u₃₀, u₃₁] of length N=32 as a rate matching input bit sequence to obtain a rate matching output bit sequence (also an output bit sequence) e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28 as eᵢ=d_{R(i)} for i=0, 1, 2, . . . , 26, 27. The bit selection is according to an ordered rate matching index set R=<R(0), R(1), R(2), R(3), R(4), R(5), R(6), R(7), R(8), R(9), R(10), R(11), R(12), R(13), R(14), R(15), R(16), R(17), R(18), R(19), R(20), R(21), R(22), R(23), R(24), R(25), R(26), R(27)>=<0, 1, 2, 3, 4, 5, 6, 7, 8, 9, 10, 11, 12, 13, 14, 15, 16, 17, 18, 19, 20, 21, 22, 23, 24, 25, 26, 27> with all elements being non-negative integers less than the output bit sequence length E=28.

### Example 3

In Example 3, a first node obtains an input bit sequence c=[c₀, c₁, c₂, c₃, c₄, c₅, c₆, c₇, c₈, c₉, c₁₀, c₁₁, c₁₂, c₁₃, c₁₄, c₁₅, c₁₆, c₁₇, c₁₈, c₁₉, c₂₀, c₂₁, c₂₂, c₂₃] of length K=24. As shown in FIG. 5C, the first node performs the following to determine an output bit sequence e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28:
(1) Perform a precoding with the input bit sequence c of length K=24 as a precoding input bit sequence to obtain a precoding output bit sequence u=[u₀, u₁, u₂, u₃, u₄, u₅, u₆, u₁₇, u₁₈, u₁₉, u₁₀, u₁₁, u₁₂, u₁₃, u₁₄, u₁₅, u₁₆, u₁₇, u₁₈, u₁₉, u₂₀, u₂₁, u₂₂, u₂₃, u₂₄, u₂₅, u₂₆, u₂₇, u₂₈, u₂₉, u₃₀, u₃₁] of length N=32 using the following:
a data bit index set Q={9, 6, 17, 10, 18, 12, 20, 24, 7, 11, 19, 13, 14, 21, 26, 25, 22, 28, 15, 23, 31, 27, 29, 30} with K=24 elements,
a rate profiling frozen bit sequence f of length N-K=32−24=8 with all elements being 0,
a recursive feedback polynomial q(D)=q₀+q₁·D+ . . . +qₘ·D^{m}=1+D²+D³ over GF(2) or equivalently a recursive feedback bit sequence q=[q₀, q₁, q₂, g₃]=[1, 0, 1, 1] with a memory length m=3,

a precoding input index set P_{I}={0, 1, 2, 4, 3, 5, 6, 7, 8, 16, 9, 17, 10, 18, 11, 19, 12, 20, 13, 21, 14, 22, 15, 23, 24, 25, 26, 28} with all elements from an ordered rate matching index set R=<R(0), R(1), R(2), R(3), R(4), R(5), R(6), R(7), R(8), R(9), R(10), R(11), R(12), R(13), R(14), R(15), R(16), R(17), R(18), R(19), R(20), R(21), R(22), R(23), R(24), R(25), R(26), R(27)>=<0, 1, 2, 4, 3, 5, 6, 7, 8, 16, 9, 17, 10, 18, 11, 19, 12, 20, 13, 21, 14, 22, 15, 23, 24, 25, 26, 28>, and

a precoding output index set P_{O}={0, 1, 2, . . . , Rₘₐₓ−1, Rₘₐₓ}={0, 1, 2, 3, 4, 5, 6, 7, 8, 9, 10, 11, 12, 13, 14, 15, 16, 17, 18, 19, 20, 21, 22, 23, 24, 25, 26, 27, 28} with all elements being non-negative integers not greater than the maximum value Rₘₐₓ=28 in the ordered rate matching index set R.

The precoding is as follows (e.g., see also Algorithm 2E of Table 3).

```
For j = 0 to m
  tⱼ = 0;
End for
k = 0;
For i = 0 to N-1
    If i ∈ Q
        t₀ = cₖ,
        k = k + 1;
    Else
        t₀ = fᵢ₋ₖ;
    End if
    If i ∈ Pₒ
        uᵢ = 0;
        For j = 0 to m
          uᵢ = mod(uⱼ +q·tⱼ, 2);
        End for
        t₀ = uᵢ,
    Else
      uᵢ = t₀;
    End if
    If i ∈ P_{I}
      For j = m to 1
            tj = tⱼ₋₁;
        End for
    End if
End for
```

(2) Perform a polar transform with the precoding output bit sequence u as a polar transform input bit sequence using a polar matrix G⁽³²⁾=(P⁽²⁾)^{⊗5} of size N=32 to obtain a polar transform output bit sequence d=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 as d=u·G⁽³²⁾, wherein, the matrix operation is over GF(2),

$${P}^{( 2 )} = [ \begin{matrix}1 & 0 \\ 1 & 1\end{matrix} ] ,$$

(P⁽²⁾)^{⊗5} is the 5-th Kronecker power of the matrix P⁽²⁾.
(3) Perform an interleaving on an interleaving input sequence being the polar transform output bit sequence d=[d₀, d₁, . . . , d_{N-1}]=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 and determine an interleaving output bit sequence d′=[d′₀, d′1, . . . , d′_{N-1}]=[d′₀, d′₁, d′₂, d′₃, d′₄, d′₅, d′₆, d′₇, d′₈, d′₉, d′₁₀, d′₁₁, d′₁₂, d′₁₃, d′₁₄, d′₁₅, d′₁₆, d′₁₇, d′₁₈, d′₁₉, d′₂₀, d′₂₁, d′₂₂, d′₂₃, d′₂₄, d′₂₅, d′₂₆, d′₂₇, d′₂₈, d′₂₉, d′₃₀, d′₃₁] is of length N=32 as d′i=d_{J}_{ᵢ} for i=0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31 (i-th bits of the interleaving output bit sequence d′ is equal to the Jᵢ-th bit of the interleaving input bit sequence d). J=[J₀, J₁, . . . , J_{N-2}, J_{N-1}]=[J₀, J₁, J₂, J₃, J₄, J₅, J₀, J₇, J₈, J₀, J₁₀, J₁₁, J₁₂, J₁₃, J₁₄, J₁₅, J₁₆, J₁₇, J₁₈, J₁₉, J₂₀, J₂₁, J₂₂, J₂₃, J₂₄, J₂₅, J₂₆, J₂₇, J₂₈, J₂₉, J₃₀, J₃₁] is an interleaver pattern determined according to a sub-block interleaver pattern π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] as follows.

```
For i = 0 to N−1
  j = floor(32i/N);
  Jᵢ = πⱼ×(N/32) + mod(i, N/32);
End for
```

(4) Perform a bit selection with the interleaving output bit sequence d′=[d′₀, d′₁, d′₂, d′₃, d′₄, d′₅, d′₆, d′₇, d′₈, d′₉, d′₁₀, d′₁₁, d′₁₂, d′₁₃, d′₁₄, d′₁₅, d′₁₆, d′₁₇, d′₁₈, d′₁₉, d′₂₀, d′₂₁, d′₂₂, d′₂₃, d′₂₄, d′₂₅, d′₂₆, d′₂₇, d′₂₈, d′₂₉, d′₃₀, d′₃₁] of length N=32 as a bit selection input bit sequence to obtain a rate matching output bit sequence (also an output bit sequence) e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28 as eᵢ=d′ᵢ for i=0, 1, 2, . . . , 26, 27 (eᵢ=d_{J}_{ᵢ} for i=0, 1, 2, . . . , 26, 27). The bit selection is according to an ordered rate matching index set R=<R(0), R(1), R(2), R(3), R(4), R(5), R(6), R(7), R(8), R(9), R(10), R(11), R(12), R(13), R(14), R(15), R(16), R(17), R(18), R(19), R(20), R(21), R(22), R(23), R(24), R(25), R(26), R(27)>=<J₀, J₁, J₂, J₃, J₄, J₅, J₆, J₇, J₈, J₉₀, J₁₀, J₁₁, J₁₂, J₁₃, J₁₄, J₁₅, J₁₆, J₁₇, J₁₈, J₁₉, J₂₀, J₂₁, J₂₂, J₂₃, J₂₄, J₂₅, J₂₆, J₂₇> with all elements being elements in the interleaver pattern with indices being non-negative integers less than the output bit sequence length E=28.

After the bit selection, the first node transmits a signal including the output bit sequence e to a second node.

### Example 4

In Example 4, a first node obtains an input bit sequence c=[c₀, c₁, c₂, c₃, c₄, c₅, c₆, c₇, c₈, c₉, c₁₀, c₁₁] of length K=12. As in FIG. 8A, the first node performs the following to determine an output bit sequence e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28:
(1) Perform a rate profiling with the input bit sequence c of length K=12 as a rate profiling input bit sequence to obtain a rate profiling output bit sequence v=[v₀, v₁, v₂, v₃, v₄, v₅, v₆, v₇, v₈, v₉, v₁₀, v₁₁, v₁₂, v₁₃, v₁₄, v₁₅, v₁₆, v₁₇, v₁₈, v₁₉, v₂₀, v₂₁, v₂₂, v₂₃, v₂₄, v₂₅, v₂₆, v₂₇, v₂₈, v₂₉, v₃₀, v₃₁] of length N=32 using the following:
a data bit index set Q={14, 21, 26, 25, 22, 28, 15, 23, 31, 27, 29, 30} with K=12 elements, and
a rate profiling frozen bit sequence f=[f₀, f₁, f₂, f₃, f₄, f₅, f₆, f₇, f₈, f₀, f₁₀, f₁₁, f₁₂, f₁₃, f₁₄, f₁₅, f₁₆, f₁₇, f₁₈, f₁₉]=[0, 0, 1, 1, 0, 0, 0, 1, 1, 1, 0, 1, 1, 0, 0, 0, 1, 0, 1, 0] of length N-K=32−12=20.

The rate profiling output bit sequence vis obtained by setting the bits in the rate profiling output bit sequence v with indices belonging to the data bit index set Q being bits in the input bit sequence c while other bits in the rate profiling output bit sequence v is set to bits in the rate profiling frozen bit sequence f as follows.

```
k = 0;
For i = 0 to N−1
  If i ∈ Q
    vᵢ = cₖ,
    k = k + 1;
  Else
    vᵢ = fᵢ₋ₖ;
  End if
End for
```

(2) Perform a pre-transform with the rate profiling output bit sequence v as a pre-transform input bit sequence and determine a pre-transform output bit sequence u=[u₀, u₁, u₂, u₃, u₄, u₅, u₆, u₇, u₈, u₉, u₁₀, u₁₁, u₁₂, u₁₃, u₁₄, u₁₅, u₁₆, u₁₇, u₁₈, u₁₉, u₂₀, u₂₁, u₂₂, u₂₃, u₂₄, u₂₅, u₂₆, u₂₇, u₂₈, u₂₉, u₃₀, u₃₁] of length N=32 using the following:
a recursive feedback polynomial q(D)=q₀+q₁·D+ . . . +qₘ·D^{m}=1+D²+D³ over GF(2) or equivalently a recursive feedback bit sequence q=[q₀, q₁, q₂, g₃]=[1, 0, 1, 1] with a memory length m=3,
a state bit sequence t=[t₀, t₁, . . . , tₘ₋₁, tₘ]=[t₀, t₁, t₂, t₃] of length m+1=3+1=4,
a precoding output index set P_{O}={0, 1, 2, . . . , Qₘₐₓ−1, Qₘₐₓ}={0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31} with all elements being non-negative integers not greater than the maximum value Qₘₐₓ=31 in the data bit index set Q={14, 21, 26, 25, 22, 28, 15, 23, 31, 27, 29, 30}, and
an empty precoding frozen bit sequence h=[ ] of length N−N_{PO}=32−32=0 with N_{PO}=32 being the size of the precoding output index set P_{O}.

The pre-transform output bit sequence u is determined as follows (e.g., see also Algorithm 7F of Table 8).

```
For j = 0 to m
  tⱼ = 0;
End for
k = 0;
k′ = 0;
For i = 0 to N−1
      If i ∈ Pₒ
          s = 0;
          t₀ = vᵢ,
          For j = 0 to m
            s = mod(s + qⱼ·tⱼ, 2);
          End for
          t₀ = s;
          uᵢ = 0;
          For j = 0 to m
            uᵢ = mod(uᵢ + qⱼ·tⱼ, 2);
          End for
      Else
        uᵢ = h_{k′};
          k′ = k′ + 1;
      End if
    For j = m to 1
          tⱼ = tⱼ₋₁;
      End for
      t₀ = 0;
End for
```

(3) Perform a polar transform with the pre-transform output bit sequence u as a polar transform input bit sequence using a polar matrix G⁽³²⁾=B⁽³²⁾. (P⁽²⁾)^{⊗5} of size N=32 to obtain a polar transform output bit sequence d=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 as d=u·G⁽³²⁾, wherein, the matrix operation is over GF(2),

$${P}^{( 2 )} = [ \begin{matrix}1 & 0 \\ 1 & 1\end{matrix} ] ,$$

(P⁽²⁾)^{⊗5} is the 5-th Kronecker power of the matrix P⁽²⁾, B⁽³²⁾ is a bit-reversal permutation matrix with N=32 rows and N=32 columns.
(4) Perform a rate matching with the polar transform output bit sequence d=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, dis, d₁₉, d₂₀, d₂₁, d₂₂, d₂₃, d₂₄, d₂₅, d₂₆, d₂₇, d₂₈, d₂₉, d₃₀, d₃₁] of length N=32 as a rate matching input bit sequence to obtain a rate matching output bit sequence (also an output bit sequence) e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28 according to an ordered rate matching index set with R as follows: eᵢ=d_{R(N-E+i)} for i=0, 1, 2, . . . , 26, 27. The ordered rate matching index set R=<R(0), R(1), R(2), R(3), R(4), R(5), R(6), R(7), R(8), R(9), R(10), R(11), R(12), R(13), R(14), R(15), R(16), R(17), R(18), R(19), R(20), R(21), R(22), R(23), R(24), R(25), R(26), R(27)>=<J₀, J₁, J₂, J₃, J₄, J₅, J₆, J₇, J₈, J₉, J₁₀, J₁₁, J₁₂, J₁₃, J₁₄, J₁₅, J₁₆, J₁₇, J₁₈, J₁₉, J₂₀, J₂₁, J₂₂, J₂₃, J₂₄, J₂₅, J₂₆, J₂₇> with Jᵢ=mod(f₁·i+f₂·i², N). f₁=7 and f₂=10, and [J₀, J₁, J₂, J₃, J₄, J₅, J₆, J₇, J₈, J₉, J₁₀, J₁₁, J₁₂, J₁₃, J₁₄, J₁₅, J₁₆, J₁₇, J₁₈, J₁₉, J₂₀, J₂₁, J₂₂, J₂₃, J₂₄, J₂₅, J₂₆, J₂₇, J₂₈, J₂₉, J₃₀, J₃₁]=[0, 17, 22, 15, 28, 29, 18, 27, 24, 9, 14, 7, 20, 21, 10, 19, 16, 1, 6, 31, 12, 13, 2, 11, 8, 25, 30, 23, 4, 5, 26, 3] is an interleaver pattern of length N=32.

After the rate matching, the first node transmits a signal including the output bit sequence e to a second node.

### Example 5

In Example 5, a first node obtains an input bit sequence c=[c₀, c₁, c₂, c₃, c₄, c₅, c₆, c₇, c₈, c₉, c₁₀, c₁₁] of length K=12. As in FIG. 8B, the first node performs the following to determine an output bit sequence e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28:
(1) Perform a rate profiling with the input bit sequence c of length K=12 as a rate profiling input bit sequence to obtain a rate profiling output bit sequence v=[v₀, v₁, v₂, v₃, v₄, v₅, v₆, v₇, v₈, v₉, v₁₀, v₁₁, v₁₂, v₁₃, v₁₄, v₁₅, v₁₆, v₁₇, v₁₈, v₁₉, v₂₀, v₂₁, v₂₂, v₂₃, v₂₄, v₂₅, v₂₆, v₂₇, v₂₈, v₂₉, v₃₀, v₃₁] of length N=32 using the following:
a data bit index set Q={14, 21, 26, 25, 22, 28, 15, 23, 31, 27, 29, 30} with K=12 elements,
a rate profiling frozen bit sequence f=[f₀, f₁, f₂, f₃, f₄, f₅, f₆, f₁, f₈, f₉, f₁₀, f₁₁, f₁₂, f₁₃, f₁₄, f₁₅, f₁₆, f₁₇, f₁₈, f₁₉, f₂₀, f₂₁, f₂₂, f₂₃, f₂₄, f₂₅, f₂₆, f₂₇, f₂₈, f₂₉, f₃₀, f₃₁]=[0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0] of length N=32 being an all-zero bit sequence.

The rate profiling output bit sequence v is obtained by setting bits in the rate profiling output bit sequence v with indices belonging to the data bit index set Q being the modulo-2 of a bit in the input bit sequence c and a bit in the rate profiling frozen bit sequence f and setting bits in the rate profiling output bit sequence v with indices not belonging to the data bit index set Q being bits in the rate profiling frozen bit sequence f as follows.

```
k = 0;
For i = 0 to N−1
  If i ∈ Q
    vᵢ = mod(cₖ + fᵢ, 2);
    k = k + 1;
  Else
    vᵢ = fᵢ;
  End if
End for
```

(2) Perform a pre-transform with the rate profiling output bit sequence v as a pre-transform input bit sequence and determine a pre-transform output bit sequence u=[u₀, u₁, u₂, u₃, u₄, u₅, u₆, u₇, u₈, u₉, u₁₀, u₁₁, u₁₂, u₁₃, u₁₄, u₁₅, u₁₆, u₁₇, u₁₈, u₁₉, u₂₀, u₂₁, u₂₂, u₂₃, u₂₄, u₂₅, u₂₆, u₂₇, u₂₈, u₂₉, u₃₀, u₃₁] of length N=32 using the following:
a generator polynomial g(D)=g₀+g₁·D+ . . . +gₘ₋₁·Dₘ₋₁+gₘ·D^{m}=1+D+D³ over GF(2) or equivalently a generator bit sequence g=[g₀, g₁, . . . , gₘ]=[1, 1, 0, 1] over GF(2) with a memory length m=3,
a recursive feedback polynomial q(D)=q₀+q₁·D+ . . . +qₘ·D^{m}=1+D²+D³ over GF(2) or equivalently a recursive feedback bit sequence q=[q₀, q₁, . . . , qₘ]=[1, 0, 1, 1] over GF(2) with a memory length m=3,
a state bit sequence t=[t₀, t₁, . . . , tₘ₋₁, tₘ] of length m+1=3+1=4,
a precoding input index set P_{I}={N−E, N−E+1, N−E+2, . . . , N−2, N−1>=<4, 5, 6, 7, 8, 9, 10, 11, 12, 13, 14, 15, 16, 17, 18, 19, 20, 21, 22, 23, 24, 25, 26, 27, 28, 29, 30, 31}, a precoding input index set P_{O}=P_{I}, and
a precoding frozen bit sequence h=[h₀, h₁, h₂, h₃]=[1, 0, 0, 1] of length N−N_{PO}=32-28=4 with N_{PO}=28 being the size of the precoding input index set P_{O}.

The pre-transform output bit sequence u is determined as follows.

```
For i = 0 to N−1
  If i ∈ Pₒ
    k = 1;
    uᵢ = q₀·vᵢ,
    While k ≤ m && k ≤ i
      uᵢ = mod(uᵢ + qₖ·uᵢ₋ₖ, 2);
      k = k + 1;
    End while
  Else
    uᵢ = vᵢ,
  End if
End for
```

(3) Perform a polar transform with the pre-transform output bit sequence u as a polar transform input bit sequence using a polar matrix (32)=(P⁽²⁾)^{⊗5} of size N=32 to obtain a polar transform output bit sequence d=[d₀, d₁, d₂, d₃, d₄, d₅, d₆, d₇, d₀, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 as d=u·G (32), wherein, the matrix operation is over GF(2),

$${P}^{( 2 )} = [ \begin{matrix}1 & 0 \\ 1 & 1\end{matrix} ] ,$$

(P⁽²⁾)^{⊗5} is the 5-th Kronecker power of the matrix P⁽²⁾, B⁽³²⁾ is a bit-reversal permutation matrix with N=32 rows and N=32 columns.
(4) Perform a bit selection with the polar transform output bit sequence d=[d₀, d₁, d₂, d₃, d₄, d₅, d₆, d₇, d₈, d₉, d₁₀, du, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 as a bit selection input bit sequence to obtain an output bit sequence e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28 as follows: eᵢ=d_{N-E+i} for i=0, 1, 2, . . . , 26, 27. The corresponding ordered rate matching index set R=<R(0), R(1), R(2), R(3), R(4), R(5), R(6), R(7), R(8), R(9), R(10), R(11), R(12), R(13), R(14), R(15), R(16), R(17), R(18), R(19), R(20), R(21), R(22), R(23), R(24), R(25), R(26), R(27)>=<N−E, N−E+1,N−E+2, . . . , N−2, N−1>=<4, 5, 6, 7, 8, 9, 10, 11, 12, 13, 14, 15, 16, 17, 18, 19, 20, 21, 22, 23, 24, 25, 26, 27, 28, 29, 30, 31>.

After the bit selection, the first node transmits a signal including the output bit sequence e to a second node.

### Example 6

In Example 6, a first node obtains an input bit sequence c=[c₀, c₁, c₂, c₃, c₄, c₅, c₆, c₇, c₈, c₉, c₁₀, c₁₁] of length K=12. As in FIG. 8C, the first node performs the following to determine an output bit sequence e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28:
(1) Perform a rate profiling with the input bit sequence c of length K=12 as a rate profiling input bit sequence to obtain a rate profiling output bit sequence v=[v₀, v₁, v₂, v₃, v₄, v₅, v₆, v₇, v₈, v₉, v₁₀, v₁₁, v₁₂, v₁₃, v₁₄, v₁₅, v₁₆, v₁₇, v₁₈, v₁₉, v₂₀, v₂₁, v₂₂, v₂₃, v₂₄, v₂₅, v₂₆, v₂₇, v₂₈, v₂₉, v₃₀, v₃₁] of length N=32 by performing vector-matrix multiplication and vector addition on a rate profiling matrix F with K=12 rows and N=32 columns and a rate profiling frozen bit sequence f over GF(2) as v=c·F+f.

The rate profiling matrix F is

$$F = [ \begin{matrix}0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0 , 0 \\ 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 0 , 1 , 0\end{matrix} ]$$

The rate profiling frozen bit sequence is f=[f₀, f₁, f₂, f₃, f₄, f₅, f₆, f₇, f₈, f₀, f₁₀, f₁₁, f₁₂, f₁₃, f₁₄, f₁₅, f₁₆, f₁₇, f₁₈, f₁₉, f₂₀, f₂₁, f₂₂, f₂₃, f₂₄, f₂₅, f₂₆, f₂₇, f₂₈, f₂₉, f₃₀, f₃₁]=[0, 1, 1, 1, 0, 1, 0, 0, 0, 0, 1, 0, 1, 0, 1, 0, 1, 1, 1, 0, 0, 0, 1, 0, 1, 1, 1, 0, 0, 0, 1].
(2) Perform a pre-transform with the rate profiling output bit sequence v as a pre-transform input bit sequence and determine a pre-transform output bit sequence u=[u₀, u₁, u₂, u₃, u₄, u₅, u₆, u₇, u₈, u₉, u₁₀, u₁₁, u₁₂, u₁₃, u₁₄, u₁₅, u₁₆, u₁₇, u₁₈, u₁₉, u₂₀, u₂₁, u₂₂, u₂₃, u₂₄, u₂₅, u₂₆, u₂₇, u₂₈, u₂₉, u₃₀, u₃₁] of length N=32 by performing vector-matrix multiplication and vector addition on a pre-transform matrix T with N=32 rows and N=32 columns and a precoding frozen bit sequence h=[h₀, h₁, h₂, h₃, h₄, h₅, h₆, h₁, h₈, h₉, h₁₀, h₁₁, h₁₂, h₁₃, h₁₄, his, h₁₆, h₁₇, h₁₈, h₁₉, h₂₀, h₂₁, h₂₂, h₂₃, h₂₄, h₂₅, h₂₆, h₂₇, h₂₈, h₂₉, h₃₀, h₃₁]=[0, 1, 1, 1, 0, 0, 0, 1, 0, 1, 0, 0, 0, 0, 1, 1, 1, 0, 1, 1, 0, 1, 0, 0, 0, 0, 0, 0, 0, 0, 1] of length N=32 over GF(2) as u=v·T+h.

The pre-transform matrix Tis

$$T = \\ [ \begin{matrix}0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 , & 1 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 , & 0 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1 , & 1 \\ 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 0 , & 1\end{matrix} ] \text{}$$

(3) Perform a polar transform with the pre-transform output bit sequence u as a polar transform input bit sequence using a polar matrix G⁽³²⁾=(P⁽²⁾)^{⊗5} of size N=32 to obtain a polar transform output bit sequence d=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 as d=u·G⁽³²⁾. The matrix operation is over GF(2),

$${P}^{( 2 )} = [ \begin{matrix}1 & 0 \\ 1 & 1\end{matrix} ] ,$$

(P⁽²⁾)^{⊗5} is the 5-th Kronecker power of the matrix P⁽²⁾.
(4) Perform an interleaving with an interleaving input sequence being the polar transform output bit sequence d=[d₀, d₁, . . . , d_{N-1}]=[d₀, d₁, d₂, d₃, d₄, d₅, d₆, d₇, d₈, d₉, d₁₀, d₁₁, d₁₂, d₁₃, d₁₄, d₁₅, d₁₆, d₁₇, d₁₈, d₁₉, d₂₀, d₂₁, d₂₂, d₂₃, d₂₄, d₂₅, d₂₆, d₂₇, d₂₈, d₂₉, d₃₀, d₃₁] of length N=32 and determine an interleaving output bit sequence d′=[d′₀, d′₁, . . . , d′_{N-1}]=[d′₀, d′₁, d′₂, d′₃, d′₄, d′₅, d′₀, d′₇, d′₈, d′₉, d′₁₀, d′₁₁, d′₁₂, d′₁₃, d′₁₄, d′₁₅, d′₁₆, d′₁₇, d′₁₈, d′₁₉, d′₂₀, d′₂₁, d′₂₂, d′₂₃, d′₂₄, d′₂₅, d′₂₆, d′₂₇, d′₂₈, d′₂₉, d′₃₀, d′₃₁] is of length N=32 as follows d′i=d_{J}_{ᵢ} for i=0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31 (the i-th bits of the interleaving output bit sequence d′ is equal to the Jᵢ-th bit of the interleaving input bit sequence d). J=[J₀, J₁, . . . , J_{N-2}, J_{N-1}]=[J₀, J₁, J₂, J₃, J₄, J₅, J₆, J₇, J₈, J₀, J₁₀, J₁₁, J₁₂, J₁₃, J₁₄, J₁₅, J₁₆, J₁₇, J₁₈, J₁₉, J₂₀, J₂₁, J₂₂, J₂₃, J₂₄, J₂₅, J₂₆, J₂₇, J₂₈, J₂₉, J₃₀, J₃₁] is an interleaver pattern determined according to a sub-block interleaver pattern π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] as follows.

```
For i = 0 to N−1
  j = floor(32i/N);
  Jᵢ = πⱼ×(N/32) + mod(i, N/32);
End for
```

(5) Perform a bit selection with the interleaving output bit sequence d′ of length N=32 as a bit selection input bit sequence to obtain an output bit sequence e=[e₀, e₁, e₂, e₃, e₄, e₅, e₆, e₇, e₈, e₉, e₁₀, e₁₁, e₁₂, e₁₃, e₁₄, e₁₅, e₁₆, e₁₇, e₁₈, e₁₉, e₂₀, e₂₁, e₂₂, e₂₃, e₂₄, e₂₅, e₂₆, e₂₇] of length E=28 as eᵢ=d′_{N-E+1} for i=0, 1, 2, . . . , 26, 27.

After the bit selection, the first node transmits a signal including the output bit sequence e to a second node.

### Example 7

In Example 7, a first node obtains an input bit sequence c=[c₀, c₁, c₂, . . . , c_{K-2}, c_{K-1}] of length K. The input sequence c comprises Lcrc cyclic redundancy check (CRC) bits determined by a cyclic generator polynomial g′(D)=g′_{Lcrc}·D^{Lcrc}+g′_{Lcrc-1}·D^{Lcrc-1}+ . . . +g′₂·D²+g′₁·D+g′₀ with coefficients over GF(2) and K-Lcrc payload bits. As in FIG. 8C, the first node performs the following to determine an output bit sequence e=[e₀, e₁, . . . , e_{E-2}, e_{E-1}] of length E using a polar matrix of size N:
(1) Perform a rate profiling with the input bit sequence c of length K as a rate profiling input bit sequence to obtain a rate profiling output bit sequence v=[v₀, v₁, . . . , v_{N-2}, v_{N-1}] of length N according to a data bit index set Q, wherein, the data bit index set Q is a K-element subset of a first integer set Z_{N}={0, 1, 2, . . . , N−2, N−1} with the first integer set Z_{N} containing all non-negative integers small than N. The rate profiling output bit sequence v is obtained as follows: a bit in the rate profiling output bit sequence v with indices belonging to the data bit index set Q is set to a bit in the input bit sequence c while a bit in the rate profiling output bit sequence v with indices not belonging to the data bit index set Q is set 0.

```
k = 0;
For i = 0 to N−1
  If i ∈ Q
    vᵢ = cₖ,
    k = k + 1;
  Else
    vᵢ = 0;
  End if
End for
```

(2) Perform a pre-transform with the rate profiling output bit sequence v as a pre-transform input bit sequence and determine a pre-transform output bit sequence u=[u₀, u₁, . . . , u_{N-2}, u_{N-1}] of length N using the following:
a generator polynomial g(D)=g₀+g₁·D+ . . . +gₘ·D^{m} over GF(2) or equivalently a generator bit sequence g=[g₀, g₁, . . . , gₘ] with a memory length m,
a precoding input index set P_{I}={0, 1, 2, . . . , Qₘₐₓ−1, Qₘₐₓ} with all elements being non-negative integers not greater than the value Qₘₐₓ, and
a precoding output index set P_{O}={0, 1, 2, . . . , Qₘₐₓ−1, Qₘₐₓ} with all elements being non-negative integers not greater than the value Qₘₐₓ. Qₘₐₓ is the maximum value in the data bit index set Q,

$${Q}_{max} = {max}_{k ∈ Q} k .$$

Then, the pre-transform output bit sequence u is determined as follows (e.g., see also Algorithm 5A). If an index i does not belong to precoding output index set P_{O}, the i-th bit uᵢ in the pre-transform output bit sequence u is set to 0.

```
For I = 0 to N−1
  If i ∈ Pₒ
      k = 0;
      j = 0;
      uᵢ = 0;
      While k ≤ m && j ≤ i
        If i − j ∈ P_{I}
            uᵢ = mod(uᵢ + gₖ · vᵢ₋ⱼ, 2);
            k = k + 1;
          End if
          j = j + 1;
      End while
  Else
    uᵢ = 0;
  End if
End for
```

(3) Perform a polar transform with the pre-transform output bit sequence u as a polar transform input bit sequence using a polar matrix G^{(N)}=(P⁽²⁾)^{⊗n} of size N to obtain a polar transform output bit sequence d=[d₀, d₁, . . . , d_{N-2}, d_{N-1}] of length N as d=u·G^{(N)}. The matrix operation is over GF(2),

$${P}^{( 2 )} = [ \begin{matrix}1 & 0 \\ 1 & 1\end{matrix} ] ,$$

(P⁽²⁾)^{⊗n} is the 5-th Kronecker power of the matrix P⁽²⁾.
(4) Perform an interleaving with the polar transform output bit sequence d=[d₀, d₁, . . . , d_{N-2}, d_{N-1}] of length N as an interleaving input sequence to obtain an interleaving output bit sequence d′=[d′₀, d′₁, . . . , d′_{N-2}, d′_{N-1}] of length N according to a sub-block interleaver pattern π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] as follows.

```
For i = 0 to N−1
  j = floor(32i/N);
  Jᵢ = πⱼ×(N/32) + mod(i, N/32);
  d′ᵢ = d_{J}_{ᵢ};
End for
```

For i=0, 1, . . . , N−2, N−1, the i-th bits of the interleaving output bit sequence d′ is equal to the Jᵢ-th bit of the interleaving input bit sequence d. J=[J₀, J₁, . . . , J_{N-2}, J_{N-1}] is an interleaver pattern of length N determined by the sub-block interleaver pattern π and the polar matrix size N. The interleaver pattern J=[J₀, J₁, . . . , J_{N-2}, J_{N-1}] is a permutation of the integer sequence [0, 1, 2, . . . , N−2, N−1].
(5) Perform a bit selection with the interleaving output bit sequence d′ of length N as a bit selection input bit sequence to obtain the output bit sequence e of length E as eₖ=d′, k=0, 1, 2, . . . , E−2, E−1. The output bit sequence e comprises bits in the interleaving output bit sequence d′ with indices less than E.

After the bit selection, the first node transmits a signal including the output bit sequence e to a second node.

### Example 8

In Example 8, a first node obtains an input bit sequence c=[c₀, c₁, c₂, . . . , c_{K-2}, c_{K-1}] of length K. The input sequence c comprises Lcrc cyclic redundancy check (CRC) bits determined by a cyclic generator polynomial g′ (D)=g′_{Lcrc}·D^{Lcrc}+g′_{Lcrc-1}·D^{Lcrc-1}+ . . . +g′₂·D²+g′ D+g′₀ with coefficients over GF(2) and K−Lcrc payload bits. As in FIG. 8A, the first node performs the following to determine an output bit sequence e=[e₀, e₁, . . . , e_{E-2}, e_{E-1}] of length E using a polar matrix of size N:
(1) Perform a rate profiling with the input bit sequence c of length K as a rate profiling input bit sequence to obtain a rate profiling output bit sequence v=[v₀, v₁, . . . , v_{N-2}, v_{N-1}] of length N according to a data bit index set Q. The data bit index set Q is a K-element subset of a first integer set Z_{N}={0, 1, 2, . . . , N−2, N−1} with the first integer set Z_{N} containing all non-negative integers small than N. The rate profiling output bit sequence vis obtained as follows: a bit in the rate profiling output bit sequence v with indices belonging to the data bit index set Q is set to a bit in the input bit sequence c while a bit in the rate profiling output bit sequence v with indices not belonging to the data bit index set Q is set 0.

```
k = 0;
For i = 0 to N−1
  If i ∈ Q
    vᵢ = cₖ,
    k = k + 1;
  Else
    vᵢ = 0;
  End if
End for
```

(2) Perform a pre-transform with the rate profiling output bit sequence v as a pre-transform input bit sequence and determine a pre-transform output bit sequence u=[u₀, u₁, . . . , u_{N-2}, U_{N-1}] of length N using the following:

a generator polynomial g(D)=g₀+g₁·D+ . . . +gₘ·D^{m} over GF(2) or equivalently a generator bit sequence g=[g₀, g₁, . . . , gₘ] with a memory length m, a precoding input index set P_{I}, and
a precoding output index set P_{O},

The pre-transform output bit sequence u is determined as follows (e.g., see also Algorithm 5B). If an index i does not belong to the precoding output index set P_{O}, the i-th bit uᵢ in the pre-transform output bit sequence u is set to the i-th bit vᵢ in the pre-transform input bit sequence v.

```
For i = 0 to N−1
  If i ∈ Pₒ
      k = 0;
      j= 0;
      uᵢ = 0;
      While k ≤ m && j ≤ i
        If i − j ∈ P_{I}
            uᵢ = mod(uᵢ + gₖ · Vᵢ₋ⱼ, 2);
            k = k + 1;
          End if
          j = j + 1;
      End while
  Else
    uᵢ = vᵢ,
  End if
End for
```

(3) Perform a polar transform with the pre-transform output bit sequence u as a polar transform input bit sequence using a polar matrix G^{(N)}=(P⁽²⁾)^{⊗n} of size N to obtain a polar transform output bit sequence d=[d₀, d₁, . . . , d_{N-2}, d_{N-1}] of length N as d=u·G^{(N)}. The matrix operation is over

$${P}^{( 2 )} = [ \begin{matrix}1 & 0 \\ 1 & 1\end{matrix} ] ,$$

(4) Perform a rate matching with the polar transform output bit sequence d=[d₀, d₁, . . . , d_{N-2}, d_{N-1}] of length N as a rate matching input sequence to obtain an output bit sequence e of length E according to an ordered rate matching index set R=<R(0), R(1), . . . , R(E−2), R(E−1)> of length E as eᵢ=d_{R(i)} for i=0, 1, 2, . . . , E−2, E−1. The i-th bit e; in the output bit sequence e is set to the R(i)-th bit d_{R(i)} in the polar transform output bit sequence d. For i=0, 1, 2, . . . , E−2, E−1, R(i) in the ordered rate matching index set R is determined according to an interleaver pattern J=[J₀, J₁, . . . , J_{N-2}, J_{N-1}] of length N. The interleaver pattern J being a permutation of the integer sequence [0, 1, 2, . . . , N−2, N−1] is determined by a sub-block interleaver pattern π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] as follows.

```
For i = 0 to N−1
  j = floor(32i/N);
  Jᵢ = πⱼ×(N/32) + mod(i, N/32);
End for
```

After the rate matching, the first node modulates the output bit sequence e into a first output symbol sequence x=[x₀, x₁, . . . , X_{E/Qm-1}] using the quadrature phase shift keying (QPSK) modulation and transmits a signal including the first output symbol sequence x to a second node, wherein, Qₘ=2 is the modulation order of QPSK.

Example settings for the precoding input index set P_{I}, the precoding output index set Po and the ordered rate matching index set R in the above process are as follows,
Example Setting 8-1: R=<R(0), R(1), . . . , R(E−2), R(E−1)>=<J₀, J₁, . . . , J_{E-2}, J_{E-1}>, P_{I}={0, 1, 2, . . . , Qₘₐₓ−1, Qₘₐₓ}, P_{O}={0, 1, 2, . . . , Qₘₐₓ−1, Qₘₐₓ};
Example Setting 8-2: R=<R(0), R(1), . . . , R(E−2), R(E−1)>=<J₀, J₁, . . . , J_{E-2}, J_{E-1}>, P_{I}={0, 1, 2, . . . , Qₘₐₓ−1, Qₘₐₓ}, P_{O}={R(0), R(1), R(2), . . . , R(E−1)};
Example Setting 8-3: R=<R(0), R(1), . . . , R(E−2), R(E−1)>=<J₀, J₁, . . . , J_{E-2}, J_{E-1}>, P_{I}={R(0), R(1), R(2), . . . , R(E−1)}, P_{O}={0, 1, 2, . . . , Qₘₐₓ−1, Qₘₐₓ};
Example Setting 8-4: R=<R(0), R(1), . . . , R(E−2), R(E−1)>=<J₀, J₁, . . . , J_{E-2}, J_{E-1}>, P_{I}={R(0), R(1), R(2), . . . , R(E−1)}, P_{O}={R(0), R(1), . . . , R(E−2), R(E−1)};
Example Setting 8-5: R=<R(0), R(1), . . . , R(E−2), R(E−1)>=<J_{N-E}, J_{N-E}+1, . . . , J_{N-2}, J_{N-1}>, P_{I}={0, 1, 2, . . . , Qₘₐₓ−1, Qₘₐₓ}, P_{O}={0, 1, 2, . . . , Qₘₐₓ−1, Qₘₐₓ};
Example Setting 8-6: R=<R(0), R(1), . . . , R(E−2), R(E−1)>=<J_{N-E}, J_{N-E}+1, . . . , J_{N-2}, J_{N-1}>, P_{I}={0, 1, 2, . . . , Qₘₐₓ−1, Qₘₐₓ}, P_{O}={R(0), R(1), R(2), . . . , R(E−1)};
Example Setting 8-7: R=<R(0), R(1), . . . , R(E−2), R(E−1)>=<J_{N-E}, J_{N-E}+1, . . . , J_{N-2}, J_{N-1}>, P_{I}={R(0), R(1), R(2), . . . , R(E−1)}, P_{O}={0, 1, 2, . . . , Qₘₐₓ−1, Qₘₐₓ};
Example Setting 8-8: R=<R(0), R(1), . . . , R(E−2), R(E−1)>=<J_{N-E}, J_{N-E}+1, . . . , J_{N-2}, J_{N-1}>, P_{I}={R(0), R(1), R(2), . . . , R(E−1)}, P_{O}={R(0), R(1), . . . , R(E−2), R(E−1)}.

Here, {0, 1, 2, . . . , Qₘₐₓ−1, Qₘₐₓ} denotes a set comprising all elements being non-negative integers not greater than the value Qₘₐₓ and the value Qₘₐₓ is the maximum value in the data bit index set Q,

$${Q}_{max} = {max}_{k ∈ Q} k ;$$

R(0), R(1), . . . , R(E−2), R(E−1) are E distinct elements in the ordered rate matching index set R=<R(0), R(1), . . . , R(E−2), R(E−1)> of size E.

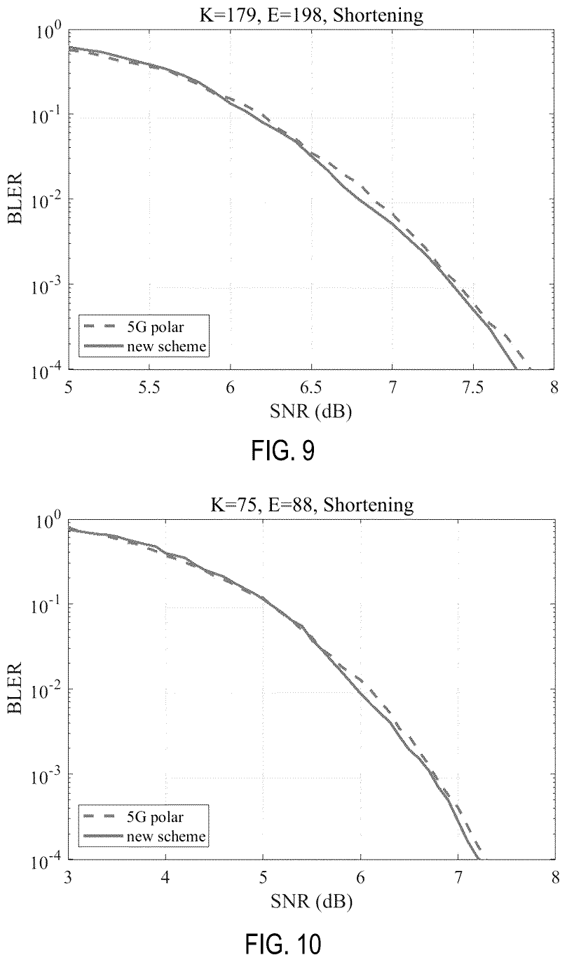

FIG. 9 illustrates example block error rate (BLER) curves for the Example Setting 8-1 with parameters in Table 10 as compared with the 5G polar code having the same input bit sequence length K and the same output bit sequence length E using QPSK modulation over additive white Gaussian noise (AWGN) channels. It can be shown that the disclosed new scheme (solid line) performs better than the 5G polar code (dashed line).

TABLE 10
Parameters for a first example of the disclosed polar coding scheme

| Parameters | Values |
|---|---|
| Input bit sequence length K | 179 |
| Number of CRC bits Lcrc | 19 |
| Cyclic generator polynomial g′(D) | g′(D) = D¹⁹ + D¹⁸ + D¹⁵ + D⁹ + D⁸ + D⁵ + D⁴ + D³ + D² + 1 |
| Output bit sequence E | 198 |
| Polar matrix size N | 256 |
| Data bit index set Q | Q = {7, 11, 13, 14, 15, 19, 20, 21, 22, 23, 24, 25, 26, 27, 28, |
| | 29, 30, 31, 34, 35, 36, 37, 38, 39, 40, 41, 42, 43, 44, 45, 46, |
| | 47, 48, 49, 50, 51, 52, 53, 54, 55, 56, 57, 58, 59, 60, 61, 62, |
| | 63, 66, 67, 68, 69, 70, 71, 72, 73, 74, 75, 76, 77, 78, 79, 80, |
| | 81, 82, 83, 84, 85, 86, 87, 88, 89, 90, 91, 92, 93, 94, 95, 96, |
| | 97, 98, 99, 100, 101, 102, 103, 104, 105, 106, 107, 108, 109, |
| | 110, 111, 112, 113, 114, 115, 116, 117, 118, 119, 120, 121, |
| | 122, 123, 124, 125, 126, 127, 129, 130, 131, 132, 133, 134, |
| | 135, 136, 137, 138, 139, 140, 141, 142, 143, 144, 145, 146, |
| | 147, 148, 149, 150, 151, 152, 153, 154, 155, 156, 157, 158, |
| | 159, 160, 161, 162, 163, 164, 165, 166, 167, 168, 169, 170, |
| | 171, 172, 173, 174, 175, 176, 177, 178, 179, 180, 181, 182, |
| | 183, 184, 185, 186, 187, 188, 189, 190, 191, 192, 193, 194, |
| | 195, 196, 197} |
| Memory length m | 6 |
| Generator polynomial g(D) | g(D) = 1 + D² + D³ + D⁵ + D⁶ (g = [1, 0, 1, 1, 0, 1, 1]) |
| (or equivalently generator | |
| bit sequence g) | |
| Maximum value Qₘₐₓ | 197 |
| in data bit index set Q | |
| Precoding input index set P_{I} | P_{I} = {0, 1, 2, . . . , Qₘₐₓ − 1, Qₘₐₓ} = {0, 1, 2, . . . , 196, 197} |
| Precoding output index set P_{O} | P_{O} = {0, 1, 2, . . . , Qₘₐₓ − 1, Qₘₐₓ} = {0, 1, 2, . . . , 196, 197} |
| Ordered rate matching index set R | R = <R(0), R(1), . . . , R(E − 2), R(E − 1)> = <0, 1, 2, 3, 4, 5, 6, 7, |
| | 8, 9, 10, 11, 12, 13, 14, 15, 16, 17, 18, 19, 20, 21, 22, 23, 32, |
| | 33, 34, 35, 36, 37, 38, 39, 24, 25, 26, 27, 28, 29, 30, 31, 40, |
| | 41, 42, 43, 44, 45, 46, 47, 48, 49, 50, 51, 52, 53, 54, 55, 56, |
| | 57, 58, 59, 60, 61, 62, 63, 64, 65, 66, 67, 68, 69, 70, 71, 128, |
| | 129, 130, 131, 132, 133, 134, 135, 72, 73, 74, 75, 76, 77, 78, |
| | 79, 136, 137, 138, 139, 140, 141, 142, 143, 80, 81, 82, 83, |
| | 84, 85, 86, 87, 144, 145, 146, 147, 148, 149, 150, 151, 88, |
| | 89, 90, 91, 92, 93, 94, 95, 152, 153, 154, 155, 156, 157, 158, |
| | 159, 96, 97, 98, 99, 100, 101, 102, 103, 160, 161, 162, 163, |
| | 164, 165, 166, 167, 104, 105, 106, 107, 108, 109, 110, 111, |
| | 168, 169, 170, 171, 172, 173, 174, 175, 112, 113, 114, 115, |
| | 116, 117, 118, 119, 176, 177, 178, 179, 180, 181, 182, 183, |
| | 120, 121, 122, 123, 124, 125, 126, 127, 184, 185, 186, 187, |
| | 188, 189, 190, 191, 192, 193, 194, 195, 196, 197> |

FIG. 10 illustrates example BLER curves for the Example Setting 8-2 with parameters in Table 11 as compared to the 5G polar code having the same input bit sequence length K and the same output bit sequence length E using QPSK modulation over AWGN channels. It can be shown that the disclosed new scheme (solid line) performs better than the 5G polar code (dashed line).

TABLE 11
Example parameters for a second example of the disclosed polar coding scheme

| Parameters | Values |
|---|---|
| Input bit sequence length K | 75 |
| Number of CRC bits Lcrc | 19 |
| Cyclic generator polynomial g′(D) | g′(D) = D¹⁹ + D¹⁸ + D¹⁵ + D⁹ + D⁸ + D⁵ + D⁴ + D³ + D² + 1 |
| Output bit sequence E | 88 |
| Polar matrix size N | 128 |
| Data bit index set Q | Q = {7, 10, 11, 12, 13, 14, 15, 18, 19, 20, 21, 22, 23, 24, 25, |
| | 26, 27, 28, 29, 30, 31, 33, 34, 35, 36, 37, 38, 39, 40, 41, 42, 43, |
| | 44, 45, 46, 47, 48, 49, 50, 51, 52, 53, 54, 55, 56, 57, 58, 59, 65, |
| | 66, 67, 68, 69, 70, 71, 72, 73, 74, 75, 76, 77, 78, 79, 80, 81, 82, |
| | 83, 84, 85, 86, 87, 88, 89, 90, 91} |
| Memory length m | 6 |
| Generator polynomial g(D) | g(D) = 1 + D² + D³ + D⁵ + D⁶ (g = [1, 0, 1, 1, 0, 1, 1]) |
| (or equivalently generator | |
| bit sequence g) | |
| Maximum value Qₘₐₓ in data | 91 |
| bit index set Q | |
| Precoding input index set P_{I} | P_{I} = {0, 1, 2, . . . , Qₘₐₓ − 1, Qₘₐₓ} = {0, 1, 2, . . . , 90, 91} |
| Precoding output index set P_{O} | P_{O} = {R(0), R(1), . . . , R(E − 2), R(E − 1)} = {0, 1, 2, 3, 4, 5, 6, 7, 8, |
| | 9, 10, 11, 16, 17, 18, 19, 12, 13, 14, 15, 20, 21, 22, 23, 24, 25, |
| | 26, 27, 28, 29, 30, 31, 32, 33, 34, 35, 64, 65, 66, 67, 36, 37, 38, |
| | 39, 68, 69, 70, 71, 40, 41, 42, 43, 72, 73, 74, 75, 44, 45, 46, 47, |
| | 76, 77, 78, 79, 48, 49, 50, 51, 80, 81, 82, 83, 52, 53, 54, 55, 84, |
| | 85, 86, 87, 56, 57, 58, 59, 88, 89, 90, 91} |
| Ordered rate matching index set R | R = <R(0), R(1), . . . , R(E − 2), R(E − 1)> = <0, 1, 2, 3, 4, 5, 6, 7, 8, |
| | 9, 10, 11, 16, 17, 18, 19, 12, 13, 14, 15, 20, 21, 22, 23, 24, 25, |
| | 26, 27, 28, 29, 30, 31, 32, 33, 34, 35, 64, 65, 66, 67, 36, 37, 38, |
| | 39, 68, 69, 70, 71, 40, 41, 42, 43, 72, 73, 74, 75, 44, 45, 46, 47, |
| | 76, 77, 78, 79, 48, 49, 50, 51, 80, 81, 82, 83, 52, 53, 54, 55, 84, |
| | 85, 86, 87, 56, 57, 58, 59, 88, 89, 90, 91> |

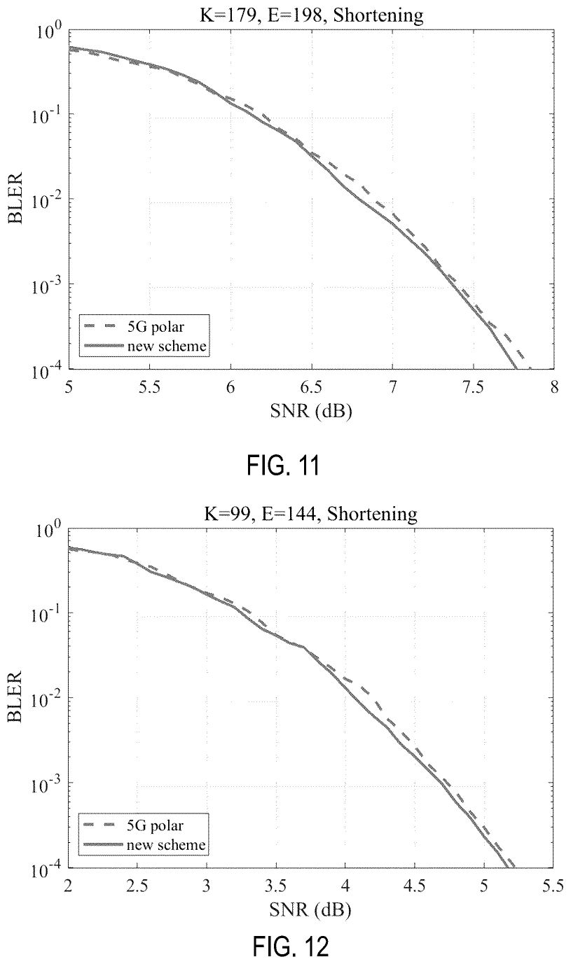

FIG. 11 illustrates example BLER curves for the Example Setting 8-3 with parameters in Table 12 as compared to the 5G polar code having the same input bit sequence length K and the same output bit sequence length E using QPSK modulation over AWGN channels. It can be shown that the disclosed new scheme (solid line) performs better than the 5G polar code (dashed line).

TABLE 12
Example parameters for a third specific example of disclosed new polar coding scheme

| Parameters | Values |
|---|---|
| Input bit sequence length K | 179 |
| number of CRC bits Lcrc | 19 |
| cyclic generator polynomial g′(D) | g′(D) = D¹⁹ + D¹⁸ + D¹⁵ + D⁹ + D⁸ + D⁵ + D⁴ + D³ + D² + 1 |
| output bit sequence E | 198 |
| polar matrix size N | 256 |
| data bit index set Q | Q = {7, 11, 13, 14, 15, 19, 20, 21, 22, 23, 24, 25, 26, 27, 28, |
| | 29, 30, 31, 34, 35, 36, 37, 38, 39, 40, 41, 42, 43, 44, 45, 46, |
| | 47, 48, 49, 50, 51, 52, 53, 54, 55, 56, 57, 58, 59, 60, 61, 62, |
| | 63, 66, 67, 68, 69, 70, 71, 72, 73, 74, 75, 76, 77, 78, 79, 80, |
| | 81, 82, 83, 84, 85, 86, 87, 88, 89, 90, 91, 92, 93, 94, 95, 96, |
| | 97, 98, 99, 100, 101, 102, 103, 104, 105, 106, 107, 108, 109, |
| | 110, 111, 112, 113, 114, 115, 116, 117, 118, 119, 120, 121, |
| | 122, 123, 124, 125, 126, 127, 129, 130, 131, 132, 133, 134, |
| | 135, 136, 137, 138, 139, 140, 141, 142, 143, 144, 145, 146, |
| | 147, 148, 149, 150, 151, 152, 153, 154, 155, 156, 157, 158, |
| | 159, 160, 161, 162, 163, 164, 165, 166, 167, 168, 169, 170, |
| | 171, 172, 173, 174, 175, 176, 177, 178, 179, 180, 181, 182, |
| | 183, 184, 185, 186, 187, 188, 189, 190, 191, 192, 193, 194, |
| | 195, 196, 197} |
| memory length m | 6 |
| generator polynomial g(D) | g(D) = 1 + D² + D³ + D⁵ + D⁶ (g = [1, 0, 1, 1, 0, 1, 1]) |
| (or equivalently generator | |
| bit sequence g) | |
| maximum value Qₘₐₓ in data | 197 |
| bit index set Q | |
| precoding input index set P_{I} | P_{I} = {R(0), R(1), R(2), . . . , R(E − 1)} = {0, 1, 2, 3, 4, 5, 6, 7, 8, |
| | 9, 10, 11, 12, 13, 14, 15, 16, 17, 18, 19, 20, 21, 22, 23, 32, |
| | 33, 34, 35, 36, 37, 38, 39, 24, 25, 26, 27, 28, 29, 30, 31, 40, |
| | 41, 42, 43, 44, 45, 46, 47, 48, 49, 50, 51, 52, 53, 54, 55, 56, |
| | 57, 58, 59, 60, 61, 62, 63, 64, 65, 66, 67, 68, 69, 70, 71, 128, |
| | 129, 130, 131, 132, 133, 134, 135, 72, 73, 74, 75, 76, 77, 78, |
| | 79, 136, 137, 138, 139, 140, 141, 142, 143, 80, 81, 82, 83, |
| | 84, 85, 86, 87, 144, 145, 146, 147, 148, 149, 150, 151, 88, |
| | 89, 90, 91, 92, 93, 94, 95, 152, 153, 154, 155, 156, 157, 158, |
| | 159, 96, 97, 98, 99, 100, 101, 102, 103, 160, 161, 162, 163, |
| | 164, 165, 166, 167, 104, 105, 106, 107, 108, 109, 110, 111, |
| | 168, 169, 170, 171, 172, 173, 174, 175, 112, 113, 114, 115, |
| | 116, 117, 118, 119, 176, 177, 178, 179, 180, 181, 182, 183, |
| | 120, 121, 122, 123, 124, 125, 126, 127, 184, 185, 186, 187, |
| | 188, 189, 190, 191, 192, 193, 194, 195, 196, 197} |
| precoding output index set P_{O} | P_{O} = {0, 1, 2, . . . , Qₘₐₓ − 1, Qₘₐₓ} = {0, 1, 2, . . . , 196, 197} |
| ordered rate matching index set R | R = <R(0), R(1), R(2), . . . , R(E − 1)> = <0, 1, 2, 3, 4, 5, 6, 7, 8, |
| | 9, 10, 11, 12, 13, 14, 15, 16, 17, 18, 19, 20, 21, 22, 23, 32, |
| | 33, 34, 35, 36, 37, 38, 39, 24, 25, 26, 27, 28, 29, 30, 31, 40, |
| | 41, 42, 43, 44, 45, 46, 47, 48, 49, 50, 51, 52, 53, 54, 55, 56, |
| | 57, 58, 59, 60, 61, 62, 63, 64, 65, 66, 67, 68, 69, 70, 71, 128, |
| | 129, 130, 131, 132, 133, 134, 135, 72, 73, 74, 75, 76, 77, 78, |
| | 79, 136, 137, 138, 139, 140, 141, 142, 143, 80, 81, 82, 83, |
| | 84, 85, 86, 87, 144, 145, 146, 147, 148, 149, 150, 151, 88, |
| | 89, 90, 91, 92, 93, 94, 95, 152, 153, 154, 155, 156, 157, 158, |
| | 159, 96, 97, 98, 99, 100, 101, 102, 103, 160, 161, 162, 163, |
| | 164, 165, 166, 167, 104, 105, 106, 107, 108, 109, 110, 111, |
| | 168, 169, 170, 171, 172, 173, 174, 175, 112, 113, 114, 115, |
| | 116, 117, 118, 119, 176, 177, 178, 179, 180, 181, 182, 183, |
| | 120, 121, 122, 123, 124, 125, 126, 127, 184, 185, 186, 187, |
| | 188, 189, 190, 191, 192, 193, 194, 195, 196, 197> |

FIG. 12 illustrates example BLER curves for the Example Setting 8-4 with parameters in Table 13 as compared to the 5G polar code having the same input bit sequence length K and the same output bit sequence length E using QPSK modulation over AWGN channels. It can be shown that the disclosed new scheme (solid line) performs better than the 5G polar code (dashed line).

TABLE 13
Example parameters for a fourth example of the disclosed new polar coding scheme

| Parameters | Values |
|---|---|
| input bit sequence length K | 99 |
| number of CRC bits Lcrc | 19 |
| cyclic generator polynomial g′(D) | g′(D) = D¹⁹ + D¹⁸ + D¹⁵ + D⁹ + D⁸ + D⁵ + D⁴ + D³ + D² + 1 |
| output bit sequence E | 144 |
| polar matrix size N | 256 |
| data bit index set Q | Q = {15, 23, 27, 28, 29, 30, 31, 39, 41, 42, 43, 44, 45, 46, 47, |
| | 49, 50, 51, 52, 53, 54, 55, 56, 57, 58, 59, 60, 61, 62, 63, 67, |
| | 69, 70, 71, 73, 74, 75, 76, 77, 78, 79, 81, 82, 83, 84, 85, 86, |
| | 87, 88, 89, 90, 91, 92, 93, 94, 95, 96, 97, 98, 99, 100, 101, |
| | 102, 103, 131, 133, 134, 135, 137, 138, 139, 140, 141, 142, |
| | 143, 144, 145, 146, 147, 148, 149, 150, 151, 152, 153, 154, |
| | 155, 156, 157, 158, 159, 160, 161, 162, 163, 164, 165, 166, 167} |
| memory length m | 6 |
| generator polynomial g(D) | g(D) = 1 + D² + D³ + D⁵ + D⁶ (g = [1, 0, 1, 1, 0, 1, 1]) |
| (or equivalently generator | |
| bit sequence g) | |
| maximum value Qₘₐₓ in data | 167 |
| bit index set Q | |
| precoding input index set P_{I} | P_{I} = {R(0), R(1), R(2), . . . , R(E − 1)} = {0, 1, 2, 3, 4, 5, 6, 7, 8, |
| | 9, 10, 11, 12, 13, 14, 15, 16, 17, 18, 19, 20, 21, 22, 23, 32, |
| | 33, 34, 35, 36, 37, 38, 39, 24, 25, 26, 27, 28, 29, 30, 31, 40, |
| | 41, 42, 43, 44, 45, 46, 47, 48, 49, 50, 51, 52, 53, 54, 55, 56, |
| | 57, 58, 59, 60, 61, 62, 63, 64, 65, 66, 67, 68, 69, 70, 71, 128, |
| | 129, 130, 131, 132, 133, 134, 135, 72, 73, 74, 75, 76, 77, 78, |
| | 79, 136, 137, 138, 139, 140, 141, 142, 143, 80, 81, 82, 83, |
| | 84, 85, 86, 87, 144, 145, 146, 147, 148, 149, 150, 151, 88, |
| | 89, 90, 91, 92, 93, 94, 95, 152, 153, 154, 155, 156, 157, 158, |
| | 159, 96, 97, 98, 99, 100, 101, 102, 103, 160, 161, 162, 163, |
| | 164, 165, 166, 167} |
| precoding output index set P_{O} | P_{O} = {R(0), R(1), R(2), . . . , R(E − 1)} = {0, 1, 2, 3, 4, 5, 6, 7, 8, |
| | 9, 10, 11, 12, 13, 14, 15, 16, 17, 18, 19, 20, 21, 22, 23, 32, |
| | 33, 34, 35, 36, 37, 38, 39, 24, 25, 26, 27, 28, 29, 30, 31, 40, |
| | 41, 42, 43, 44, 45, 46, 47, 48, 49, 50, 51, 52, 53, 54, 55, 56, |
| | 57, 58, 59, 60, 61, 62, 63, 64, 65, 66, 67, 68, 69, 70, 71, 128, |
| | 129, 130, 131, 132, 133, 134, 135, 72, 73, 74, 75, 76, 77, 78, |
| | 79, 136, 137, 138, 139, 140, 141, 142, 143, 80, 81, 82, 83, |
| | 84, 85, 86, 87, 144, 145, 146, 147, 148, 149, 150, 151, 88, |
| | 89, 90, 91, 92, 93, 94, 95, 152, 153, 154, 155, 156, 157, 158, |
| | 159, 96, 97, 98, 99, 100, 101, 102, 103, 160, 161, 162, 163, |
| | 164, 165, 166, 167} |
| ordered rate matching index set R | R = <R(0), R(1), R(2), . . . , R(E − 1)> = <0, 1, 2, 3, 4, 5, 6, 7, 8, |
| | 9, 10, 11, 12, 13, 14, 15, 16, 17, 18, 19, 20, 21, 22, 23, 32, |
| | 33, 34, 35, 36, 37, 38, 39, 24, 25, 26, 27, 28, 29, 30, 31, 40, |
| | 41, 42, 43, 44, 45, 46, 47, 48, 49, 50, 51, 52, 53, 54, 55, 56, |
| | 57, 58, 59, 60, 61, 62, 63, 64, 65, 66, 67, 68, 69, 70, 71, 128, |
| | 129, 130, 131, 132, 133, 134, 135, 72, 73, 74, 75, 76, 77, 78, |
| | 79, 136, 137, 138, 139, 140, 141, 142, 143, 80, 81, 82, 83, |
| | 84, 85, 86, 87, 144, 145, 146, 147, 148, 149, 150, 151, 88, |
| | 89, 90, 91, 92, 93, 94, 95, 152, 153, 154, 155, 156, 157, 158, |
| | 159, 96, 97, 98, 99, 100, 101, 102, 103, 160, 161, 162, 163, |
| | 164, 165, 166, 167> |

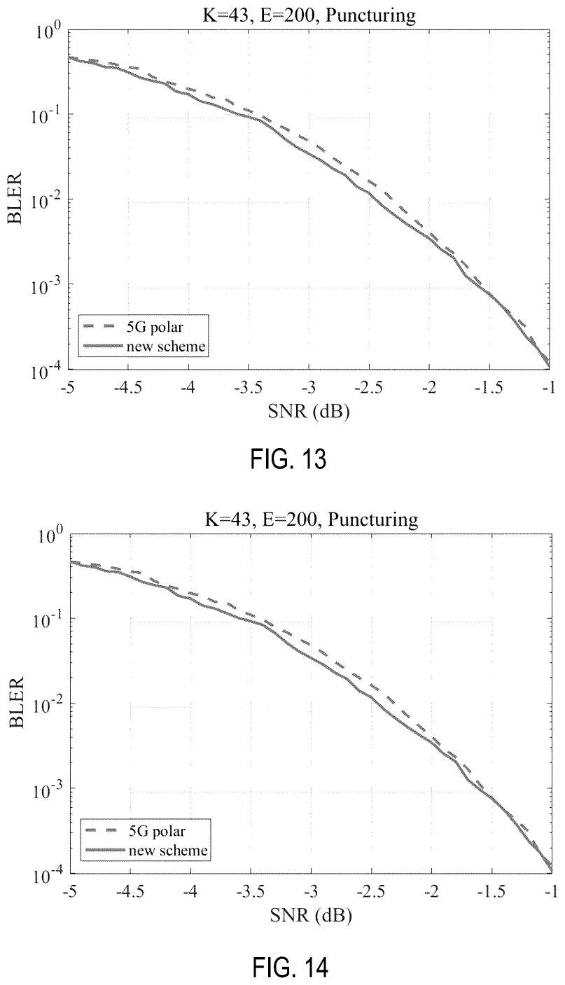

FIG. 13 illustrates example BLER curves for the Example Setting 8-5 with parameters in Table 14 as compared to the 5G polar code having the same input bit sequence length K and the same output bit sequence length E using QPSK modulation over AWGN channels. It can be shown that the disclosed new scheme (solid line) performs better than the 5G polar code (dashed line).

TABLE 14
Example parameters for a fifth example of the disclosed new polar coding scheme

| Parameters | Values |
|---|---|
| input bit sequence length K | 43 |
| number of CRC bits Lcrc | 19 |
| cyclic generator polynomial g′(D) | g′(D) = D¹⁹ + D¹⁸ + D¹⁵ + D⁹ + D⁸ + D⁵ + D⁴ + D³ + D² + 1 |
| output bit sequence E | 200 |
| polar matrix size N | 256 |
| data bit index set Q | Q = {119, 123, 125, 126, 127, 175, 183, 187, 189, 190, 191, |
| | 207, 215, 218, 219, 220, 221, 222, 223, 230, 231, 233, 234, |
| | 235, 236, 237, 238, 239, 241, 242, 243, 244, 245, 246, 247, |
| | 248, 249, 250, 251, 252, 253, 254, 255} |
| memory length m | 6 |
| generator polynomial g(D) | g(D) = 1 + D² + D³ + D⁵ + D⁶ (g = [1, 0, 1, 1, 0, 1, 1]) |
| (or equivalently generator | |
| bit sequence g) | |
| maximum value Qₘₐₓ in data | 255 |
| bit index set Q | |
| precoding input index set P_{I} | P_{I} = {0, 1, . . . , Qₘₐₓ} = {0, 1, 2, . . . , 254, 255} |
| precoding output index set P_{O} | P_{O} = {0, 1, . . . , Qₘₐₓ} = {0, 1, 2, . . . , 254, 255} |
| ordered rate matching index set R | R = <R(0), R(1), R(2), . . . , R(E − 1)> = <56, 57, 58, 59, 60, 61, |
| | 62, 63, 64, 65, 66, 67, 68, 69, 70, 71, 128, 129, 130, 131, |
| | 132, 133, 134, 135, 72, 73, 74, 75, 76, 77, 78, 79, 136, 137, |
| | 138, 139, 140, 141, 142, 143, 80, 81, 82, 83, 84, 85, 86, 87, |
| | 144, 145, 146, 147, 148, 149, 150, 151, 88, 89, 90, 91, 92, |
| | 93, 94, 95, 152, 153, 154, 155, 156, 157, 158, 159, 96, 97, |
| | 98, 99, 100, 101, 102, 103, 160, 161, 162, 163, 164, 165, |
| | 166, 167, 104, 105, 106, 107, 108, 109, 110, 111, 168, 169, |
| | 170, 171, 172, 173, 174, 175, 112, 113, 114, 115, 116, 117, |
| | 118, 119, 176, 177, 178, 179, 180, 181, 182, 183, 120, 121, |
| | 122, 123, 124, 125, 126, 127, 184, 185, 186, 187, 188, 189, |
| | 190, 191, 192, 193, 194, 195, 196, 197, 198, 199, 200, 201, |
| | 202, 203, 204, 205, 206, 207, 208, 209, 210, 211, 212, 213, |
| | 214, 215, 224, 225, 226, 227, 228, 229, 230, 231, 216, 217, |
| | 218, 219, 220, 221, 222, 223, 232, 233, 234, 235, 236, 237, |
| | 238, 239, 240, 241, 242, 243, 244, 245, 246, 247, 248, 249, |
| | 250, 251, 252, 253, 254, 255> |

FIG. 14 gives specific example BLER curves for the Example Setting 8-6 with parameters in Table 15 as compared with the 5G polar code with the same input bit sequence length K and the same output bit sequence length E using QPSK modulation over AWGN channels. It can be shown that the disclosed new scheme (solid line) performs better than the 5G polar code (dashed line).

TABLE 15
Example parameters for a sixth example of the new polar coding scheme

| Parameters | Values |
|---|---|
| input bit sequence length K | 43 |
| number of CRC bits Lcrc | 19 |
| cyclic generator polynomial g′(D) | g′(D) = D¹⁹ + D¹⁸ + D¹⁵ + D⁹ + D⁸ + D⁵ + D⁴ + D³ + D² + 1 |
| output bit sequence E | 200 |
| polar matrix size N | 256 |
| data bit index set Q | Q = {119, 123, 125, 126, 127, 175, 183, 187, 189, 190, 191, |
| | 207, 215, 218, 219, 220, 221, 222, 223, 230, 231, 233, 234, |
| | 235, 236, 237, 238, 239, 241, 242, 243, 244, 245, 246, 247, |
| | 248, 249, 250, 251, 252, 253, 254, 255} |
| memory length m | 6 |
| generator polynomial g(D) | g(D) = 1 + D² + D³ + D⁵ + D⁶ (g = [1, 0, 1, 1, 0, 1, 1]) |
| (or equivalently generator | |
| bit sequence g) | |
| maximum value Qₘₐₓ in data | 255 |
| bit index set Q | |
| precoding input index set P_{I} | P_{I} = {0, 1, . . . , Qₘₐₓ} = {0, 1, 2, . . . , 254, 255} |
| precoding output index set P_{O} | P_{O} = {R(0), R(1), R(2), . . . , R(E − 1)} = {56, 57, 58, 59, 60, 61, |
| | 62, 63, 64, 65, 66, 67, 68, 69, 70, 71, 128, 129, 130, 131, |
| | 132, 133, 134, 135, 72, 73, 74, 75, 76, 77, 78, 79, 136, 137, |
| | 138, 139, 140, 141, 142, 143, 80, 81, 82, 83, 84, 85, 86, 87, |
| | 144, 145, 146, 147, 148, 149, 150, 151, 88, 89, 90, 91, 92, |
| | 93, 94, 95, 152, 153, 154, 155, 156, 157, 158, 159, 96, 97, |
| | 98, 99, 100, 101, 102, 103, 160, 161, 162, 163, 164, 165, |
| | 166, 167, 104, 105, 106, 107, 108, 109, 110, 111, 168, 169, |
| | 170, 171, 172, 173, 174, 175, 112, 113, 114, 115, 116, 117, |
| | 118, 119, 176, 177, 178, 179, 180, 181, 182, 183, 120, 121, |
| | 122, 123, 124, 125, 126, 127, 184, 185, 186, 187, 188, 189, |
| | 190, 191, 192, 193, 194, 195, 196, 197, 198, 199, 200, 201, |
| | 202, 203, 204, 205, 206, 207, 208, 209, 210, 211, 212, 213, |
| | 214, 215, 224, 225, 226, 227, 228, 229, 230, 231, 216, 217, |
| | 218, 219, 220, 221, 222, 223, 232, 233, 234, 235, 236, 237, |
| | 238, 239, 240, 241, 242, 243, 244, 245, 246, 247, 248, 249, |
| | 250, 251, 252, 253, 254, 255} |
| ordered rate matching index set R | R = <R(0), R(1), R(2), . . . , R(E − 1)> = <56, 57, 58, 59, 60, 61, |
| | 62, 63, 64, 65, 66, 67, 68, 69, 70, 71, 128, 129, 130, 131, |
| | 132, 133, 134, 135, 72, 73, 74, 75, 76, 77, 78, 79, 136, 137, |
| | 138, 139, 140, 141, 142, 143, 80, 81, 82, 83, 84, 85, 86, 87, |
| | 144, 145, 146, 147, 148, 149, 150, 151, 88, 89, 90, 91, 92, |
| | 93, 94, 95, 152, 153, 154, 155, 156, 157, 158, 159, 96, 97, |
| | 98, 99, 100, 101, 102, 103, 160, 161, 162, 163, 164, 165, |
| | 166, 167, 104, 105, 106, 107, 108, 109, 110, 111, 168, 169, |
| | 170, 171, 172, 173, 174, 175, 112, 113, 114, 115, 116, 117, |
| | 118, 119, 176, 177, 178, 179, 180, 181, 182, 183, 120, 121, |
| | 122, 123, 124, 125, 126, 127, 184, 185, 186, 187, 188, 189, |
| | 190, 191, 192, 193, 194, 195, 196, 197, 198, 199, 200, 201, |
| | 202, 203, 204, 205, 206, 207, 208, 209, 210, 211, 212, 213, |
| | 214, 215, 224, 225, 226, 227, 228, 229, 230, 231, 216, 217, |
| | 218, 219, 220, 221, 222, 223, 232, 233, 234, 235, 236, 237, |
| | 238, 239, 240, 241, 242, 243, 244, 245, 246, 247, 248, 249, |
| | 250, 251, 252, 253, 254, 255> |

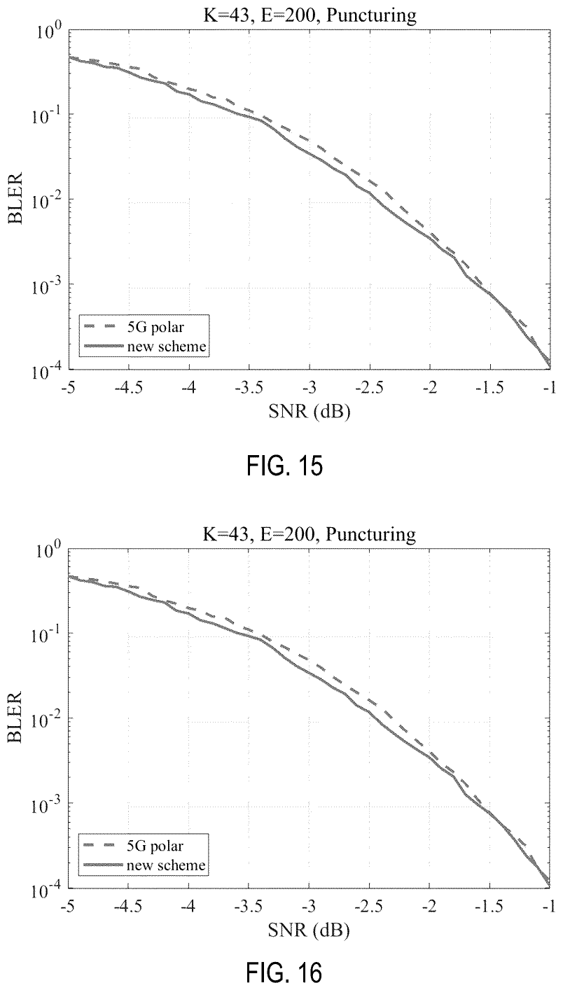

FIG. 15 illustrates example BLER curves for the Example Setting 8-7 with parameters in Table 16 as compared to the 5G polar code having the same input bit sequence length K and the same output bit sequence length E using QPSK modulation over AWGN channels. It can be shown that the disclosed new scheme (solid line) performs better than the 5G polar code (dashed line).

TABLE 16
parameters for a seventh example of the disclosed polar coding scheme

| Parameters | Values |
|---|---|
| input bit sequence length K | 43 |
| number of CRC bits Lcrc | 19 |
| cyclic generator polynomial g′(D) | g′(D) = D¹⁹ + D¹⁸ + D¹⁵ + D⁹ + D⁸ + D⁵ + D⁴ + D³ + D² + 1 |
| output bit sequence E | 200 |
| polar matrix size N | 256 |
| data bit index set Q | Q = {119, 123, 125, 126, 127, 175, 183, 187, 189, 190, 191, |
| | 207, 215, 218, 219, 220, 221, 222, 223, 230, 231, 233, 234, |
| | 235, 236, 237, 238, 239, 241, 242, 243, 244, 245, 246, 247, |
| | 248, 249, 250, 251, 252, 253, 254, 255} |
| memory length m | 6 |
| generator polynomial g(D) | g(D) = 1 + D² + D³ + D⁵ + D⁶ (g = [1, 0, 1, 1, 0, 1, 1]) |
| (or equivalently generator | |
| bit sequence g) | |
| maximum value Qₘₐₓ in data | 255 |
| bit index set Q | |
| precoding input index set P_{I} | P_{I} = {R(0), R(1), R(2), . . . , R(E − 1)} = {56, 57, 58, 59, 60, 61, |
| | 62, 63, 64, 65, 66, 67, 68, 69, 70, 71, 128, 129, 130, 131, |
| | 132, 133, 134, 135, 72, 73, 74, 75, 76, 77, 78, 79, 136, 137, |
| | 138, 139, 140, 141, 142, 143, 80, 81, 82, 83, 84, 85, 86, 87, |
| | 144, 145, 146, 147, 148, 149, 150, 151, 88, 89, 90, 91, 92, |
| | 93, 94, 95, 152, 153, 154, 155, 156, 157, 158, 159, 96, 97, |
| | 98, 99, 100, 101, 102, 103, 160, 161, 162, 163, 164, 165, |
| | 166, 167, 104, 105, 106, 107, 108, 109, 110, 111, 168, 169, |
| | 170, 171, 172, 173, 174, 175, 112, 113, 114, 115, 116, 117, |
| | 118, 119, 176, 177, 178, 179, 180, 181, 182, 183, 120, 121, |
| | 122, 123, 124, 125, 126, 127, 184, 185, 186, 187, 188, 189, |
| | 190, 191, 192, 193, 194, 195, 196, 197, 198, 199, 200, 201, |
| | 202, 203, 204, 205, 206, 207, 208, 209, 210, 211, 212, 213, |
| | 214, 215, 224, 225, 226, 227, 228, 229, 230, 231, 216, 217, |
| | 218, 219, 220, 221, 222, 223, 232, 233, 234, 235, 236, 237, |
| | 238, 239, 240, 241, 242, 243, 244, 245, 246, 247, 248, 249, |
| | 250, 251, 252, 253, 254, 255} |
| precoding output index set P_{O} | P_{O} = {0, 1, . . . , Qₘₐₓ} = {0, 1, 2, . . . , 254, 255} |
| ordered rate matching index set R | R = <R(0), R(1), R(2), . . . , R(E − 1)> = <56, 57, 58, 59, 60, 61, |
| | 62, 63, 64, 65, 66, 67, 68, 69, 70, 71, 128, 129, 130, 131, |
| | 132, 133, 134, 135, 72, 73, 74, 75, 76, 77, 78, 79, 136, 137, |
| | 138, 139, 140, 141, 142, 143, 80, 81, 82, 83, 84, 85, 86, 87, |
| | 144, 145, 146, 147, 148, 149, 150, 151, 88, 89, 90, 91, 92, |
| | 93, 94, 95, 152, 153, 154, 155, 156, 157, 158, 159, 96, 97, |
| | 98, 99, 100, 101, 102, 103, 160, 161, 162, 163, 164, 165, |
| | 166, 167, 104, 105, 106, 107, 108, 109, 110, 111, 168, 169, |
| | 170, 171, 172, 173, 174, 175, 112, 113, 114, 115, 116, 117, |
| | 118, 119, 176, 177, 178, 179, 180, 181, 182, 183, 120, 121, |
| | 122, 123, 124, 125, 126, 127, 184, 185, 186, 187, 188, 189, |
| | 190, 191, 192, 193, 194, 195, 196, 197, 198, 199, 200, 201, |
| | 202, 203, 204, 205, 206, 207, 208, 209, 210, 211, 212, 213, |
| | 214, 215, 224, 225, 226, 227, 228, 229, 230, 231, 216, 217, |
| | 218, 219, 220, 221, 222, 223, 232, 233, 234, 235, 236, 237, |
| | 238, 239, 240, 241, 242, 243, 244, 245, 246, 247, 248, 249, |
| | 250, 251, 252, 253, 254, 255> |

FIG. 16 illustrates example BLER curves for the Example Setting 8-8 with parameters in Table 17 as compared to the 5G polar code having the same input bit sequence length K and the same output bit sequence length E using QPSK modulation over AWGN channels. It can be shown that the disclosed new scheme (solid line) performs better than the 5G polar code (dashed line).

TABLE 17
Example parameters for an eighth example of the disclosed polar coding scheme

| Parameters | Values |
|---|---|
| input bit sequence length K | 43 |
| number of CRC bits Lcrc | 19 |
| cyclic generator polynomial g′(D) | g′(D) = D¹⁹ + D¹⁸ + D¹⁵ + D⁹ + D⁸ + D⁵ + D⁴ + D³ + D² + 1 |
| output bit sequence E | 200 |
| polar matrix size N | 256 |
| data bit index set Q | Q = {119, 123, 125, 126, 127, 175, 183, 187, 189, 190, 191, |
| | 207, 215, 218, 219, 220, 221, 222, 223, 230, 231, 233, 234, |
| | 235, 236, 237, 238, 239, 241, 242, 243, 244, 245, 246, 247, |
| | 248, 249, 250, 251, 252, 253, 254, 255} |
| memory length m | 6 |
| generator polynomial g(D) | g(D) = 1 + D² + D³ + D⁵ + D⁶ (g = [1, 0, 1, 1, 0, 1, 1]) |
| (or equivalently generator | |
| bit sequence g) | |
| maximum value Qₘₐₓ in data | 255 |
| bit index set Q | |
| precoding input index set P_{I} | P_{I} = {R(0), R(1), R(2), . . . , R(E − 1)} = {56, 57, 58, 59, 60, 61, |
| | 62, 63, 64, 65, 66, 67, 68, 69, 70, 71, 128, 129, 130, 131, |
| | 132, 133, 134, 135, 72, 73, 74, 75, 76, 77, 78, 79, 136, 137, |
| | 138, 139, 140, 141, 142, 143, 80, 81, 82, 83, 84, 85, 86, 87, |
| | 144, 145, 146, 147, 148, 149, 150, 151, 88, 89, 90, 91, 92, |
| | 93, 94, 95, 152, 153, 154, 155, 156, 157, 158, 159, 96, 97, |
| | 98, 99, 100, 101, 102, 103, 160, 161, 162, 163, 164, 165, |
| | 166, 167, 104, 105, 106, 107, 108, 109, 110, 111, 168, 169, |
| | 170, 171, 172, 173, 174, 175, 112, 113, 114, 115, 116, 117, |
| | 118, 119, 176, 177, 178, 179, 180, 181, 182, 183, 120, 121, |
| | 122, 123, 124, 125, 126, 127, 184, 185, 186, 187, 188, 189, |
| | 190, 191, 192, 193, 194, 195, 196, 197, 198, 199, 200, 201, |
| | 202, 203, 204, 205, 206, 207, 208, 209, 210, 211, 212, 213, |
| | 214, 215, 224, 225, 226, 227, 228, 229, 230, 231, 216, 217, |
| | 218, 219, 220, 221, 222, 223, 232, 233, 234, 235, 236, 237, |
| | 238, 239, 240, 241, 242, 243, 244, 245, 246, 247, 248, 249, |
| | 250, 251, 252, 253, 254, 255} |
| precoding output index set P_{O} | P_{O} = {R(0), R(1), R(2), . . . , R(E − 1)} = {56, 57, 58, 59, 60, 61, |
| | 62, 63, 64, 65, 66, 67, 68, 69, 70, 71, 128, 129, 130, 131, |
| | 132, 133, 134, 135, 72, 73, 74, 75, 76, 77, 78, 79, 136, 137, |
| | 138, 139, 140, 141, 142, 143, 80, 81, 82, 83, 84, 85, 86, 87, |
| | 144, 145, 146, 147, 148, 149, 150, 151, 88, 89, 90, 91, 92, |
| | 93, 94, 95, 152, 153, 154, 155, 156, 157, 158, 159, 96, 97, |
| | 98, 99, 100, 101, 102, 103, 160, 161, 162, 163, 164, 165, |
| | 166, 167, 104, 105, 106, 107, 108, 109, 110, 111, 168, 169, |
| | 170, 171, 172, 173, 174, 175, 112, 113, 114, 115, 116, 117, |
| | 118, 119, 176, 177, 178, 179, 180, 181, 182, 183, 120, 121, |
| | 122, 123, 124, 125, 126, 127, 184, 185, 186, 187, 188, 189, |
| | 190, 191, 192, 193, 194, 195, 196, 197, 198, 199, 200, 201, |
| | 202, 203, 204, 205, 206, 207, 208, 209, 210, 211, 212, 213, |
| | 214, 215, 224, 225, 226, 227, 228, 229, 230, 231, 216, 217, |
| | 218, 219, 220, 221, 222, 223, 232, 233, 234, 235, 236, 237, |
| | 238, 239, 240, 241, 242, 243, 244, 245, 246, 247, 248, 249, |
| | 250, 251, 252, 253, 254, 255} |
| ordered rate matching index set R | R = <R(0), R(1), R(2), . . . , R(E − 1)> = <56, 57, 58, 59, 60, 61, |
| | 62, 63, 64, 65, 66, 67, 68, 69, 70, 71, 128, 129, 130, 131, |
| | 132, 133, 134, 135, 72, 73, 74, 75, 76, 77, 78, 79, 136, 137, |
| | 138, 139, 140, 141, 142, 143, 80, 81, 82, 83, 84, 85, 86, 87, |
| | 144, 145, 146, 147, 148, 149, 150, 151, 88, 89, 90, 91, 92, |
| | 93, 94, 95, 152, 153, 154, 155, 156, 157, 158, 159, 96, 97, |
| | 98, 99, 100, 101, 102, 103, 160, 161, 162, 163, 164, 165, |
| | 166, 167, 104, 105, 106, 107, 108, 109, 110, 111, 168, 169, |
| | 170, 171, 172, 173, 174, 175, 112, 113, 114, 115, 116, 117, |
| | 118, 119, 176, 177, 178, 179, 180, 181, 182, 183, 120, 121, |
| | 122, 123, 124, 125, 126, 127, 184, 185, 186, 187, 188, 189, |
| | 190, 191, 192, 193, 194, 195, 196, 197, 198, 199, 200, 201, |
| | 202, 203, 204, 205, 206, 207, 208, 209, 210, 211, 212, 213, |
| | 214, 215, 224, 225, 226, 227, 228, 229, 230, 231, 216, 217, |
| | 218, 219, 220, 221, 222, 223, 232, 233, 234, 235, 236, 237, |
| | 238, 239, 240, 241, 242, 243, 244, 245, 246, 247, 248, 249, |
| | 250, 251, 252, 253, 254, 255> |

It is noted that FIGS. 13-16 are the same due to the minimum value 119 in Q being larger than the minimum value 56 in R, which makes the convolutional output the same regardless of P_{I} being {0, 1, 2, . . . , Qₘₐₓ} or {R(0), R(1), R(2), . . . , R(E−1)} and/or P_{O} being {0, 1, 2, . . . , Qₘₐₓ} or {R(0), R(1), R(2), . . . , R(E−1)} in the setting with K=43 and E=200.

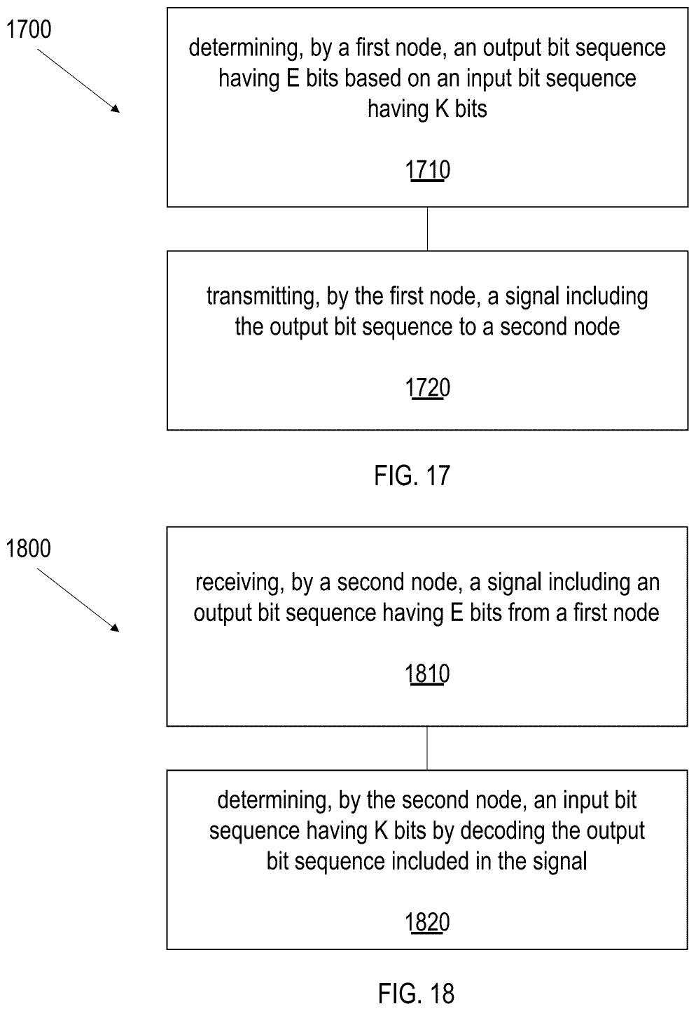

FIG. 17 is a flowchart representation of a method for digital communication in accordance with one or more embodiments of the present technology. The method 1700 includes, at operation 1710, determining, by a first node, an output bit sequence having E bits based on an input bit sequence having K bits. The output bit sequence is determined based on a transform that is applied prior to applying a Polar transform having a size of N. The transform (e.g., the pre-transform) is based on at least one index set that is a subset of a set of bit indices (e.g., P_{I} and/or Po). The set of bit indices comprises all non-negative integers that are less than N and wherein K<N and K<E. The method 1700 includes, at operation 1720, transmitting, by the first node, a signal including the output bit sequence to a second node.

FIG. 18 is a flowchart representation of a method for digital communication in accordance with one or more embodiments of the present technology. The method 1800 includes, at operation 1810, receiving, by a second node, a signal including an output bit sequence having E bits from a first node. The method 1800 includes, at operation 1820, determining, by the second node, an input bit sequence having K bits by decoding the output bit sequence included in the signal. The input bit sequence is determined based on a transform that is applied after applying an inverse Polar transform having a size of N. The transform (e.g., the pre-transform) is based on at least one index set that is a subset of a set of bit indices. The set of bit indices comprises all non-negative integers that are less than N and wherein K<N and K<E. In some embodiments, the at least one index set comprises an input index set and/or an output index set.

In some embodiments, the at least one index set comprises all non-negative integers that are equal to or smaller than Qₘₐₓ, where Qₘₐₓ is an element that has a largest value in a first index set (having K elements, Q being a subset of the set of bit indices that comprises all non-negative integers that are less than N. For example, Q is a data bit index set and

$${Q}_{max} = {max}_{k ∈ Q} k .$$

In some embodiments, the at least one index set is same as an ordered rate matching index set R=<R(0), R(1), . . . , R(Nᵣ−2), R(Nᵣ−1)>, where Nᵣ=min(E, N).

In some embodiments, the at least one index set comprises all non-negative integers that are equal to or smaller than Rₘₐₓ, wherein Rₘₐₓ is an element that has a largest value in an ordered rate matching index set R with

$${R}_{max} = {max}_{k ∈ R} k .$$

In some embodiments, the output bit sequence consists of bits in an output bit sequence of the Polar transform with indices being in an ordered rate matching index set R=<R(0), R(1), . . . , R(Nᵣ−2), R(Nᵣ−1)>. The output bit sequence of the Polar transform has a length N, and Nᵣ=min(E, N). For example, K=4, N=8, E=6, R=<R(0), R(1), R(2), R(3), R(4), R(5)>=<0, 1, 3, 4, 7, 5>, and a polar transform output bit sequence d=[d₀, d₁, d₂, d₃, d₄, d₅, d₆, d₇]. The output bit sequence e=[c₀, c₁, c₂, c₃, c₄, c₅]=[d_{R(0)}, d_{R(1)}, d_{R(2)}, d_{R(3)}, d_{R(4)}, d_{R(5)}]=[d₀, d₁, d₃, d₄, d₇, d₅].

In some embodiments, the output bit sequence is determined based on an intermediate bit sequence (e.g., the sequence u), and wherein an i-th bit of the intermediate bit sequence is set to a predetermined value in response to an index i not being in the at least one index set. The predetermined value comprises 0, a value in a state bit sequence, or a value in a frozen bit sequence.

In some embodiments, the output bit sequence is determined based on an intermediate bit sequence (e.g., the sequence u), and wherein an i-th bit of the intermediate bit sequence is set to an i-th bit of a rate profile output bit sequence in response to an index i not being in the at least one index set. The rate profile output bit sequence is of length N.

In some embodiments, an j-th bit of an intermediate bit sequence (e.g., sequence u) is determined by a convolution bit sequence or a convolution polynomial in response to an index j being in the at least one index set. In some embodiments, the convolution bit sequence comprises a generator bit sequence g=[g₀, g₁, . . . , gₘ], or a recursive feedback bit sequence q=[40, 41, . . . , qₘ]. In some embodiments, the convolution polynomial comprises a generator polynomial g(D)=g₀+g₁·D)+. . . +gₘ₋₁·Dₘ₋₁+gₘ·D^{m}, or a recursive feedback polynomial q(D)=q₀+q₁D+ . . . +qₘ₋₁·Dₘ₋₁+qₘ·D^{m}.

In some embodiments, a state bit sequence t=[t₀, t₁, . . . , tₘ₋₁, tₘ] configured to store a convolution state is shifted in response to an index i being in the at least one index set. In some embodiments, the input bit sequence is represented as c, wherein the output bit sequence is determined based on an intermediate bit sequence (e.g., sequence u), and wherein an i-th bit in the intermediate bit sequence is determined based on a linear combination of elements c₀, c₁, c₂, . . . , cᵢ₋₁, cᵢ in c.

In some embodiments, the output bit sequence is determined based on an intermediate bit sequence (e.g., sequence u), and wherein an i-th bit in the intermediate bit sequence is determined by a sub-sequence of the input bit sequence and a rate profile frozen bit sequence f=[f₀, f₁, . . . , f_{N-K-1}] that is a binary sequence of length N-K. In some embodiments, the output bit sequence is determined based on an intermediate bit sequence (e.g., sequence u). An i-th bit in the intermediate bit sequence is determined based on a linear combination of bits in a rate profile output bit sequence with indices being in the at least one index set (e.g., the intersection of the input index set and the bit index set) and not greater than i, where the rate profile output bit sequence is of length N. For example, if P_{I}={3, 4, 6, 7}, then 0-th bit in the intermediate bit sequence is determined by an empty set { }={0} n P_{I}, 1-st bit in the intermediate bit sequence is determined by an empty set { }={0, 1}∩P_{I}, 2-nd bit in the intermediate bit sequence is determined by an empty set { }={0, 1, 2}∩P_{I}, 3-rd bit in the intermediate bit sequence is determined by an set {3}={0, 1, 2, 3}∩P_{I}, 4-th bit in the intermediate bit sequence is determined by an set {3, 4}={0, 1, 2, 3, 4}∩P_{I}, 5-th bit in the intermediate bit sequence is determined by an set {3, 4}={0, 1, 2, 3, 4, 5}∩P_{I}, 6-th bit in the intermediate bit sequence is determined by an set {3, 4, 6}={0, 1, 2, 3, 4, 5, 6}∩P_{I}, 7-th bit in the intermediate bit sequence is determined by an set {3, 4, 6, 7}={0, 1, 2, 3, 4, 5, 6, 7}∩P_{I}.

In some embodiments, the input bit sequence is represented as c. The output bit sequence is determined based on an intermediate bit sequence (e.g., sequence u). An i-th bit in the intermediate bit sequence is determined based on a linear combination of elements c₀, c₁, c₂, . . . , c_{M-2}, C_{M-1} in c. M represents a number of elements that are shared by a first index set Q that is a subset of the set of bit indices and a second index set {0, 1, 2, . . . , i−1, i} that comprises all non-negative integers not greater than i. For example, for Q={3, 5, 7}, i=1, Q∩{0, 1, 2, . . . , i−1, i}={ } and M=0; for Q={3, 5, 7}, i=3, Q∩{0, 1, 2, . . . , i−1, i}={3} and M=1; for Q={3, 5, 7}, i=4, Q∩{0, 1, 2, . . . , i−1, i}={3} and M=1; for Q={3, 5, 7}, i=5, we have Q∩{0, 1, 2, . . . , i−1, i}={3, 5} and M=2, etc. The i-th bit in the intermediate bit sequence is based on a linear combination of elements v₀, vᵢ, v₂, . . . , vᵢ in v, where v having N bits is the input of a transform. For example, for K=3 and N=8, c=[c₀, c₁, c₂], Q={3, 5, 7}, v=[v₀, v₁, v₂, v₃, v₄, v₅, v₆, v₇]=[0, 0, 0, c₀, 0, c₁, 0, c₂]. v₃, v₅, v₇ are set to c₀, c₁, c₂, respectively, while other bits in v are all set to 0. The 0th bit in the intermediate bit sequence is based on a linear combination of element v₀ (no element in c). The 1^{st} bit in the intermediate bit sequence is based on a linear combination of elements v₀, v₁ (no element in c). The 2^{nd} bit in the intermediate bit sequence is based on a linear combination of elements v₀, vᵢ, v₂ (no element in c). The 3rd bit in the intermediate bit sequence is based on a linear combination of elements v₀, v₁, v₂, v₃ (or a linear combination of element c₀). The 4th bit in the intermediate bit sequence is based on a linear combination of elements v₀, v₁, v₂, v₃, v₄ (also a linear combination of element c₀). The 5th bit in the intermediate bit sequence is based on a linear combination of elements v₀, vᵢ, v₂, v₃, v₄, v₅ (or a linear combination of elements c₀, c₁). The 6th bit in the intermediate bit sequence is based on a linear combination of elements v₀, v₁, v₂, v₃, v₄, v₅, v₆ (or a linear combination of elements c₀, c₁). The 7th bit in the intermediate bit sequence is based on a linear combination of elements v₀, v₁, v₂, v₃, v₄, v₅, v₆, v₇ (or a linear combination of elements c₀, c₁, c₂).

It will be appreciated by one of skill in the art that the disclosed techniques can be applied prior to the Polar transform in channel coding to improve transmission efficiency. For example, in some embodiments, a method for wireless communication can include applying a pre-transform operation prior to the Polar coding such that, as a result of the pre-transform operation (e.g., based on rate profiling to account for different payload sizes), a subset of bits having a length not equal to the Polar coding length N is coded to provide variable code lengths that are adaptive according to the payload size. As described in this patent document, the pre-transform operation can include shuffling based on indexes. Various possible pre-transform techniques are described with reference to FIGS. 5A-C, FIGS. 8A-C, Algorithms 1A-1L, Algorithms 2A-2L, Algorithms 3A-3L, Algorithms 4A-4B, Algorithms 5A-5G, Algorithms 6A-6G, and Algorithms 7A-7G. Other pre-transform operations can include index remapping using look-up tables or state machines. The methods illustrated in FIGS. 17-18 and described above are specific examples of the disclosed techniques. The disclosed techniques also include other approaches that are mathematically equivalent to the methods illustrated in FIGS. 17-18, the algorithms (Algorithms 1A-1L, Algorithms 2A-2L, Algorithms 3A-3L, Algorithms 4A-4B, Algorithms 5A-5G, Algorithms 6A-6G, and Algorithms 7A-7G), and/or the examples (e.g., Examples 1-8) described above.

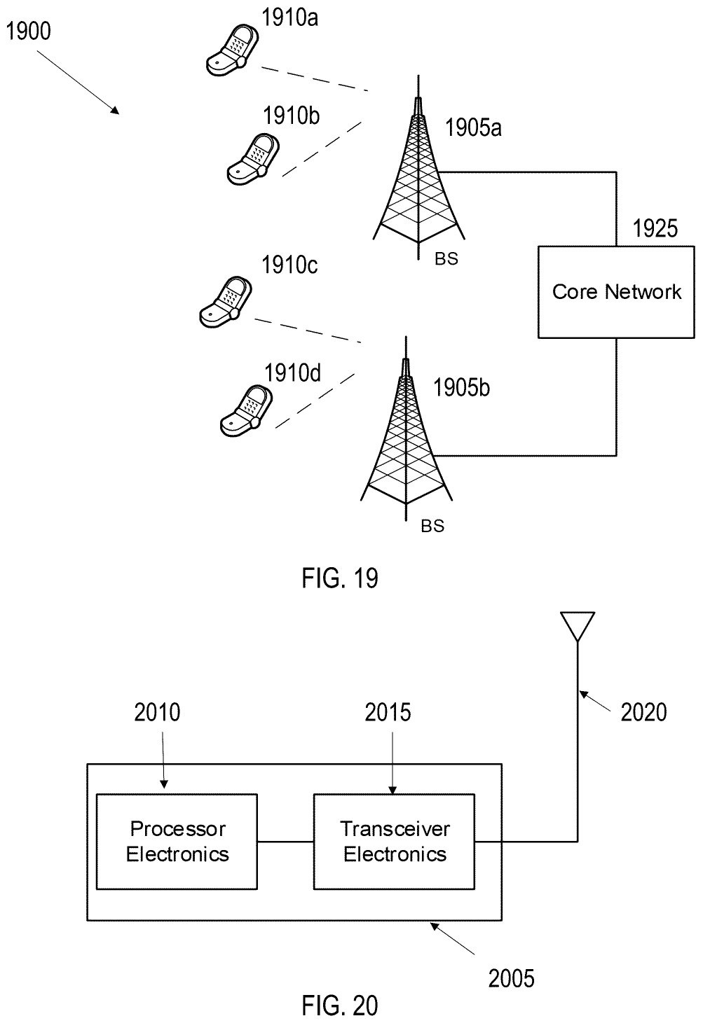

FIG. 19 shows an example of a wireless communication system 1900 where techniques in accordance with one or more embodiments of the present technology can be applied. A wireless communication system 1900 can include one or more base stations (BSs) 1905a, 1905b, one or more wireless devices (or UEs) 1910a, 1910b, 1910c, 1910d, and a core network 1925. A base station 1905a, 1905b can provide wireless service to user devices 1910a, 1910b, 1910c and 1910d in one or more wireless sectors. In some implementations, a base station 1905a, 1905b includes directional antennas to produce two or more directional beams to provide wireless coverage in different sectors. The core network 1925 can communicate with one or more base stations 1905a, 1905b. The core network 1925 provides connectivity with other wireless communication systems and wired communication systems. The core network may include one or more service subscription databases to store information related to the subscribed user devices 1910a, 1910b, 1910c, and 1910d. A first base station 1905a can provide wireless service based on a first radio access technology, whereas a second base station 1905b can provide wireless service based on a second radio access technology. The base stations 1905a and 1905b may be co-located or may be separately installed in the field according to the deployment scenario. The user devices 1910a, 1910b, 1910c, and 1910d can support multiple different radio access technologies. The techniques and embodiments described in the present document may be implemented by the base stations of wireless devices described in the present document.

FIG. 20 is a block diagram representation of a portion of a radio station in accordance with one or more embodiments of the present technology can be applied. A radio station 2005 such as a network node, a base station, or a wireless device (or a user device, UE) can include processor electronics 2010 such as a microprocessor that implements one or more of the wireless techniques presented in this document. The radio station 2005 can include transceiver electronics 2015 to send and/or receive wireless signals over one or more communication interfaces such as antenna 2020. The radio station 2005 can include other communication interfaces for transmitting and receiving data. Radio station 2005 can include one or more memories (not explicitly shown) configured to store information such as data and/or instructions. In some implementations, the processor electronics 2010 can include at least a portion of the transceiver electronics 2015. In some embodiments, at least some of the disclosed techniques, modules or functions are implemented using the radio station 2005. In some embodiments, the radio station 2005 may be configured to perform the methods described herein.

The disclosed and other embodiments, modules and the functional operations described in this document can be implemented in digital electronic circuitry, or in computer software, firmware, or hardware, including the structures disclosed in this document and their structural equivalents, or in combinations of one or more of them. The disclosed and other embodiments can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal, that is generated to encode information for transmission to suitable receiver apparatus.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this document can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random-access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described, and other implementations, enhancements and variations can be made based on what is described and illustrated in this patent document.

I/We claim:

1. A method for digital communication, comprising:
determining, by a first node, an output bit sequence having E bits based on an input bit sequence having K bits, wherein the output bit sequence is determined based on an intermediate bit sequence and further based on a transform that is applied prior to applying a Polar transform having a size of N, wherein the transform is based on at least one index set that is a subset of a set of bit indices, wherein the set of bit indices comprises all non-negative integers that are less than N and wherein K<N and K<E; and
transmitting, by the first node, a signal including the output bit sequence to a second node.

2. The method of claim 1, wherein the at least one index set comprises all non-negative integers that are equal to or smaller than Qₘₐₓ, wherein Qₘₐₓ is an element that has a largest value in a first index set Q having K elements, Q being a subset of the set of bit indices that comprises all non-negative integers that are less than N, and wherein
$${Q}_{max} = {max}_{k ∈ Q} k .$$

3. The method of claim 1, wherein the at least one index set is same as an ordered rate matching index set R=<R(0), R(1), . . . , R(Nᵣ−2), R(Nᵣ−1)>, wherein Nᵣ=min(E, N).

4. The method of claim 1, wherein the at least one index set comprises all non-negative integers that are equal to or smaller than Rₘₐₓ, wherein Rₘₐₓ is an element that has a largest value in an ordered rate matching index set R with
$${R}_{max} = {max}_{k ∈ R} k ,$$
wherein the output bit sequence consists of bits in an output bit sequence of the Polar transform with indices being in an ordered rate matching index set R=<R(0), R(1), . . . , R(Nᵣ−2), R(Nᵣ−1)>, wherein the output bit sequence of the Polar transform has a length N, and wherein Nᵣ=min(E, N).

5. The method of claim 1, wherein an j-th bit of the intermediate bit sequence is determined by a convolution bit sequence or a convolution polynomial in response to an index j being in the at least one index set, wherein the convolution bit sequence comprises a generator bit sequence g=[g₀, g₁, . . . , gₘ], or a recursive feedback bit sequence q=[q₀, q₁, . . . , qₘ]; or wherein the convolution polynomial comprises a generator polynomial g(D)=g₀+g₁·D+ . . . +gₘ₋₁·Dₘ₋₁+gₘ·D^{m}, or a recursive feedback polynomial q(D)=q₀+q₁·D+ . . . +qₘ₋₁·Dₘ₋₁+qₘ·D^{m}.

6. A method for digital communication, comprising:
receiving, by a second node, a signal including an output bit sequence having E bits from a first node, wherein the output bit sequence is determined based on an intermediate bit sequence; and
determining, by the second node, an input bit sequence having K bits by decoding the output bit sequence included in the signal, wherein the input bit sequence is determined based on a transform that is applied after applying an inverse Polar transform having a size of N, wherein the transform is based on at least one index set that is a subset of a set of bit indices, wherein the set of bit indices comprises all non-negative integers that are less than N and wherein K<N and K<E.

7. The method of claim 6, wherein the at least one index set comprises all non-negative integers that are equal to or smaller than Qₘₐₓ, wherein Qₘₐₓ is an element that has a largest value in a first index set Q having K elements, Q being a subset of the set of bit indices that comprises all non-negative integers that are less than N, and wherein
$${Q}_{max} = {max}_{k ∈ Q} k .$$

8. The method of claim 6, wherein the at least one index set is same as an ordered rate matching index set R=<R(0), R(1), . . . , R(Nᵣ−2), R(Nᵣ−1)>, wherein Nᵣ=min(E, N).

9. The method of claim 6, wherein the at least one index set comprises all non-negative integers that are equal to or smaller than Rₘₐₓ, wherein Rₘₐₓ is an element that has a largest value in an ordered rate matching index set R with
$${R}_{max} = {max}_{k ∈ R} k ,$$
wherein the output bit sequence consists of bits in an output bit sequence of the Polar transform with indices being in an ordered rate matching index set R=<R(0), R(1), . . . , R(Nᵣ−2), R(Nᵣ−1)>, wherein the output bit sequence of the Polar transform has a length N, and wherein Nᵣ=min(E, N).

10. The method of claim 6, wherein an j-th bit of the intermediate bit sequence is determined by a convolution bit sequence or a convolution polynomial in response to an index j being in the at least one index set, wherein the convolution bit sequence comprises a generator bit sequence g=[g₀, g₁, . . . , gₘ], or a recursive feedback bit sequence q=[q₀, q₁, . . . , qₘ]; or wherein the convolution polynomial comprises a generator polynomial g(D)=g₀+g₁·D+ . . . +gₘ₋₁·Dₘ₋₁+gₘ·D^{m}, or a recursive feedback polynomial q(D)=q₀+q₁·D+ . . . +qₘ₋₁·Dₘ₋₁+qₘ·D^{m}.

11. A communication apparatus, comprising at least a processor configured to cause the communication apparatus to:
determine an output bit sequence having E bits based on an input bit sequence having K bits, wherein the output bit sequence is determined based on an intermediate bit sequence and further based on a transform that is applied prior to applying a Polar transform having a size of N, wherein the transform is based on at least one index set that is a subset of a set of bit indices, wherein the set of bit indices comprises all non-negative integers that are less than N and wherein K<N and K<E; and
transmit a signal including the output bit sequence to a second node.

12. The communication apparatus of claim 11, wherein the at least one index set comprises all non-negative integers that are equal to or smaller than Qₘₐₓ, wherein Qₘₐₓ is an element that has a largest value in a first index set Q having K elements, Q being a subset of the set of bit indices that comprises all non-negative integers that are less than N, and wherein
$${Q}_{max} = {max}_{k ∈ Q} k .$$

13. The communication apparatus of claim 11, wherein the at least one index set is same as an ordered rate matching index set R=<R(0), R(1), . . . , R(Nᵣ−2), R(Nᵣ−1)>, wherein Nᵣ=min(E, N).

14. The communication apparatus of claim 11, wherein the at least one index set comprises all non-negative integers that are equal to or smaller than Rₘₐₓ, wherein Rₘₐₓ is an element that has a largest value in an ordered rate matching index set R with
$${R}_{max} = {max}_{k ∈ R} k ,$$
wherein the output bit sequence consists of bits in an output bit sequence of the Polar transform with indices being in an ordered rate matching index set R=<R(0), R(1), . . . , R(Nᵣ−2), R(Nᵣ−1)>, wherein the output bit sequence of the Polar transform has a length N, and wherein Nᵣ=min(E, N).

15. The communication apparatus of claim 11, wherein an j-th bit of the intermediate bit sequence is determined by a convolution bit sequence or a convolution polynomial in response to an index j being in the at least one index set, wherein the convolution bit sequence comprises a generator bit sequence g=[g₀, g₁, . . . , gₘ], or a recursive feedback bit sequence q=[q₀, q₁, . . . , qₘ]; or wherein the convolution polynomial comprises a generator polynomial g(D)=g₀+g₁·D+ . . . +gₘ₋₁·Dₘ₋₁+gₘ·D^{m}, or a recursive feedback polynomial q(D)=q₀+q₁·D+ . . . +qₘ₋₁·Dₘ₋₁+qₘ·D^{m}.

16. A communication apparatus, comprising at least a processor configured to cause the communication apparatus to:
receive a signal including an output bit sequence having E bits from a first node, wherein the output bit sequence is determined based on an intermediate bit sequence; and
determine an input bit sequence having K bits by decoding the output bit sequence included in the signal, wherein the input bit sequence is determined based on a transform that is applied after applying an inverse Polar transform having a size of N, wherein the transform is based on at least one index set that is a subset of a set of bit indices, wherein the set of bit indices comprises all non-negative integers that are less than N and wherein K<N and K<E.

17. The communication apparatus of claim 16, wherein the at least one index set comprises all non-negative integers that are equal to or smaller than Qₘₐₓ, wherein Qₘₐₓ is an element that has a largest value in a first index set Q having K elements, Q being a subset of the set of bit indices that comprises all non-negative integers that are less than N, and wherein
$${Q}_{max} = {max}_{k ∈ Q} k .$$

18. The communication apparatus of claim 16, wherein the at least one index set is same as an ordered rate matching index set R=<R(0), R(1), . . . , R(Nᵣ−2), R(Nᵣ−1)>, wherein Nᵣ=min(E, N).

19. The communication apparatus of claim 16, wherein the at least one index set comprises all non-negative integers that are equal to or smaller than Rₘₐₓ, wherein Rₘₐₓ is an element that has a largest value in an ordered rate matching index set R with
$${R}_{max} = {max}_{k ∈ R} k ,$$
wherein the output bit sequence consists of bits in an output bit sequence of the Polar transform with indices being in an ordered rate matching index set R=<R(0), R(1), . . . , R(Nᵣ−2), R(Nᵣ−1)>, wherein the output bit sequence of the Polar transform has a length N, and wherein Nᵣ=min(E, N).

20. The communication apparatus of claim 16, wherein an j-th bit of the intermediate bit sequence is determined by a convolution bit sequence or a convolution polynomial in response to an index j being in the at least one index set, wherein the convolution bit sequence comprises a generator bit sequence g=[g₀, g₁, . . . , gₘ], or a recursive feedback bit sequence q=[q₀, q₁, . . . , qₘ]; or wherein the convolution polynomial comprises a generator polynomial g(D)=g₀+g₁·D+ . . . +gₘ₋₁·Dₘ₋₁+gₘ·D^{m}, or a recursive feedback polynomial q(D)=q₀+q₁·D+ . . . +qₘ₋₁·Dₘ₋₁+qₘ·D^{m}.
